(19) United States
(12) Patent Application Publication
(10) Pub. No.: US 2026/0198169 A1
(43) Pub. Date: Jul. 9, 2026

(54) POLYCYCLIC COMPOUND, LIGHT-EMITTING DEVICE AND ELECTRONIC DEVICE

(71) Applicant: Samsung Display Co., Ltd., Yongin-si (KR)

(72) Inventors: Hirokazu MIYASHITA, Yongin-si (KR); Hyung Jong KIM, Yongin-si (KR); Jun Ha PARK, Yongin-si (KR); Han Kyu PAK, Yongin-si (KR); Min Jae SUNG, Yongin-si (KR); Mun Ki SIM, Yongin-si (KR); Min Jung JUNG, Yongin-si (KR)

(21) Appl. No.: 19/344,160

(22) Filed: Sep. 29, 2025

(30) Foreign Application Priority Data
Jan. 8, 2025 (KR) 10-2025-0002833

(51) Int. Cl. H10K 50/12; C07F 5/02; H10K 50/19; H10K 85/30; H10K 85/60; H10K 101/25

(52) U.S. Cl. CPC H10K 50/12; C07F 5/027; H10K 50/19; H10K 85/346; H10K 85/626; H10K 85/633; H10K 85/636; H10K 85/654; H10K 85/6572; H10K 85/6574; H10K 85/6576; H10K 85/658; H10K 2101/25

(57) ABSTRACT

Embodiments provide a polycyclic compound, a light-emitting device that includes the polycyclic compound, and an electronic device that includes the light-emitting device. The light-emitting device includes a first electrode, a second electrode, and an emission layer between the first electrode and the second electrode. The emission layer includes a polycyclic compound represented by Chemical Formula 1.

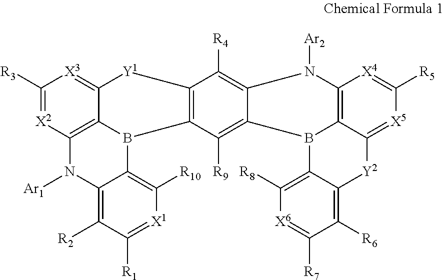

### CROSS-REFERENCE TO RELATED APPLICATION

The present application claims priority to and the benefit of Korean Patent Application No. 10-2025-0002833, filed on Jan. 8, 2025, in the Korean Intellectual Property Office, the entire content of which is incorporated by reference herein.

### BACKGROUND

### 1. Field

Embodiments of the present disclosure relate to a polycyclic compound, a light-emitting device and an electronic device.

### 2. Description of the Related Art

An organic light-emitting diode (OLED) display has a self-luminous property, and may provide improved viewing angle and contrast properties. Additionally, a high response speed and a high luminance may be provided by the OLED.

A light-emitting device may include an emission layer between a first electrode and a second electrode. A hole transferred from the first electrode and an electron transferred from the second electrode may be recombined in the emission layer to generate an exciton. Light emission properties are implemented as the exciton is shifted from an excited state to a ground state.

The emission layer may include a light-emitting material. The excitons may be formed in a ratio of 25% and 75% of a singlet state and a triplet state, respectively. The light-emitting material may be classified into a fluorescence material, a phosphorescence material, and a delayed fluorescence material according to a mechanism used by the excitons.

In a quantum mechanics aspect, a singlet exciton (S₁) may be used for the light-emission in the fluorescent material, and a triplet exciton (T₁) may proceed to an exothermic process in which a transition to S₀ is a non-emission process.

To achieve a theoretical 100% internal quantum efficiency, materials capable of implementing a reverse intersystem crossing (RISC) from the triplet state to the singlet state are researched and developed.

### SUMMARY

According to an aspect of embodiments of the present disclosure, there is provided a polycyclic compound having improved color property, luminous efficiency and life-span property.

According to an aspect of embodiments of the present disclosure, there is provided a light-emitting device having improved color property, luminous efficiency and life-span property.

According to an aspect of embodiments of the present disclosure, there is provided an electronic device having improved color property, luminous efficiency and life-span property.

A polycyclic compound may be represented by Chemical Formula 1.

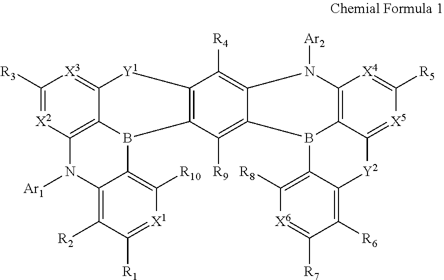

In Chemical Formula 1, Y¹ and Y² may each independently be S, O or Se, X¹ to X⁶ may each independently be CR₁₁ or N, at least one selected from X¹ to X⁶ may be N. When two or more of X¹ to X⁶ are CR₁₁, two or more CR₁₁ are the same or different from each other. R₁ to R₁₁ may each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group, and two or more adjacent groups selected from among R₁ to R₁₁ may be optionally combined with each other to form a saturated or unsaturated ring.

When nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ may each independently be a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

In some embodiments, any one or two selected from X¹ to X⁶ is N, and the remainder may be CR₁₁.

In some embodiments, at least one selected from X² and X⁴ among X¹ to X⁶ may be N, and the remainder may be CR₁₁.

In some embodiments, Y₁ and Y₂ may be the same.

A light-emitting device may include a first electrode, a second electrode, and an emission layer between the first electrode and the second electrode. The emission layer may include the polycyclic compound represented by Chemical Formula 1.

In some embodiments, the polycyclic compound may be included as a thermally activated delayed fluorescence (TADF) dopant.

In some embodiments, each of the plurality of emission layers may include the polycyclic compound, and the polycyclic compound may be included as a thermally activated delayed fluorescence (TADF) dopant.

An electronic device may include the light-emitting device.

The polycyclic compound according to embodiments of the present disclosure may provide improved color property, luminous efficiency and life-span property.

The light-emitting device according to embodiments of the present disclosure and the electronic device including the light-emitting device may have improved color property, luminous efficiency and life-span property.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1 to 6 are schematic cross-sectional views illustrating light-emitting devices in accordance with example embodiments of the present disclosure.

FIG. 7 is a schematic cross-sectional view illustrating a display device in accordance with example embodiments of the present disclosure.

FIG. 8 is a schematic cross-sectional view illustrating a display device in accordance with example embodiments of the present disclosure.

FIG. 9 is a schematic cross-sectional view illustrating a stack construction of light-emitting structure in a display device in accordance with example embodiments of the present disclosure.

FIG. 10 is a schematic cross-sectional view illustrating a display device in accordance with example embodiments of the present disclosure.

FIG. 11 is a schematic cross-sectional view illustrating a display device in accordance with example embodiments of the present disclosure.

FIG. 12 is a schematic exploded perspective view illustrating an electronic device in accordance with example embodiments of the present disclosure.

FIG. 13 is a schematic view illustrating an electronic device in accordance with example embodiments of the present disclosure.

FIG. 14 is a block diagram of an electronic device in accordance with an embodiment of the present disclosure.

FIG. 15 shows schematic diagrams of electronic devices in accordance with various suitable embodiments of the present disclosure.

### DETAILED DESCRIPTION

A polycyclic compound according to embodiments of the present disclosure may have an extended luminescent core and may include an electron-deficient nitrogen in the luminescent core, so that a deep HOMO energy level may be achieved. Accordingly, improved color properties may be implemented, and a carrier balance may be improved by suitably or appropriately controlling movement speeds of electrons and holes.

In embodiments, the polycyclic compound may have a substituent other than hydrogen or deuterium at at least one selected from carbons adjacent to the electron-deficient nitrogen atom, so that improved oxidation stability and energy efficiency may be achieved.

According to embodiments of the present disclosure, a light-emitting element including the polycyclic compound and an electronic device including the same are provided.

### Definition of Terminology

In the present specification, the term “substituted or unsubstituted” may refer to being substituted or unsubstituted by one or more substituent selected from the group consisting of, e.g., a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group (e.g., a C₁-C₆₀ or C₁-C₁₀ alkyl group), an alkenyl group (e.g., a C₂-C₆₀ or C₂-C₁₀ alkenyl group), an alkynyl group (e.g., a C₂-C₆₀ or C₂-C₁₀ alkynyl group), an alkoxy group (e.g., a C₁-C₆₀ or C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may refer to a group in which at least one selected from hydrogen atoms of the alkyl group is substituted with the above-described substituent, and thus the substituent is further bonded to a carbon atom of the alkyl group.

The substituent may include a combination of substituents selected from the groups described above. For example, at least one hydrogen atom in the alkyl group, the aryl group, and/or the like, included as a substituent may be substituted with a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, a heterocyclic group, or a combination thereof.

In the substituents described above, a multivalent substituent such as an amino group, a phosphine sulfide group, a phosphine oxide group, a sulfinyl group, a sulfonyl group, an oxy group, a carbonyl group, an ester group, and/or the like, may each independently be substituted with a C₁-C₁₀ alkyl group, a C₁-C₁₀ alkenyl group, a C₁-C₁₀ alkynyl group, or a C₆-C₁₀ aryl group.

In the specification, the term “substituted or unsubstituted Cₐ-C_{b} Y group” the range of a to b refers to the number of carbon atoms in an unsubstituted Y group, and may not include the number of carbon atoms of a substituent.

In the specification, an alkyl group may be a monovalent hydrocarbon group in which one hydrogen atom is removed from a linear or branched hydrocarbon group. Examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, and/or the like.

In the specification, an alkylene group may be a divalent hydrocarbon group in which two hydrogen atoms are removed from a linear or branched hydrocarbon group.

In the specification, an alkenyl group may have the same skeleton as that of an alkyl group, and may be a monovalent hydrocarbon group that includes at least one carbon-carbon double bond. In the specification, an alkenylene group may be a divalent hydrocarbon group in which one hydrogen atom is further removed from an alkenyl group.

In the specification, an alkynyl group may have the same skeleton as that of an alkyl group, and may be a monovalent hydrocarbon group that includes at least one carbon-carbon triple bond. In the specification, an alkynylene group may be a divalent hydrocarbon group in which one hydrogen atom is further removed from an alkynyl group.

In the specification, an aryl group may be a monovalent hydrocarbon group in which one hydrogen atom is removed from a hydrocarbon group having an aromatic structure. The definition of an aryl group may also encompass a group in which a plurality of aromatic rings are directly connected, such as a biphenyl group. Examples of an aryl group may include, e.g., a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, and/or the like.

In the specification, a group in which two or more aryl rings are condensed to each other or linked to each other by an alicyclic hydrocarbon ring, such as a fluorenyl group, can be encompassed in the definition of an aryl group.

For example, a biphenyl group may be interpreted as an aryl group, or may be interpreted as a phenyl group that is substituted with a phenyl group.

In the specification, an arylene group may be a divalent hydrocarbon group in which two hydrogen atoms are removed from an aryl group.

In the specification, a heteroaryl group may be a monovalent group having an aromatic structure that includes at least one heteroatom such as B, O, P, S, and Si as a ring-forming atom. In the specification, a heteroarylene group may be a divalent group having an aromatic structure that includes at least one heteroatom such as B, O, P, S, and Si as a ring-forming atom. When a heteroaryl group or a heteroarylene group includes two or more heteroatoms, the two or more heteroatoms may be the same as or different from each other.

In the specification, a group in which two or more aryl rings are condensed or linked to a non-aromatic heterocyclic ring, such as a carbazole group, can also be encompassed in the definition of a heteroaryl group.

In the specification, the term “cyclic group” may encompass a monocyclic group or a polycyclic group, and may also encompass an alicyclic ring or an aromatic ring.

In the specification, the term “polycyclic group” may be a group in which two or more rings are connected to each other or condensed to each other through one or more atoms. For example, a polycyclic structure may include a bicyclic structure through a bridge carbon, a spiro structure, a fused structure, and/or the like.

In the specification, the term “condensed group” or “condensed ring structure” may each be a group in which two or more adjacent rings share two or more atoms selected from among the above-described polycyclic structures. Examples of a condensed ring structure may include naphthalene, anthracene, phenanthrene, fluorene, pyrene, benzopyrene, pentacene, polyacene, helicene, and/or the like.

In the specification, the term “carbocyclic group (e.g., C₃-C₆₀ carbocyclic group)” may be a cyclic group in which carbon atoms are the only ring-forming atoms. In the specification, a heterocyclic group (e.g., a C₁-C₆₀ heterocyclic group) may be a cyclic group that includes at least one heteroatom as a ring-forming atom, in addition to carbon atoms.

In the specification, a carbocyclic group and a heterocyclic group may each independently be a monocyclic group that consists of one ring or a polycyclic group in which two or more rings are condensed with each other.

### Polycyclic Compound

A polycyclic compound according to embodiments may be represented by Chemical Formula 1 below.

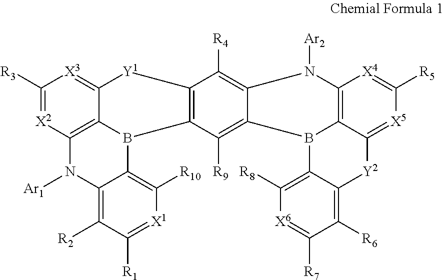

In Chemical Formula 1, Y¹ and Y² may each independently be S, O or Se.

X¹ to X⁶ may each independently be CR₁₁ or N, at least one selected from X¹ to X⁶ may be N. When the number of CR₁₁ is 2 or more, two or more CR₁₁ may be the same or different.

R₁ to R₁₁ may each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among R₁ to R₁₁ may optionally be combined with each other to form a saturated or unsaturated ring.

When nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ may each independently be a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

The polycyclic compound may include an electron-deficient nitrogen atom in an extended luminescent core to have a deep HOMO energy level. At least one selected from carbons adjacent to the electron-deficient nitrogen atom may have a substituent other than hydrogen or deuterium, and thus an interaction with surrounding compounds may be reduced. Accordingly, color properties of the polycyclic compound may be improved, and life-span properties and energy efficiency may be improved. In embodiments, a driving voltage of the light-emitting device including the polycyclic compound may be lowered.

In an embodiment, the saturated ring may be selected from a 5-membered ring, a 6-membered ring, and a 7-membered ring, and may be a hydrocarbon ring or a heteroatom-containing ring. The saturated ring may be unsubstituted or substituted with at least one selected from the group consisting of deuterium, —F, —Cl, —CD₃, —CD₂H, —CDH₂, a C₁-C₁₀ straight-chain alkyl group, a C₃-C₁₀ branched alkyl group, a C₂-C₁₀ straight-chain alkenyl group, a C₃-C₁₀ branched alkenyl group, and a C₆-C₁₀ aryl group.

In an embodiment, the unsaturated ring may be selected from a 5-membered ring, a 6-membered ring and a 7-membered ring, and may be a hydrocarbon ring or a heteroatom-containing ring. The unsaturated ring may be, e.g., a cycloalkene or an aromatic ring which contains a C═C unsaturated double bond. The unsaturated ring may be unsubstituted or substituted with at least one selected from the group consisting of deuterium, —F, —Cl, —CD₃, —CD₂H, —CDH₂, a C₁-C₁₀ straight-chain alkyl group, a C₃-C₁₀ branched alkyl group, a C₂-C₁₀ straight-chain alkenyl group, a C₃-C₁₀ branched alkenyl group, and a C₆-C₁₀ aryl group.

In an embodiment, e.g., the substituted or unsubstituted C₈-C₆₀ condensed polycyclic group may be a condensed polycyclic group in which a C₄-C₁₀ aliphatic hydrocarbon ring and a C₆-C₅₀ aromatic hydrocarbon ring are condensed. The condensed polycyclic group may have a structure in which, e.g., one C₄-C₆ aliphatic hydrocarbon ring is condensed between two C₆-C₁₅ aromatic hydrocarbon ring. The condensed polycyclic group may be, e.g., a substituted or unsubstituted carbazole group, a substituted or unsubstituted fluorene group, or a spiro-bifluorene group.

In an embodiment, the silyl group may be —Si(R^{Sa})(R^{Sb})(R^{Sc}), and R^{Sa}, R^{Sb} and R^{Sc} may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group. The above definition of the condensed polycyclic group may be equally applied.

In some embodiments, when nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ may each independently be a substituted or unsubstituted C₁-C₆₀ alkyl group, a substituted or unsubstituted C₃-C₆₀ cycloalkyl group, a substituted or unsubstituted C₃-C₆₀ heterocycloalkyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

In some embodiments, when nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ may each independently be a substituted or unsubstituted C₆-C₆₀ aryl group, a substituted or unsubstituted C₇-C₆₀ arylalkyl group, a substituted or unsubstituted C₂-C₆₀ heteroaryl group, or a substituted or unsubstituted C₃-C₆₀ heteroarylalkyl group. Accordingly, oxidation stability of the polycyclic compound may be further improved.

In some embodiments, any one or two selected from X¹ to X⁶ in Chemical Formula 1 may be N, and the remainder may be CR₁₁.

In some embodiments, any one selected from X¹ to X⁶ may be N, and the remainder may be CR₁₁.

In some embodiments, X² and/or X⁴ among X¹ to X⁶ may be N, and the remainder may be CR₁₁. Accordingly, an energy level (S1 level) of the lowest singlet excited state of the polycyclic compound may be increased and the HOMO energy level may be deepened, thereby further improving color purity in a blue emission wavelength range while achieving high oxidation stability.

In some embodiments, Y₁ and Y₂ may be the same.

In some embodiments, Y₁ and Y₂ may be oxygen. Accordingly, the HOMO energy level of the polycyclic compound may become deeper.

In some embodiments, the polycyclic compound may be represented by any one selected from Chemical Formulae 1-1 to 1-6 below.

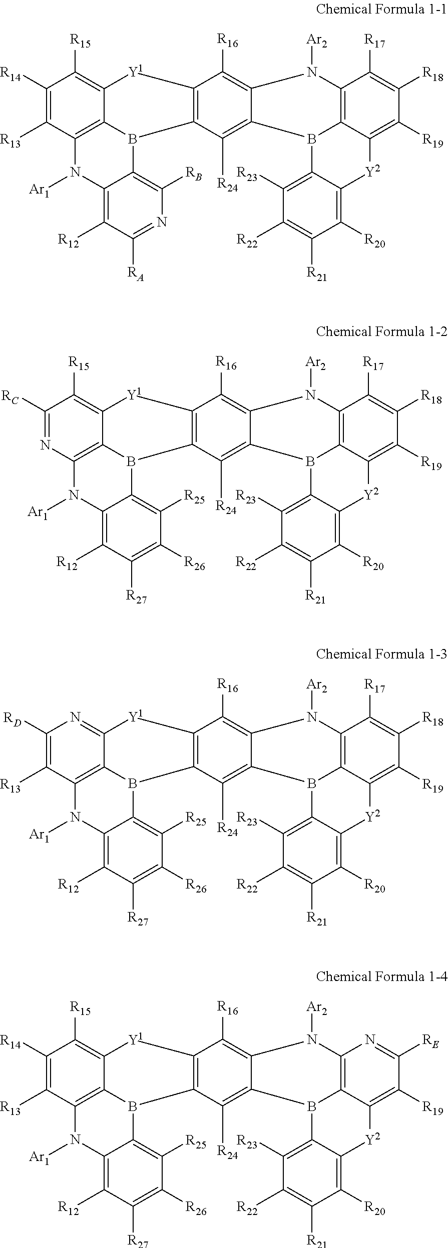

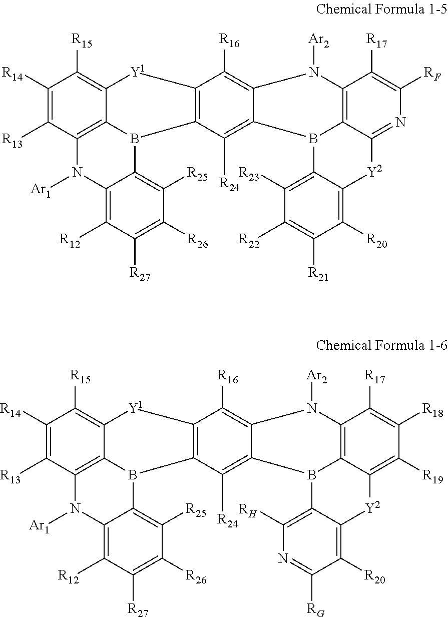

In Chemical Formulae 1-1 to 1-6, Y¹ and Y² may each independently be S, O or Se.

R₁₂ to R₂₇ and R_{A} to R_{H} may each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among R₁₂ to R₂₇ may optionally be combined with each other to form a saturated or unsaturated ring.

At least one selected from R_{A} and R_{B}; R_{C} to R_{F}; and at least one selected from R_{G} and R_{H} may each independently be a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

Accordingly, both color purity and life-span properties in the blue emission region of the polycyclic compound may be improved, and the driving voltage of the light-emitting device including the polycyclic compound may be reduced.

In some embodiments, Ar₁ and Ar₂ may each independently be selected from groups represented by Chemical Formulae 2-1 to 2-12.

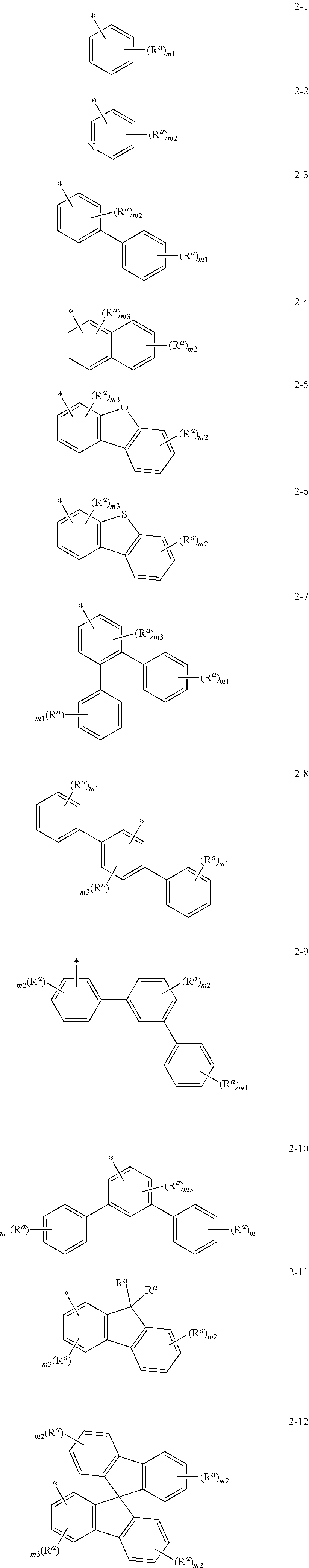

In Chemical Formulae 2-1 to 2-12, R^{a} may each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group. When R^{a} is plural (e.g., when there are a plurality of R^{a}), two or more adjacent R^{a} may optionally be combined with each other to form a saturated or unsaturated ring. When R^{a} is plural (e.g., when there are a plurality of R^{a}), two or more R^{a} may be the same or different.

In embodiments, m1 may be the same or different, and may be an integer from 0 to 5. In embodiments, m2 may be the same or different, and may be an integer from 0 to 4. m3 may be the same or different, and may be an integer from 0 to 3. In embodiments, *- represents a bonding position.

According to embodiments of the present disclosure, stacking between the polycyclic compounds may be suppressed or reduced. Thus, movement speed of electrons and holes may be suitably or appropriately controlled to improve carrier balance.

In some embodiments, Ar₁ and Ar₂ may each independently be selected from groups represented by Chemical Formulae 2-3, and 2-7 to 2-10. Accordingly, carrier balance may be further improved to achieve high luminescence properties.

In some embodiments, Ar₁ and Ar₂ may each be independently selected from groups represented by Chemical Formulae 2-13, 2-14, and 2-15 below. Accordingly, packing between the polycyclic compounds may be further suppressed or reduced.

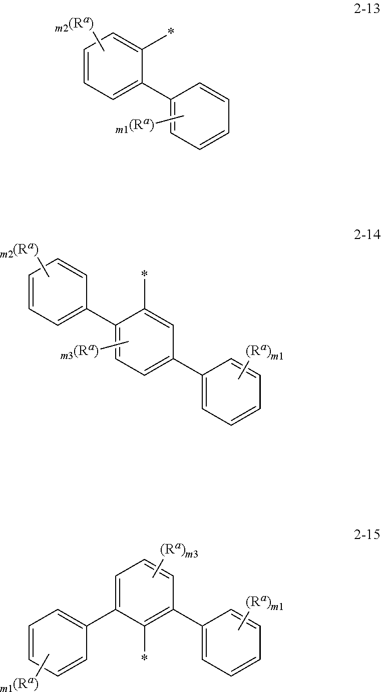

In Chemical Formulae 2-13 to 2-15, the above descriptions of R^{a} and m1 to m3 may also be applied.

In some embodiments, Ar₁ and Ar₂ may each independently be selected from group represented by Chemical Formula 2-10.

In some embodiments, at least one selected from R₂₀ to R₂₃ in Chemical Formula 1-1; at least one selected from R₁₂, R₂₀ to R₂₃, and R₂₅ to R₂₇ in Chemical Formula 1-2 to 1-5; and at least one selected from R₁₂, and R₂₅ to R₂₇ in Chemical Formula 1-6 may each independently be a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

Accordingly, chemical reactivity of the polycyclic compound with surrounding compounds may be reduced, thereby further improving the life-span properties.

In some embodiments, when at least one selected from the carbons to which R₁, R₃, R₅, R₇, R₈ and R₁₀ are directly bonded is adjacent to nitrogen, at least one selected from the corresponding R₁, R₃, R₅, R₇, R₈ and R₁₀ may each independently be selected from a group represented by —CH₃, —CD₃, —CD₂H, —CDH₂, and any one selected from Chemical Formulae 3-1 to 3-12.

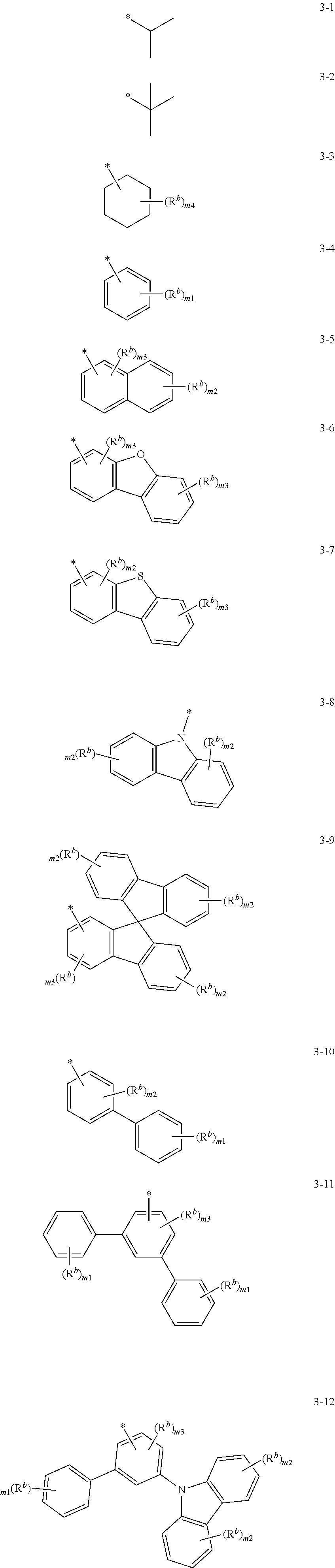

In Chemical Formulae 3-1 to 3-12, R^{b} may each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group. When R^{b} is plural (e.g., when there are a plurality of R^{b}), two or more adjacent R^{b} may optionally be combined with each other to form a saturated or unsaturated ring. When R^{b} is plural (e.g., when there are a plurality of R^{b}), two or more R^{b} may be the same or different.

In embodiments, m1 may be the same or different, and may be an integer from 0 to 5. m2 may be the same or different, and may be an integer from 0 to 4. m4 may be an integer from 0 to 11. m3 may be the same or different, and may be an integer from 0 to 3. In embodiments, *- represents a bonding position.

In some embodiments, in Chemical Formulae 1-1 to 1-6, at least one selected from R_{A} and R_{B}; R_{C} to R_{F}; and at least one selected from R_{G} and R_{H} may each independently be selected from —CH₃, —CD₃, —CD₂H, —CDH₂, and any one selected from Chemical Formulae 3-1 to 3-12.

In Chemical Formula 1-1, R_{B} may be hydrogen or deuterium, and R_{A} may be a substituted or unsubstituted C₆-C₆₀ aryl group, a substituted or unsubstituted C₇-C₆₀ arylalkyl group, a substituted or unsubstituted C₂-C₆₀ heteroaryl group, or a substituted or unsubstituted C₃-C₆₀ heteroarylalkyl group. Accordingly, oxidation stability of the polycyclic compound may be further improved.

In some embodiments, in Chemical Formula 1-1, R_{B} may be hydrogen or deuterium, and R_{A} may be a substituted or unsubstituted C₆-C₆₀ aryl group.

In some embodiments, in Chemical Formula 1-1, R_{B} may be hydrogen or deuterium, and R_{A} may be selected from groups represented by Chemical formulae 3-4 to 3-12.

In some embodiments, R_{C} in Chemical Formula 1-2, R_{D} in Chemical Formula 1-3, R_{E} in Chemical Formula 1-4, and R_{F} in Chemical Formula 1-5 may each independently be a substituted or unsubstituted C₆-C₆₀ aryl group, a substituted or unsubstituted C₇-C₆₀ arylalkyl group, a substituted or unsubstituted C₂-C₆₀ heteroaryl group, or a substituted or unsubstituted C₃-C₆₀ heteroarylalkyl group. Accordingly, oxidation stability of the polycyclic compound may be further improved.

In some embodiments, R_{C} in Chemical Formula 1-2, R_{D} in Chemical Formula 1-3, R_{E} in Chemical Formula 1-4, and R_{F} in Chemical Formula 1-5 may each independently be a substituted or unsubstituted C₆-C₆₀ aryl group.

In some embodiments, R_{C} in Chemical Formula 1-2, R_{D} in Chemical Formula 1-3, R_{E} in Chemical Formula 1-4, and R_{F} in Chemical Formula 1-5 may each independently be selected from groups represented by Chemical Formulae 3-4 to 3-12.

In Chemical Formula 1-6, R_{H} may be hydrogen or deuterium, and R_{G} may be a substituted or unsubstituted C₆-C₆₀ aryl group, a substituted or unsubstituted C₇-C₆₀ arylalkyl group, a substituted or unsubstituted C₂-C₆₀ heteroaryl group, or a substituted or unsubstituted C₃-C₆₀ heteroarylalkyl group. Accordingly, oxidation stability of the polycyclic compound may be further improved.

In some embodiments, in Chemical Formula 1-6, R_{H} may be hydrogen or deuterium, and R_{G} may be a substituted or unsubstituted C₆-C₆₀ aryl group.

In some embodiments, in Chemical Formula 1-6, R_{H} may be hydrogen or deuterium, and R_{G} may be selected from groups represented by Chemical Formulae 3-4 to 3-12.

In some embodiments, R^{a} and R^{b} may each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₃₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group. When R^{a} or R^{b} is plural (e.g., when there are a plurality of R^{a} and/R^{b}), two or more adjacent R^{a} or R^{b} may optionally be combined with each other to form a saturated or unsaturated ring.

In some embodiments, the polycyclic compound may be any one selected from Compounds 1 to 140 below.

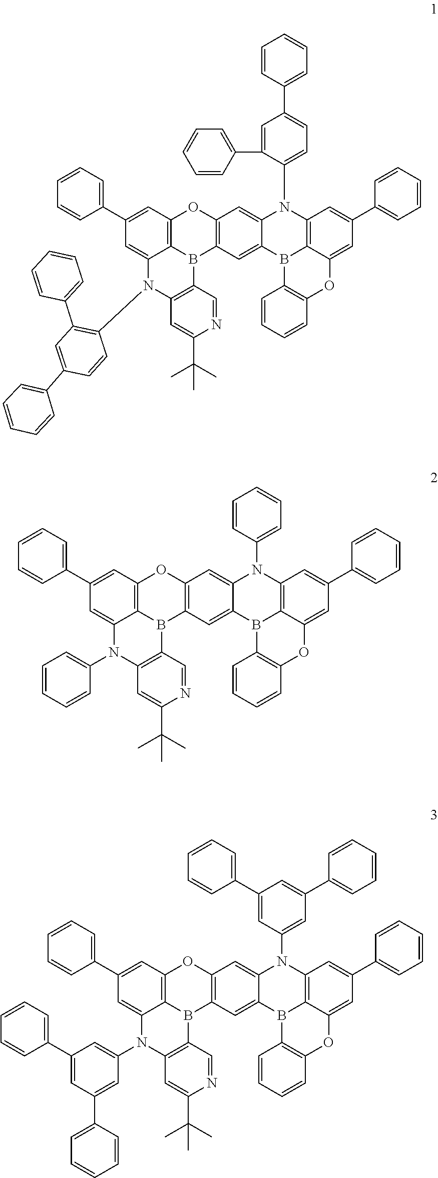 [SMILES: CC(C)(C)c1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2 ; CC(C)(C)c1cc2c(cn1)B1c3cc4c(cc3Oc3cc(-c5ccccc5)cc(c31)N2c1ccccc1)N(c1ccccc1)c1cc(-c2ccccc2)cc2c1B4c1ccccc1O2 ; CC(C)(C)c1cc2c(cn1)B1c3cc4c(cc3Oc3cc(-c5ccccc5)cc(c31)N2c1cc(-c2ccccc2)cc(-c2ccccc2)c1)N(c1cc(-c2ccccc2)cc(-c2ccccc2)c1)c1cc(-c2ccccc2)cc2c1B4c1ccccc1O2]

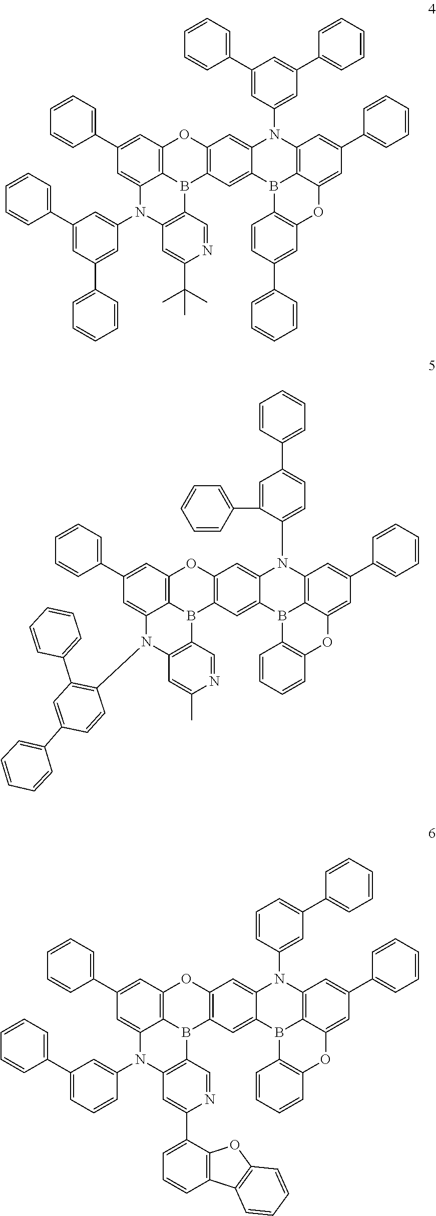 [SMILES: CC(C)(C)c1cc2c(cn1)B1c3cc4c(cc3Oc3cc(-c5ccccc5)cc(c31)N2c1cc(-c2ccccc2)cc(-c2ccccc2)c1)N(c1cc(-c2ccccc2)cc(-c2ccccc2)c1)c1cc(-c2ccccc2)cc2c1B4c1ccc(-c3ccccc3)cc1O2 ; Cc1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2 ; c1ccc(-c2cccc(N3c4cc(-c5cccc6c5oc5ccccc56)ncc4B4c5cc6c(cc5Oc5cc(-c7ccccc7)cc3c54)N(c3cccc(-c4ccccc4)c3)c3cc(-c4ccccc4)cc4c3B6c3ccccc3O4)c2)cc1]

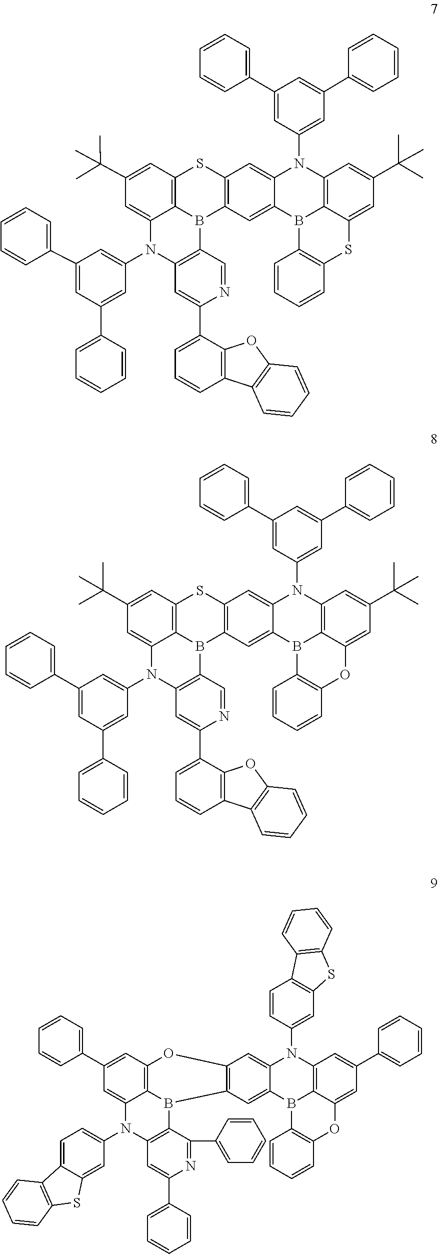 [SMILES: CC(C)(C)c1cc2c3c(c1)N(c1cc(-c4ccccc4)cc(-c4ccccc4)c1)c1cc(-c4cccc5c4oc4ccccc45)ncc1B3c1cc3c(cc1S2)N(c1cc(-c2ccccc2)cc(-c2ccccc2)c1)c1cc(C(C)(C)C)cc2c1B3c1ccccc1S2 ; CC(C)(C)c1cc2c3c(c1)N(c1cc(-c4ccccc4)cc(-c4ccccc4)c1)c1cc4c(cc1B3c1ccccc1O2)B1c2cnc(-c3cccc5c3oc3ccccc35)cc2N(c2cc(-c3ccccc3)cc(-c3ccccc3)c2)c2cc(C(C)(C)C)cc(c21)S4 ; c1ccc(-c2cc3c4c(c2)N(c2ccc5c(c2)sc2ccccc25)c2cc5c(cc2B4c2ccccc2O3)B2c3c(cc(-c4ccccc4)cc3N(c3ccc4c(c3)sc3ccccc34)c3cc(-c4ccccc4)nc(-c4ccccc4)c32)O5)cc1]

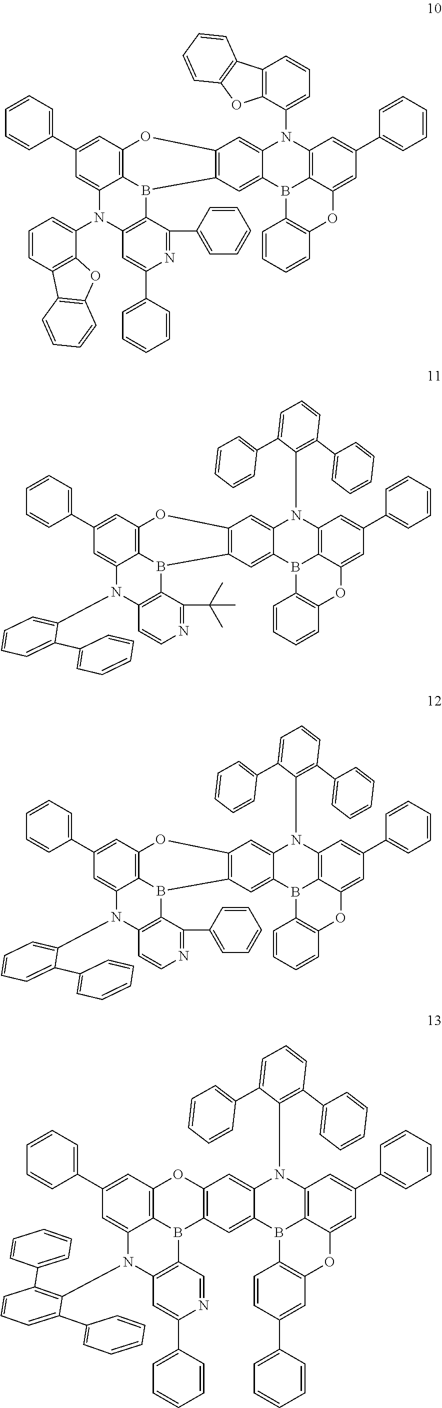

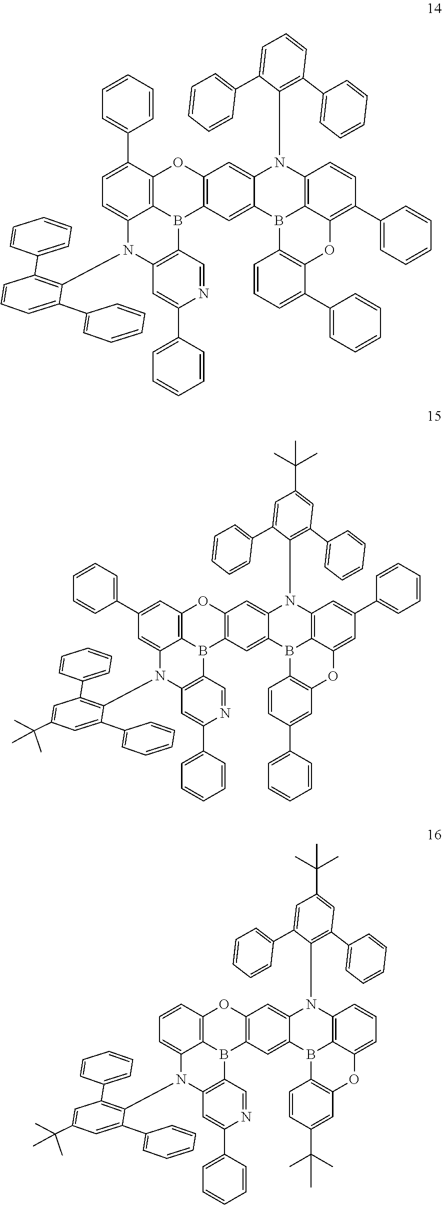

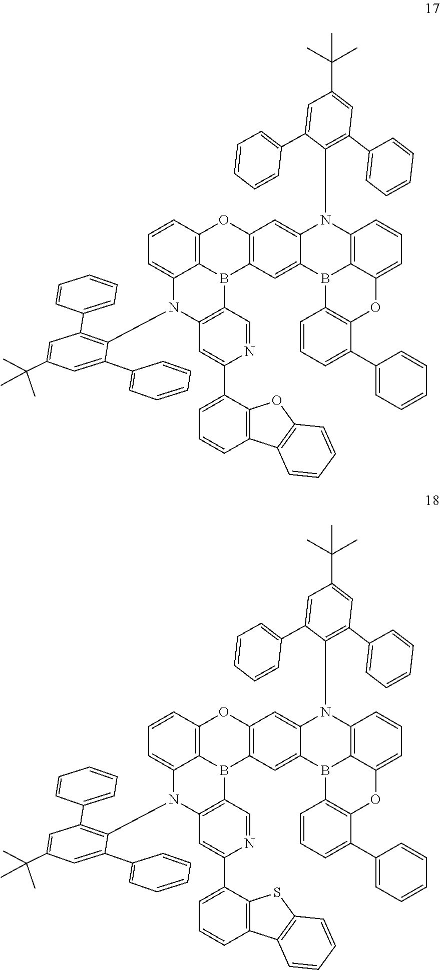 [SMILES: CC(C)(C)c1cc(-c2ccccc2)c(N2c3cc(-c4cccc5c4oc4ccccc45)ncc3B3c4cc5c(cc4Oc4cccc2c43)N(c2c(-c3ccccc3)cc(C(C)(C)C)cc2-c2ccccc2)c2cccc3c2B5c2cccc(-c4ccccc4)c2O3)c(-c2ccccc2)c1 ; CC(C)(C)c1cc(-c2ccccc2)c(N2c3cc(-c4cccc5c4sc4ccccc45)ncc3B3c4cc5c(cc4Oc4cccc2c43)N(c2c(-c3ccccc3)cc(C(C)(C)C)cc2-c2ccccc2)c2cccc3c2B5c2cccc(-c4ccccc4)c2O3)c(-c2ccccc2)c1]

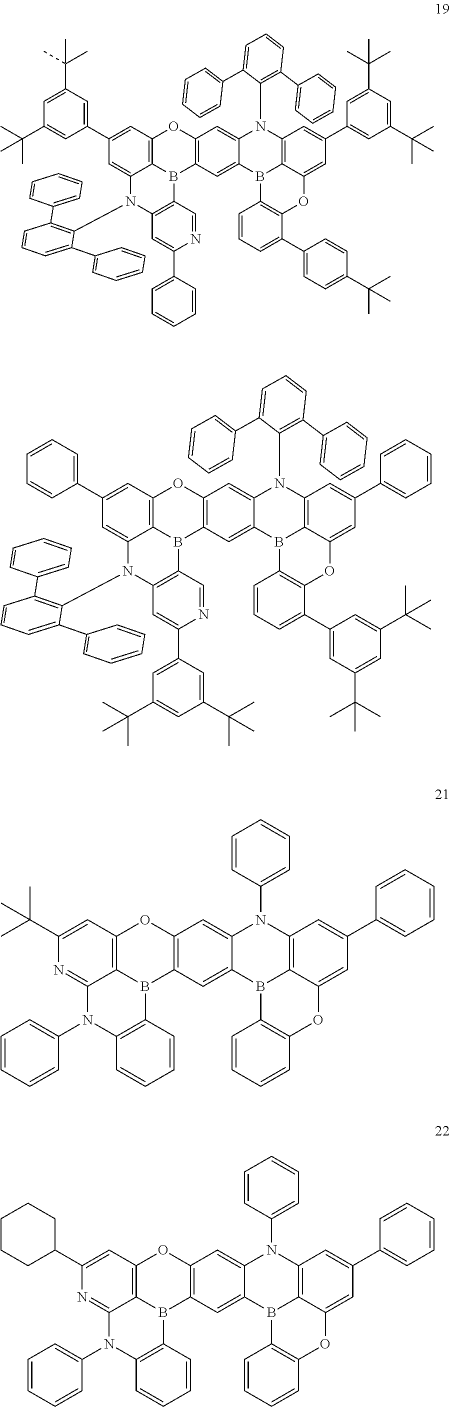

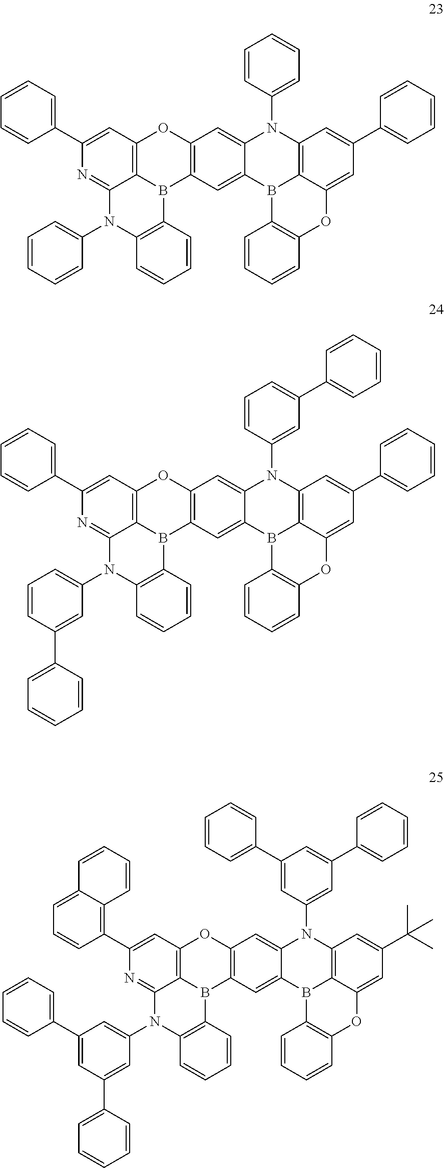 [SMILES: c1ccc(-c2cc3c4c(c2)N(c2ccccc2)c2cc5c(cc2B4c2ccccc2O3)B2c3ccccc3N(c3ccccc3)c3nc(-c4ccccc4)cc(c32)O5)cc1 ; c1ccc(-c2cccc(N3c4cc5c(cc4B4c6ccccc6Oc6cc(-c7ccccc7)cc3c64)B3c4ccccc4N(c4cccc(-c6ccccc6)c4)c4nc(-c6ccccc6)cc(c43)O5)c2)cc1 ; CC(C)(C)c1cc2c3c(c1)N(c1cc(-c4ccccc4)cc(-c4ccccc4)c1)c1cc4c(cc1B3c1ccccc1O2)B1c2ccccc2N(c2cc(-c3ccccc3)cc(-c3ccccc3)c2)c2nc(-c3cccc5ccccc35)cc(c21)O4]

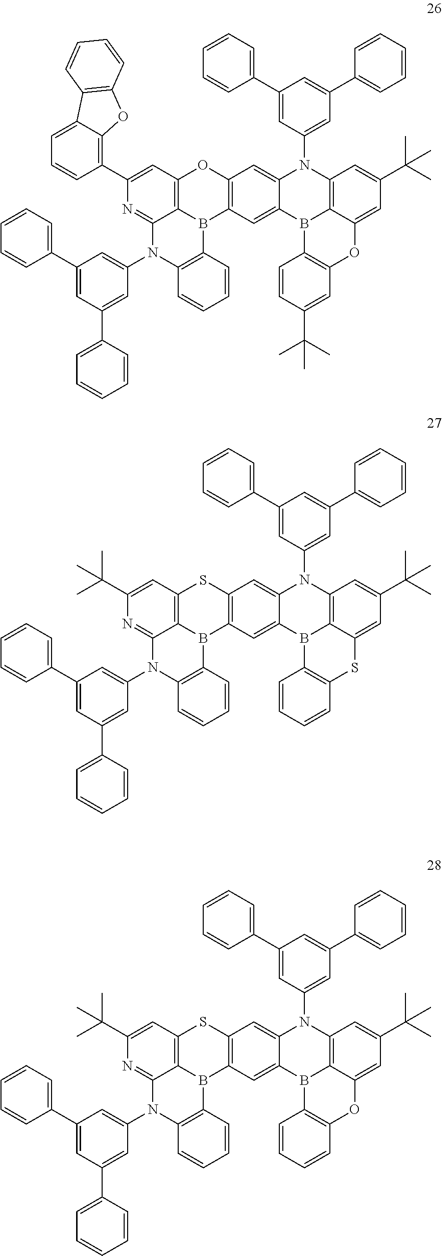 [SMILES: CC(C)(C)c1ccc2c(c1)Oc1cc(C(C)(C)C)cc3c1B2c1cc2c(cc1N3c1cc(-c3ccccc3)cc(-c3ccccc3)c1)Oc1cc(-c3cccc4c3oc3ccccc34)nc3c1B2c1ccccc1N3c1cc(-c2ccccc2)cc(-c2ccccc2)c1 ; CC(C)(C)c1cc2c3c(c1)N(c1cc(-c4ccccc4)cc(-c4ccccc4)c1)c1cc4c(cc1B3c1ccccc1S2)B1c2ccccc2N(c2cc(-c3ccccc3)cc(-c3ccccc3)c2)c2nc(C(C)(C)C)cc(c21)S4 ; CC(C)(C)c1cc2c3c(c1)N(c1cc(-c4ccccc4)cc(-c4ccccc4)c1)c1cc4c(cc1B3c1ccccc1O2)B1c2ccccc2N(c2cc(-c3ccccc3)cc(-c3ccccc3)c2)c2nc(C(C)(C)C)cc(c21)S4]

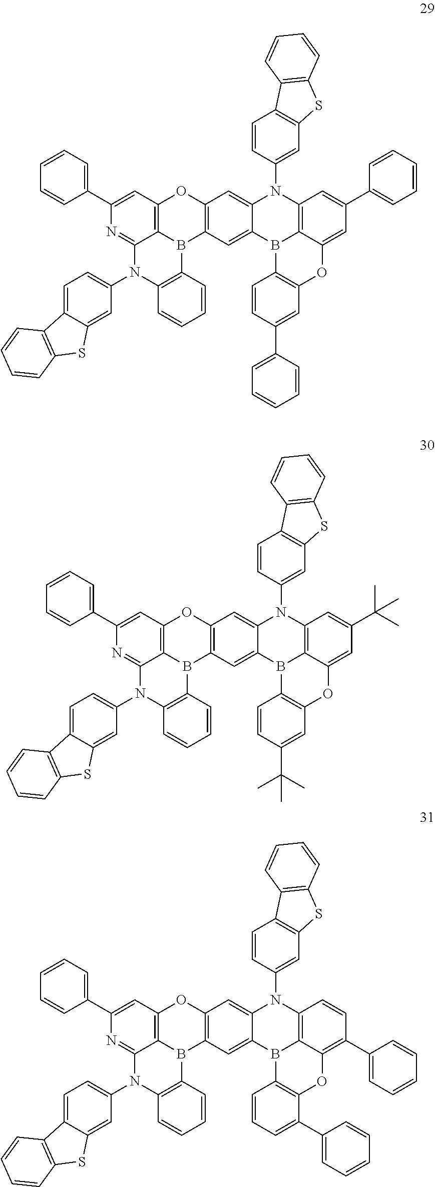 [SMILES: c1ccc(-c2ccc3c(c2)Oc2cc(-c4ccccc4)cc4c2B3c2cc3c(cc2N4c2ccc4c(c2)sc2ccccc24)Oc2cc(-c4ccccc4)nc4c2B3c2ccccc2N4c2ccc3c(c2)sc2ccccc23)cc1 ; CC(C)(C)c1ccc2c(c1)Oc1cc(C(C)(C)C)cc3c1B2c1cc2c(cc1N3c1ccc3c(c1)sc1ccccc13)Oc1cc(-c3ccccc3)nc3c1B2c1ccccc1N3c1ccc2c(c1)sc1ccccc12 ; c1ccc(-c2cc3c4c(n2)N(c2ccc5c(c2)sc2ccccc25)c2ccccc2B4c2cc4c(cc2O3)N(c2ccc3c(c2)sc2ccccc23)c2ccc(-c3ccccc3)c3c2B4c2cccc(-c4ccccc4)c2O3)cc1]

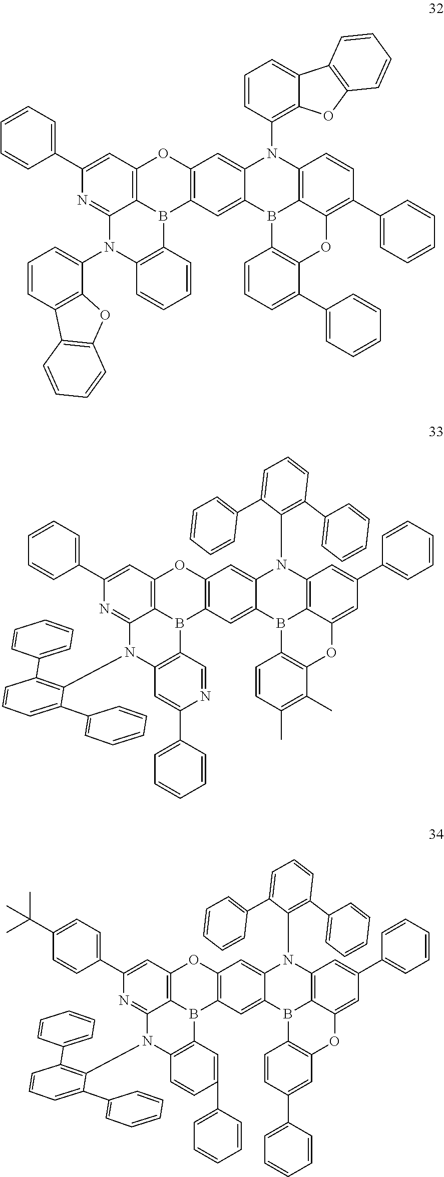 [SMILES: c1ccc(-c2cc3c4c(n2)N(c2cccc5c2oc2ccccc25)c2ccccc2B4c2cc4c(cc2O3)N(c2cccc3c2oc2ccccc23)c2ccc(-c3ccccc3)c3c2B4c2cccc(-c4ccccc4)c2O3)cc1 ; Cc1ccc2c(c1C)Oc1cc(-c3ccccc3)cc3c1B2c1cc2c(cc1N3c1c(-c3ccccc3)cccc1-c1ccccc1)Oc1cc(-c3ccccc3)nc3c1B2c1cnc(-c2ccccc2)cc1N3c1c(-c2ccccc2)cccc1-c1ccccc1 ; CC(C)(C)c1ccc(-c2cc3c4c(n2)N(c2c(-c5ccccc5)cccc2-c2ccccc2)c2ccc(-c5ccccc5)cc2B4c2cc4c(cc2O3)N(c2c(-c3ccccc3)cccc2-c2ccccc2)c2cc(-c3ccccc3)cc3c2B4c2ccc(-c4ccccc4)cc2O3)cc1]

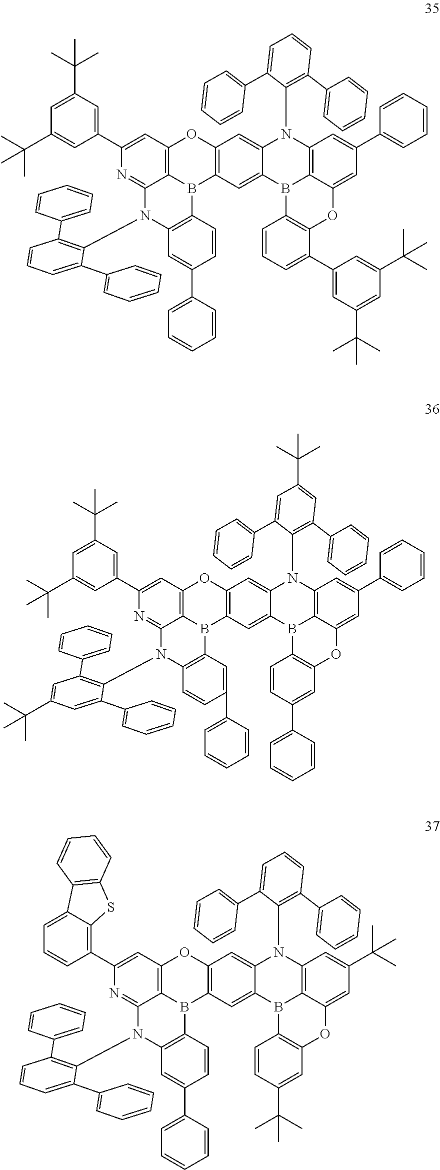

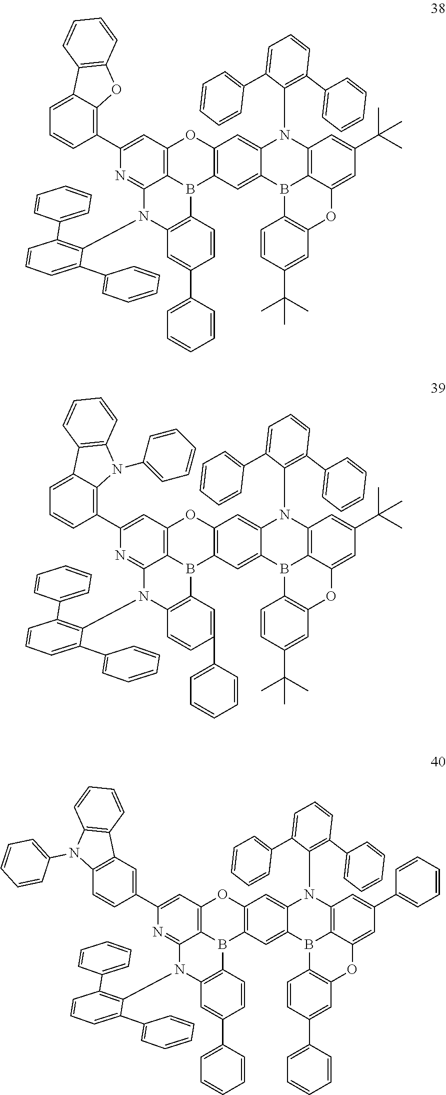

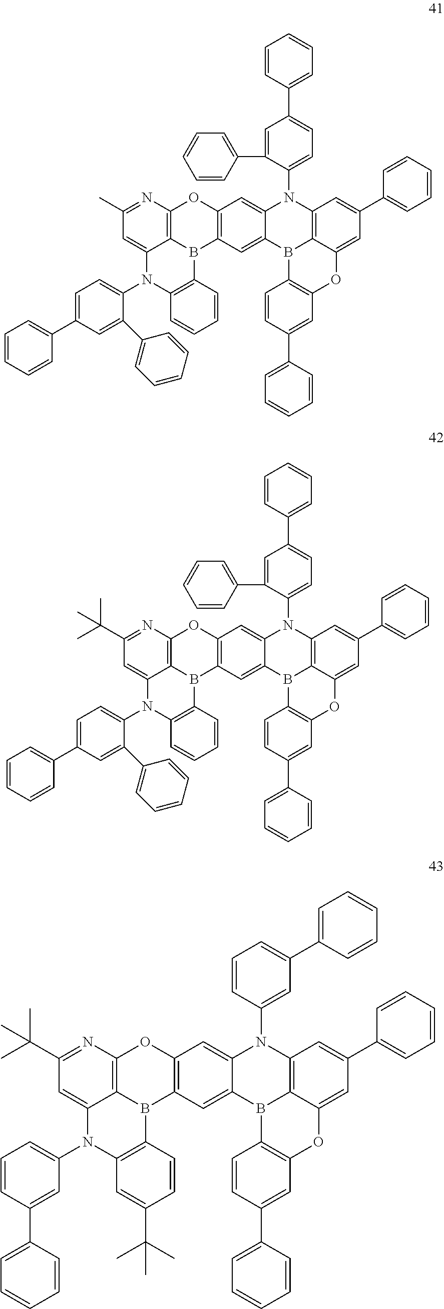 [SMILES: Cc1cc2c3c(n1)Oc1cc4c(cc1B3c1ccccc1N2c1ccc(-c2ccccc2)cc1-c1ccccc1)B1c2ccc(-c3ccccc3)cc2Oc2cc(-c3ccccc3)cc(c21)N4c1ccc(-c2ccccc2)cc1-c1ccccc1 ; CC(C)(C)c1cc2c3c(n1)Oc1cc4c(cc1B3c1ccccc1N2c1ccc(-c2ccccc2)cc1-c1ccccc1)B1c2ccc(-c3ccccc3)cc2Oc2cc(-c3ccccc3)cc(c21)N4c1ccc(-c2ccccc2)cc1-c1ccccc1 ; CC(C)(C)c1ccc2c(c1)N(c1cccc(-c3ccccc3)c1)c1cc(C(C)(C)C)nc3c1B2c1cc2c(cc1O3)N(c1cccc(-c3ccccc3)c1)c1cc(-c3ccccc3)cc3c1B2c1ccc(-c2ccccc2)cc1O3]

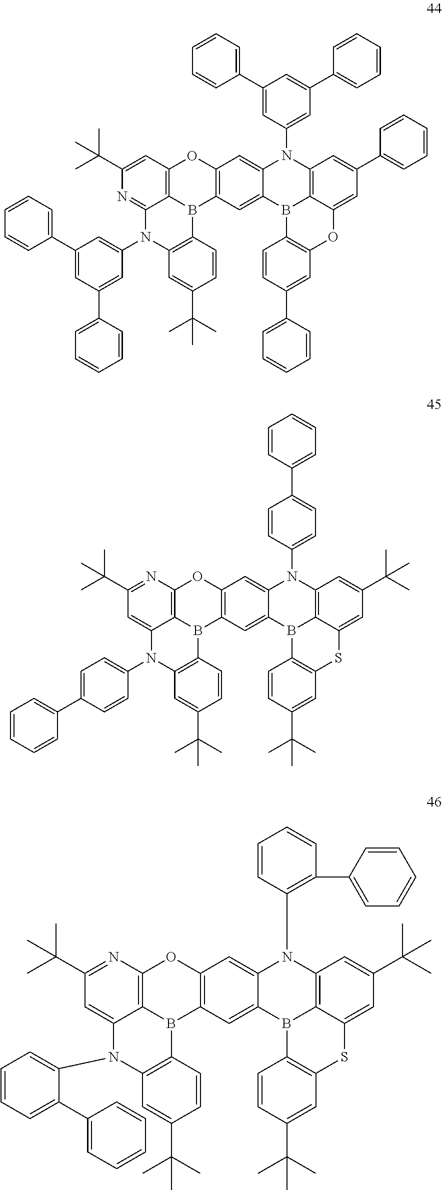 [SMILES: CC(C)(C)c1ccc2c(c1)N(c1cc(-c3ccccc3)cc(-c3ccccc3)c1)c1nc(C(C)(C)C)cc3c1B2c1cc2c(cc1O3)N(c1cc(-c3ccccc3)cc(-c3ccccc3)c1)c1cc(-c3ccccc3)cc3c1B2c1ccc(-c2ccccc2)cc1O3 ; CC(C)(C)c1ccc2c(c1)Sc1cc(C(C)(C)C)cc3c1B2c1cc2c(cc1N3c1ccc(-c3ccccc3)cc1)Oc1nc(C(C)(C)C)cc3c1B2c1ccc(C(C)(C)C)cc1N3c1ccc(-c2ccccc2)cc1 ; CC(C)(C)c1ccc2c(c1)Sc1cc(C(C)(C)C)cc3c1B2c1cc2c(cc1N3c1ccccc1-c1ccccc1)Oc1nc(C(C)(C)C)cc3c1B2c1ccc(C(C)(C)C)cc1N3c1ccccc1-c1ccccc1]

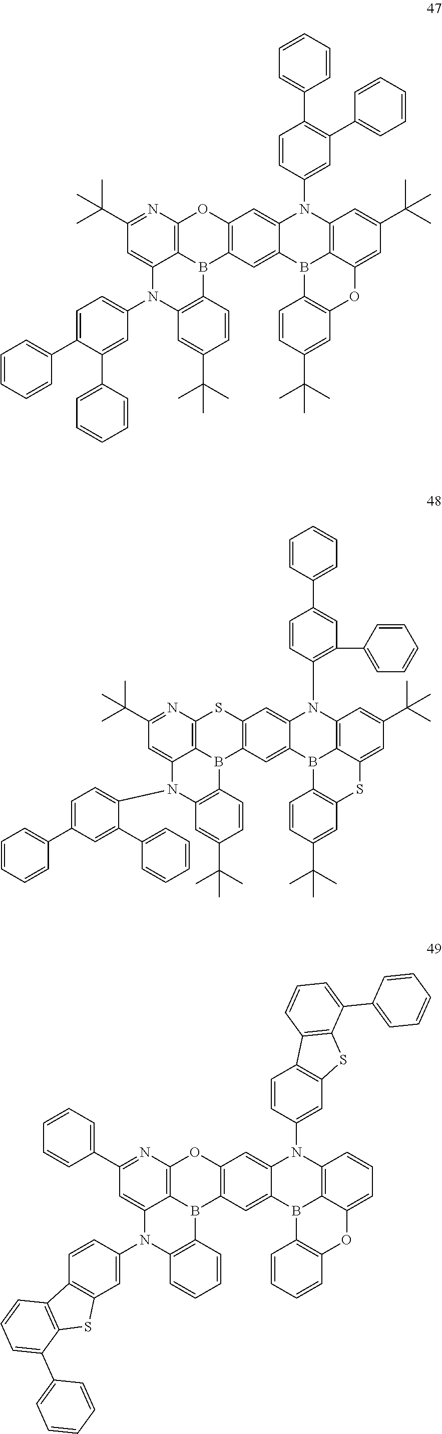 [SMILES: CC(C)(C)c1ccc2c(c1)Oc1cc(C(C)(C)C)cc3c1B2c1cc2c(cc1N3c1ccc(-c3ccccc3)c(-c3ccccc3)c1)Oc1nc(C(C)(C)C)cc3c1B2c1ccc(C(C)(C)C)cc1N3c1ccc(-c2ccccc2)c(-c2ccccc2)c1 ; CC(C)(C)c1ccc2c(c1)Sc1cc(C(C)(C)C)cc3c1B2c1cc2c(cc1N3c1ccc(-c3ccccc3)cc1-c1ccccc1)Sc1nc(C(C)(C)C)cc3c1B2c1ccc(C(C)(C)C)cc1N3c1ccc(-c2ccccc2)cc1-c1ccccc1 ; c1ccc(-c2cc3c4c(n2)Oc2cc5c(cc2B4c2ccccc2N3c2ccc3c(c2)sc2c(-c4ccccc4)cccc23)B2c3ccccc3Oc3cccc(c32)N5c2ccc3c(c2)sc2c(-c4ccccc4)cccc23)cc1]

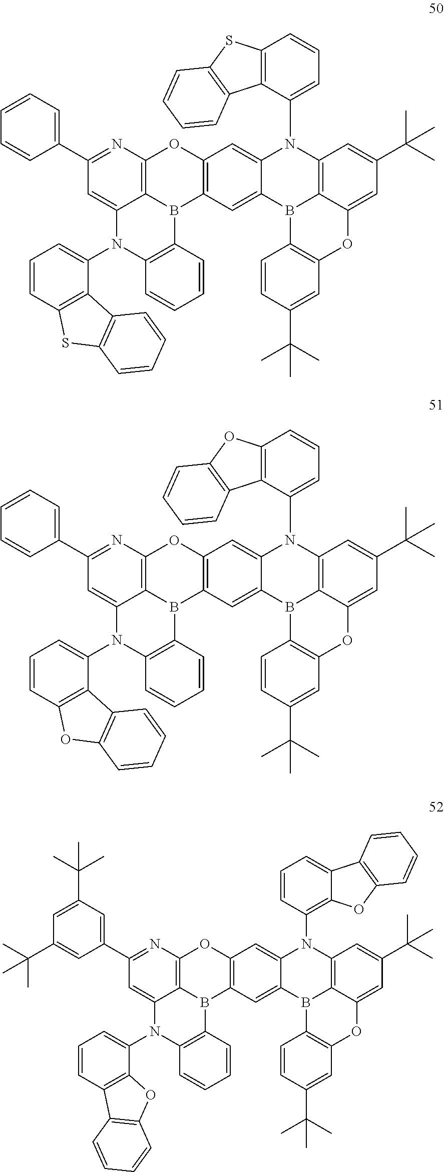

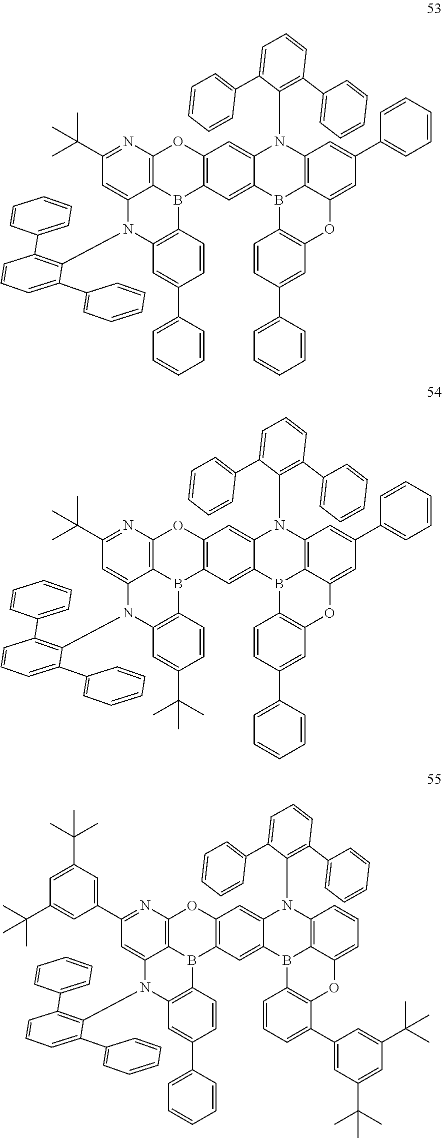

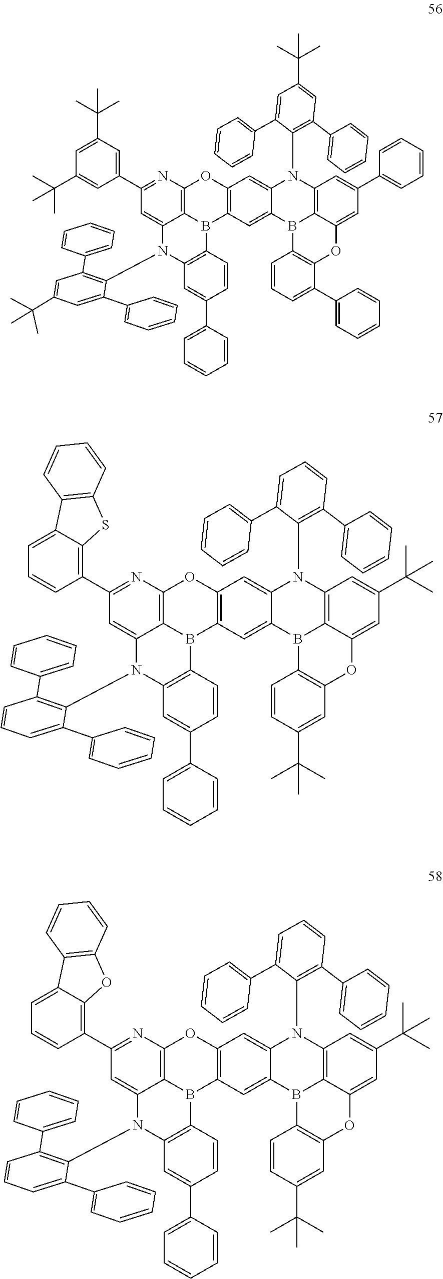

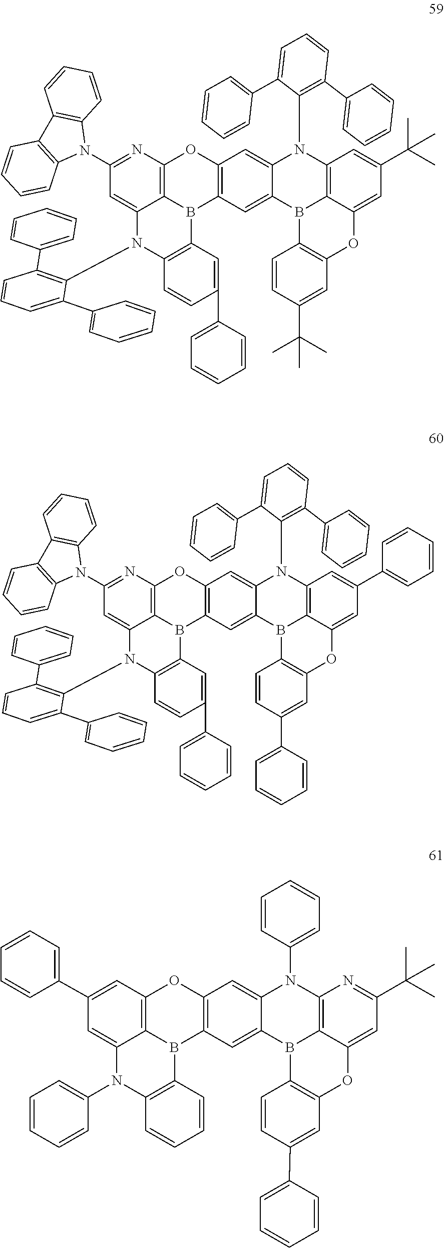 [SMILES: CC(C)(C)c1ccc2c(c1)Oc1cc(C(C)(C)C)cc3c1B2c1cc2c(cc1N3c1c(-c3ccccc3)cccc1-c1ccccc1)Oc1nc(-n3c4ccccc4c4ccccc43)cc3c1B2c1cc(-c2ccccc2)ccc1N3c1c(-c2ccccc2)cccc1-c1ccccc1 ; c1ccc(-c2ccc3c(c2)Oc2cc(-c4ccccc4)cc4c2B3c2cc3c(cc2N4c2c(-c4ccccc4)cccc2-c2ccccc2)Oc2nc(-n4c5ccccc5c5ccccc54)cc4c2B3c2cc(-c3ccccc3)ccc2N4c2c(-c3ccccc3)cccc2-c2ccccc2)cc1 ; CC(C)(C)c1cc2c3c(n1)N(c1ccccc1)c1cc4c(cc1B3c1ccc(-c3ccccc3)cc1O2)B1c2ccccc2N(c2ccccc2)c2cc(-c3ccccc3)cc(c21)O4]

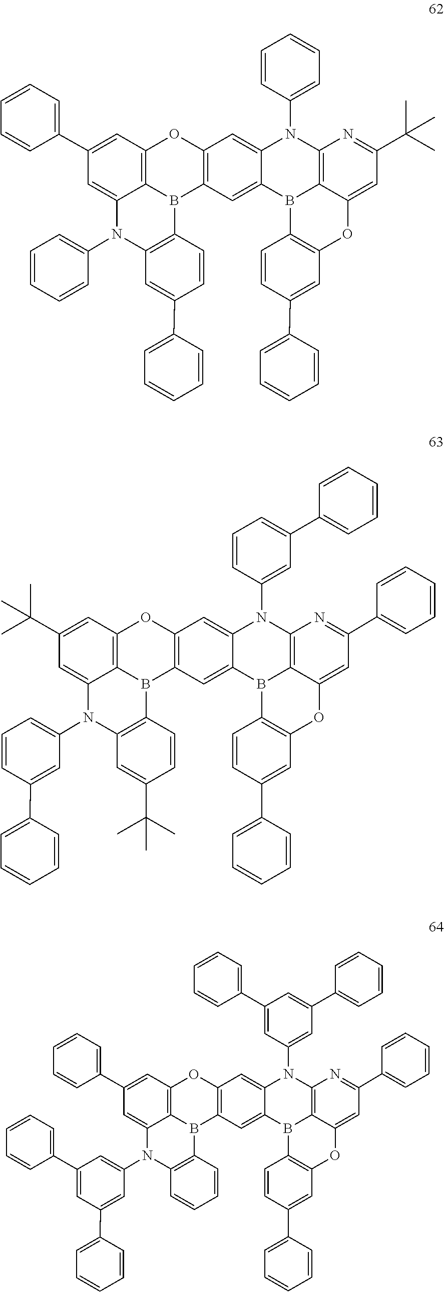 [SMILES: CC(C)(C)c1cc2c3c(n1)N(c1ccccc1)c1cc4c(cc1B3c1ccc(-c3ccccc3)cc1O2)B1c2ccc(-c3ccccc3)cc2N(c2ccccc2)c2cc(-c3ccccc3)cc(c21)O4 ; CC(C)(C)c1ccc2c(c1)N(c1cccc(-c3ccccc3)c1)c1cc(C(C)(C)C)cc3c1B2c1cc2c(cc1O3)N(c1cccc(-c3ccccc3)c1)c1nc(-c3ccccc3)cc3c1B2c1ccc(-c2ccccc2)cc1O3 ; c1ccc(-c2cc(-c3ccccc3)cc(N3c4ccccc4B4c5cc6c(cc5Oc5cc(-c7ccccc7)cc3c54)N(c3cc(-c4ccccc4)cc(-c4ccccc4)c3)c3nc(-c4ccccc4)cc4c3B6c3ccc(-c5ccccc5)cc3O4)c2)cc1]

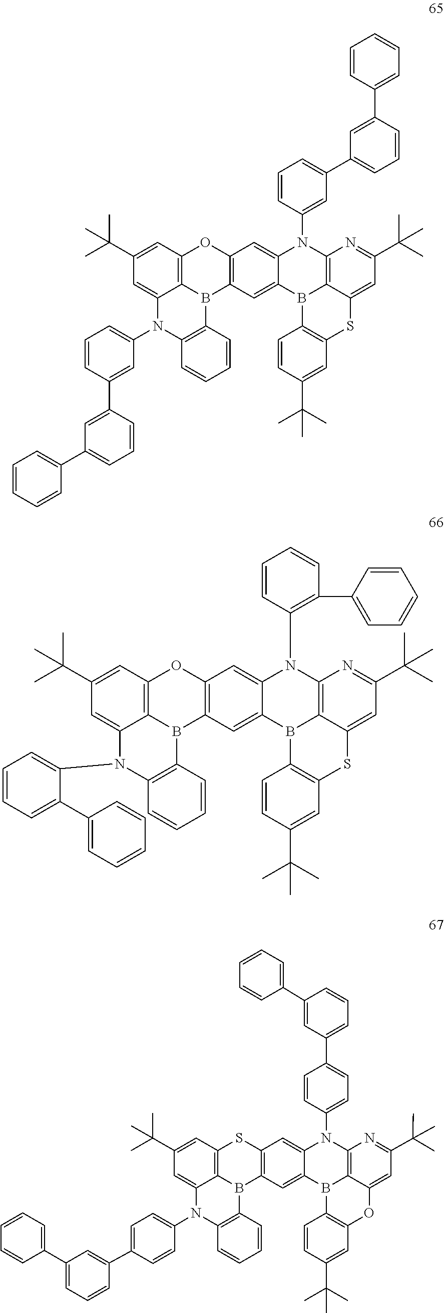 [SMILES: CC(C)(C)c1ccc2c(c1)Sc1cc(C(C)(C)C)nc3c1B2c1cc2c(cc1N3c1cccc(-c3cccc(-c4ccccc4)c3)c1)Oc1cc(C(C)(C)C)cc3c1B2c1ccccc1N3c1cccc(-c2cccc(-c3ccccc3)c2)c1 ; CC(C)(C)c1ccc2c(c1)Sc1cc(C(C)(C)C)nc3c1B2c1cc2c(cc1N3c1ccccc1-c1ccccc1)Oc1cc(C(C)(C)C)cc3c1B2c1ccccc1N3c1ccccc1-c1ccccc1 ; CC(C)(C)c1ccc2c(c1)Oc1cc(C(C)(C)C)nc3c1B2c1cc2c(cc1N3c1ccc(-c3cccc(-c4ccccc4)c3)cc1)Sc1cc(C(C)(C)C)cc3c1B2c1ccccc1N3c1ccc(-c2cccc(-c3ccccc3)c2)cc1]

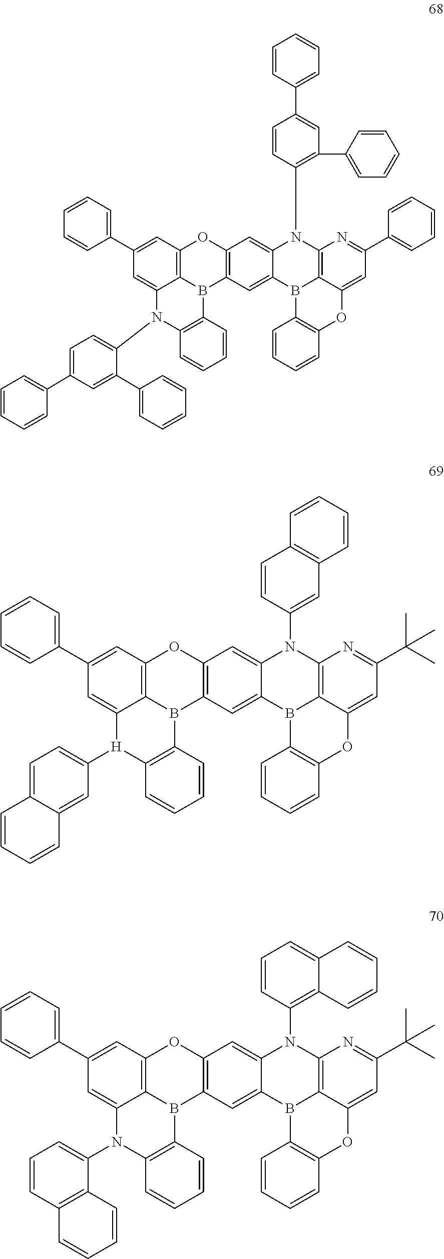

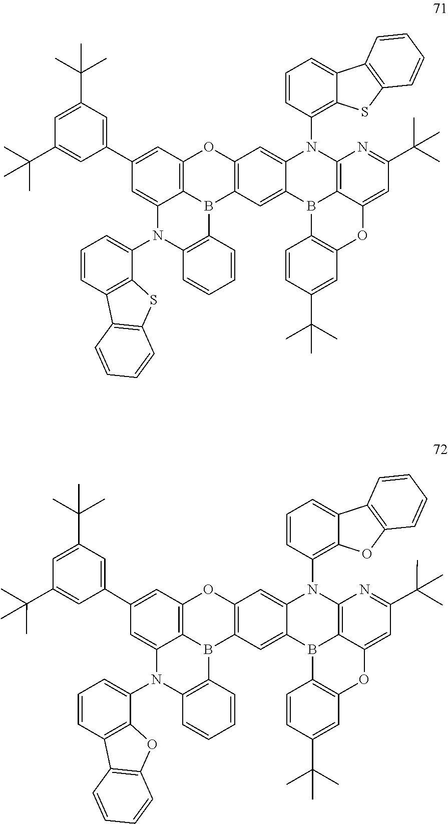

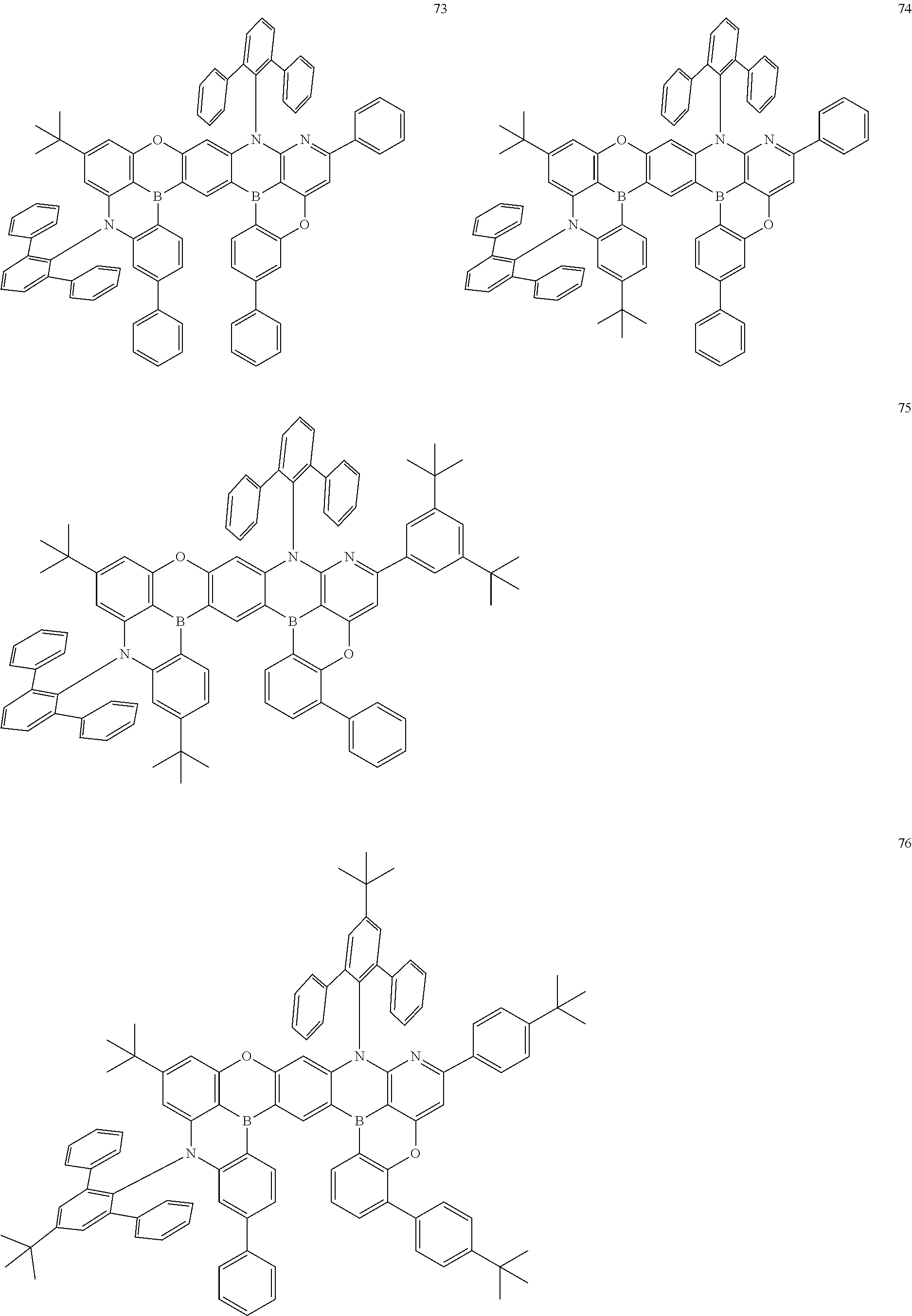

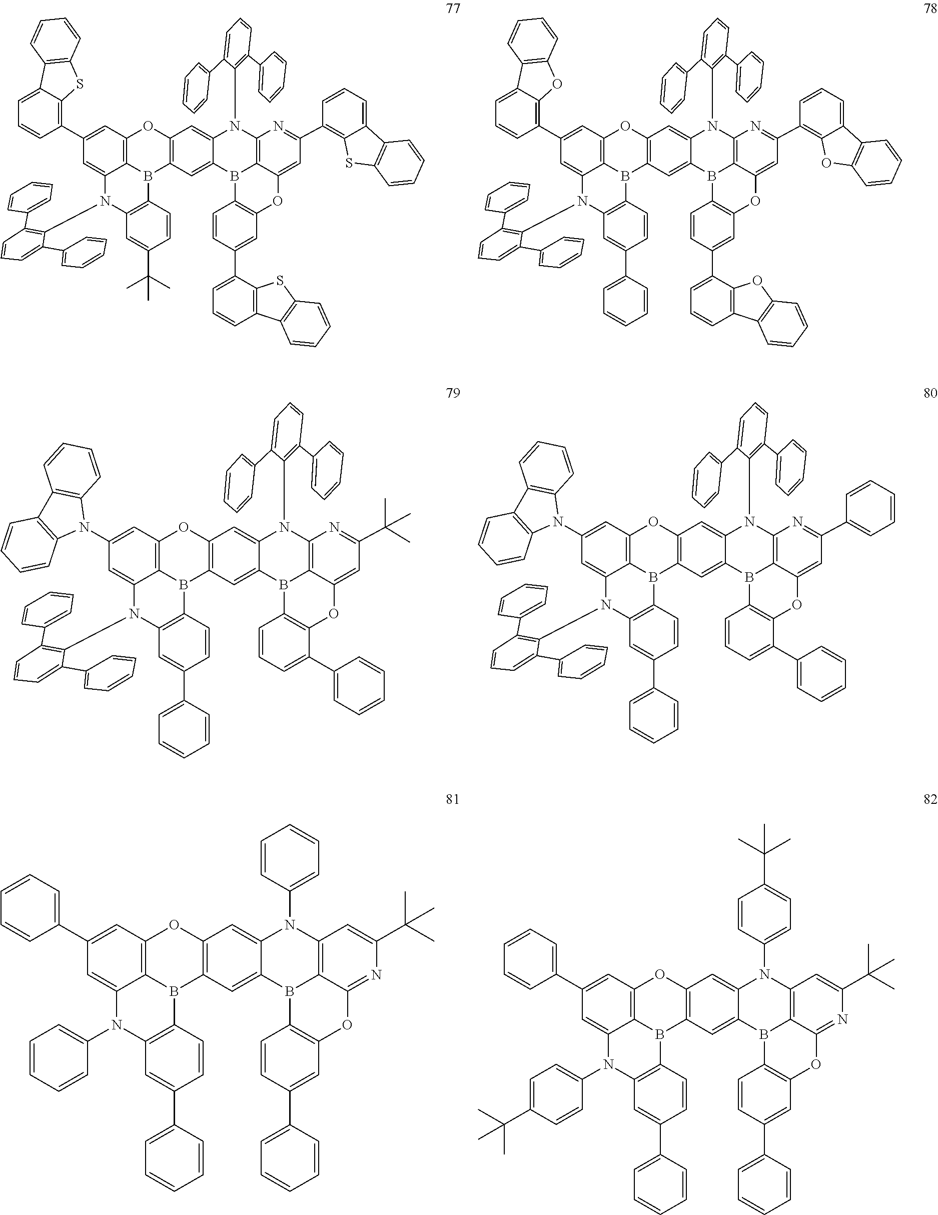

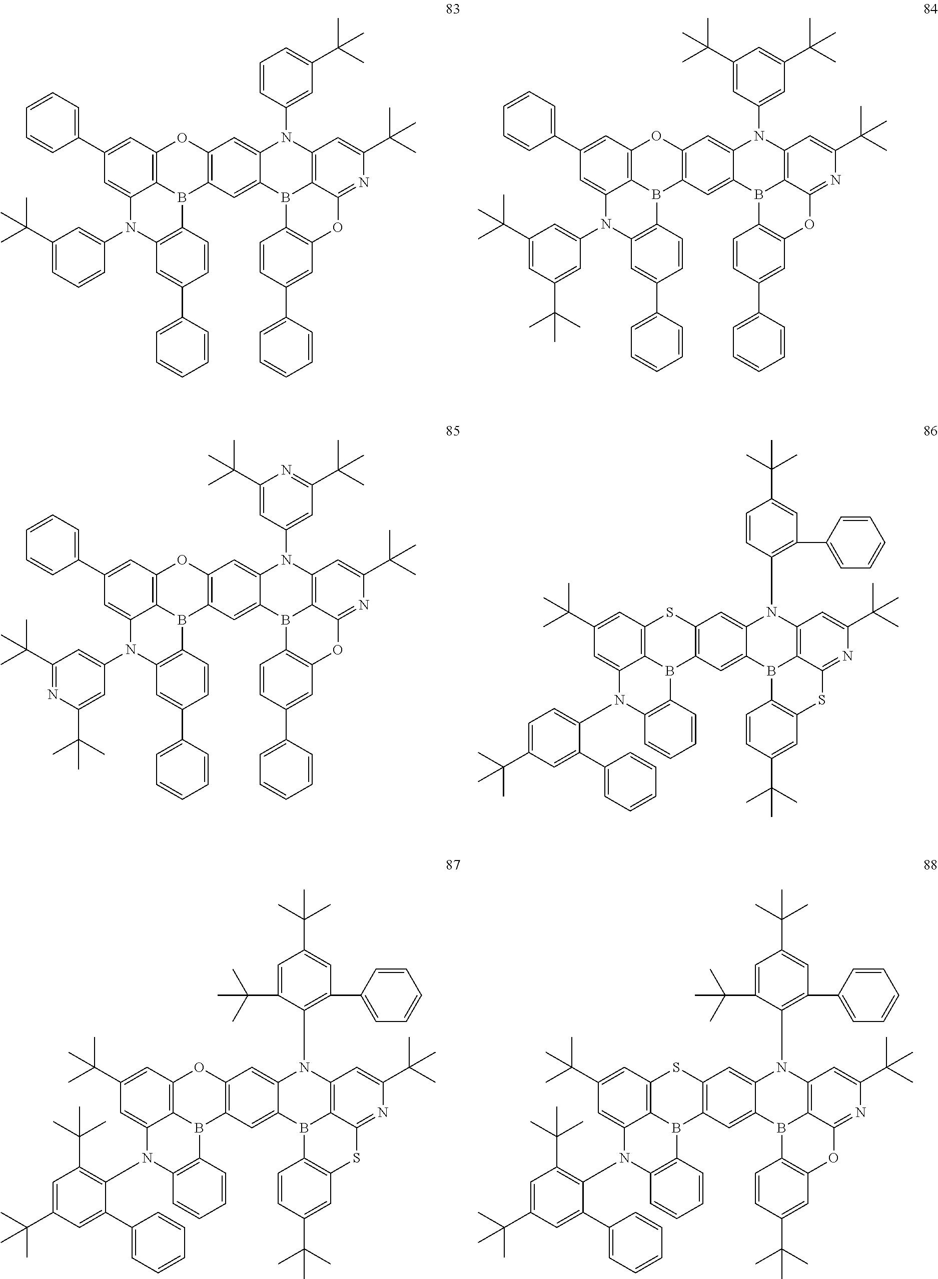

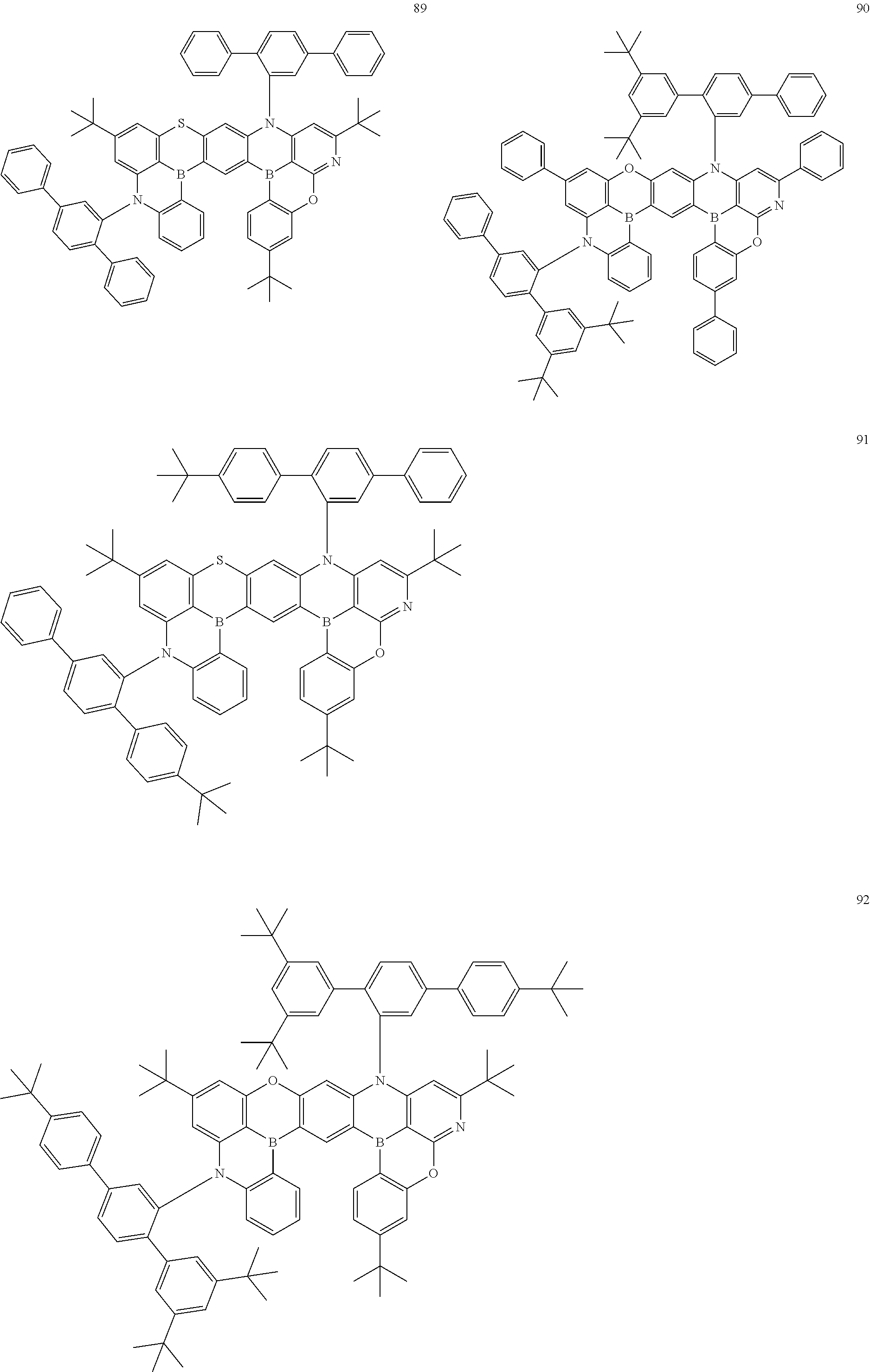

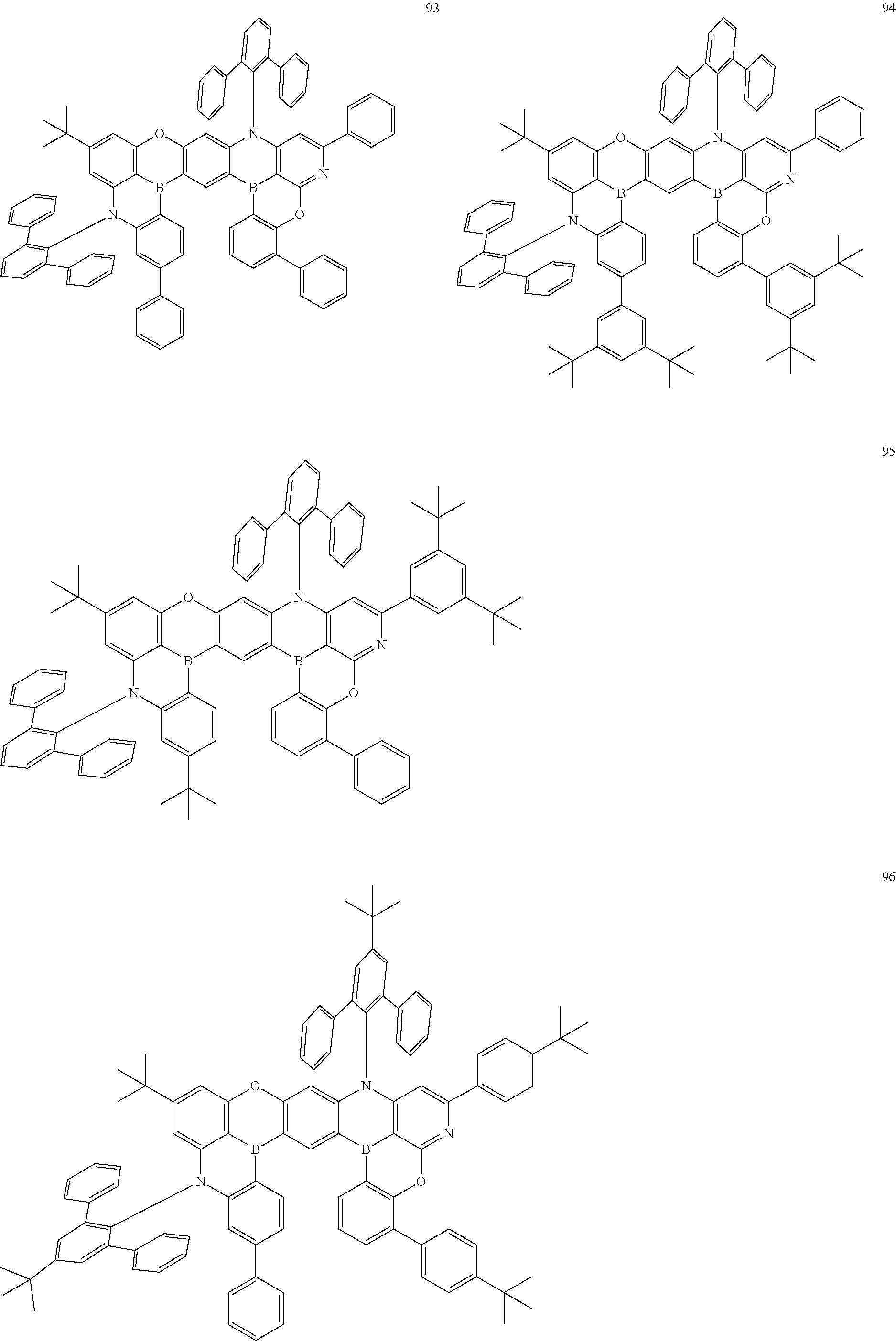

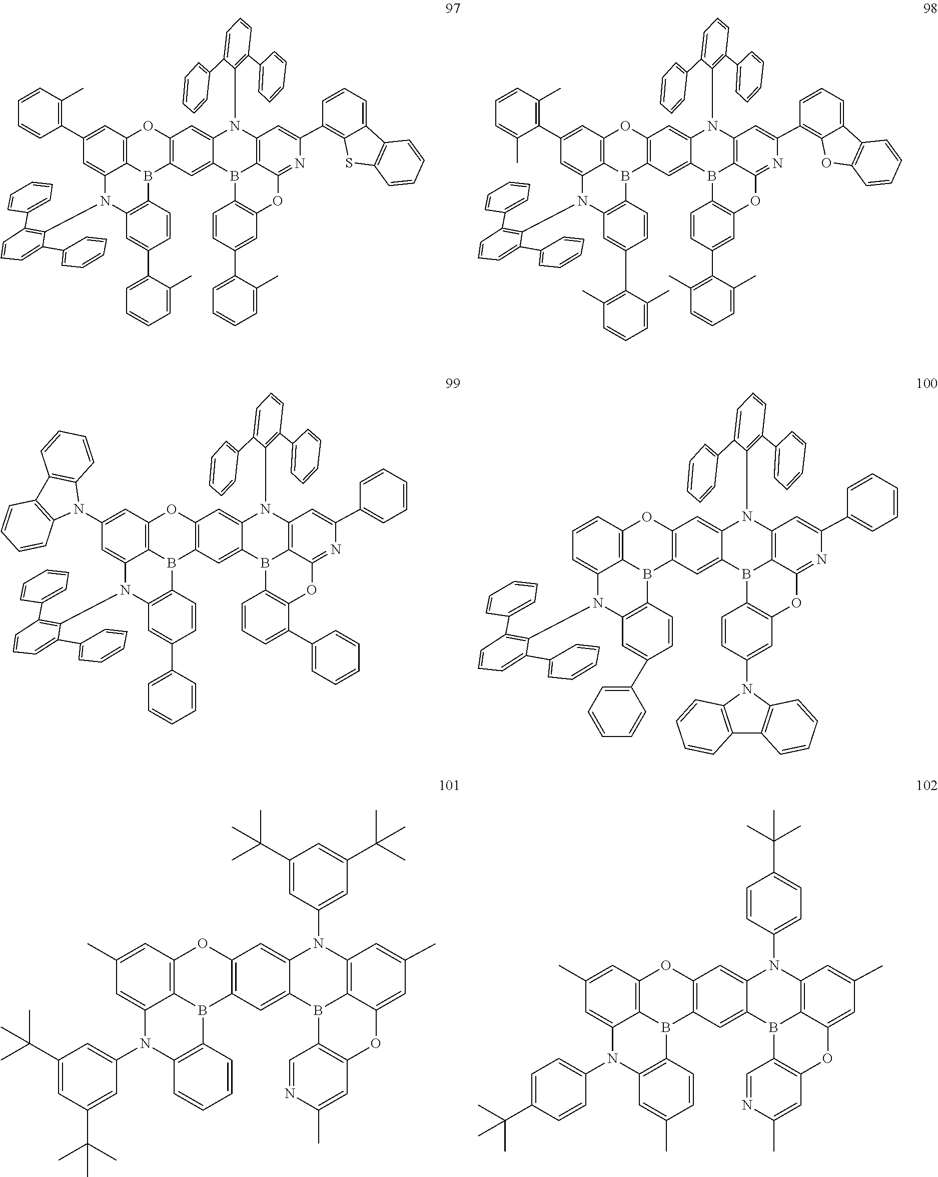

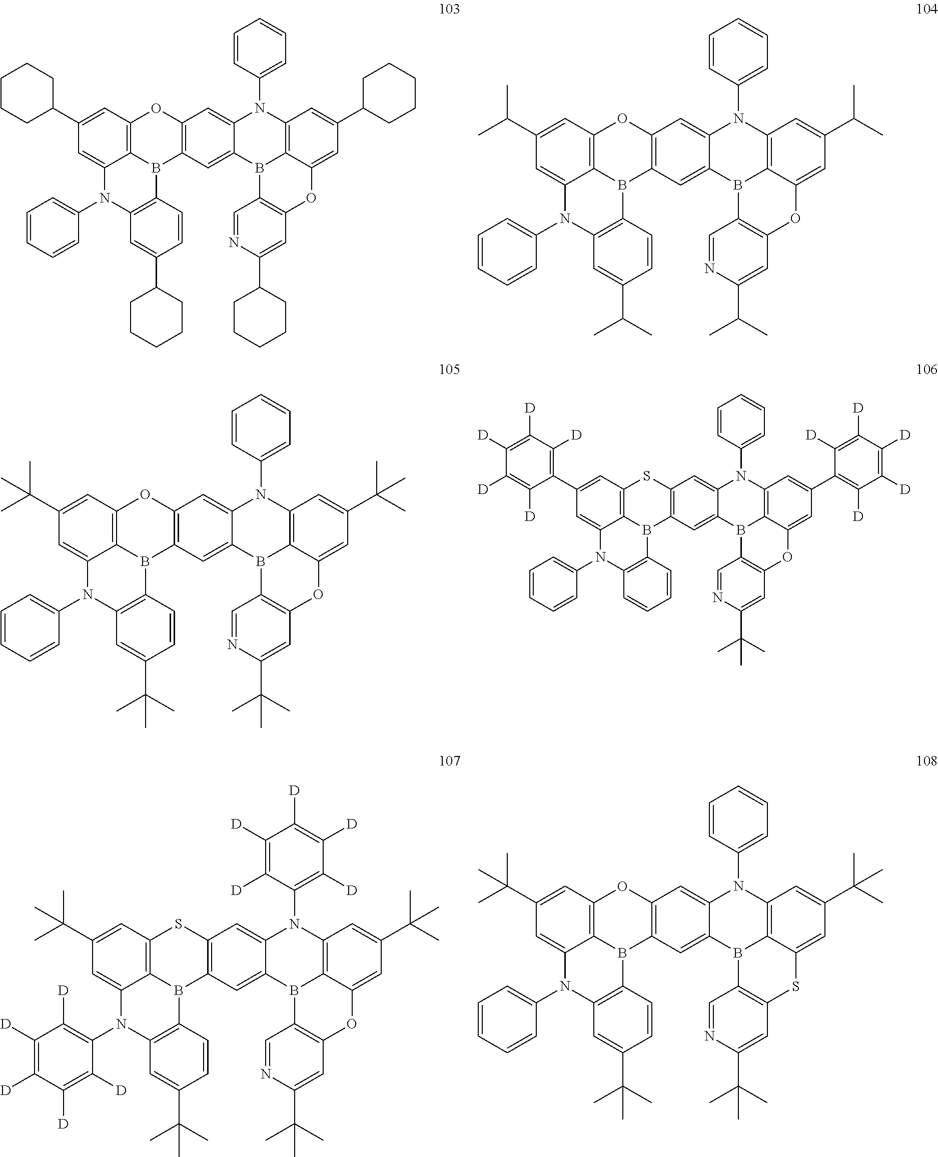

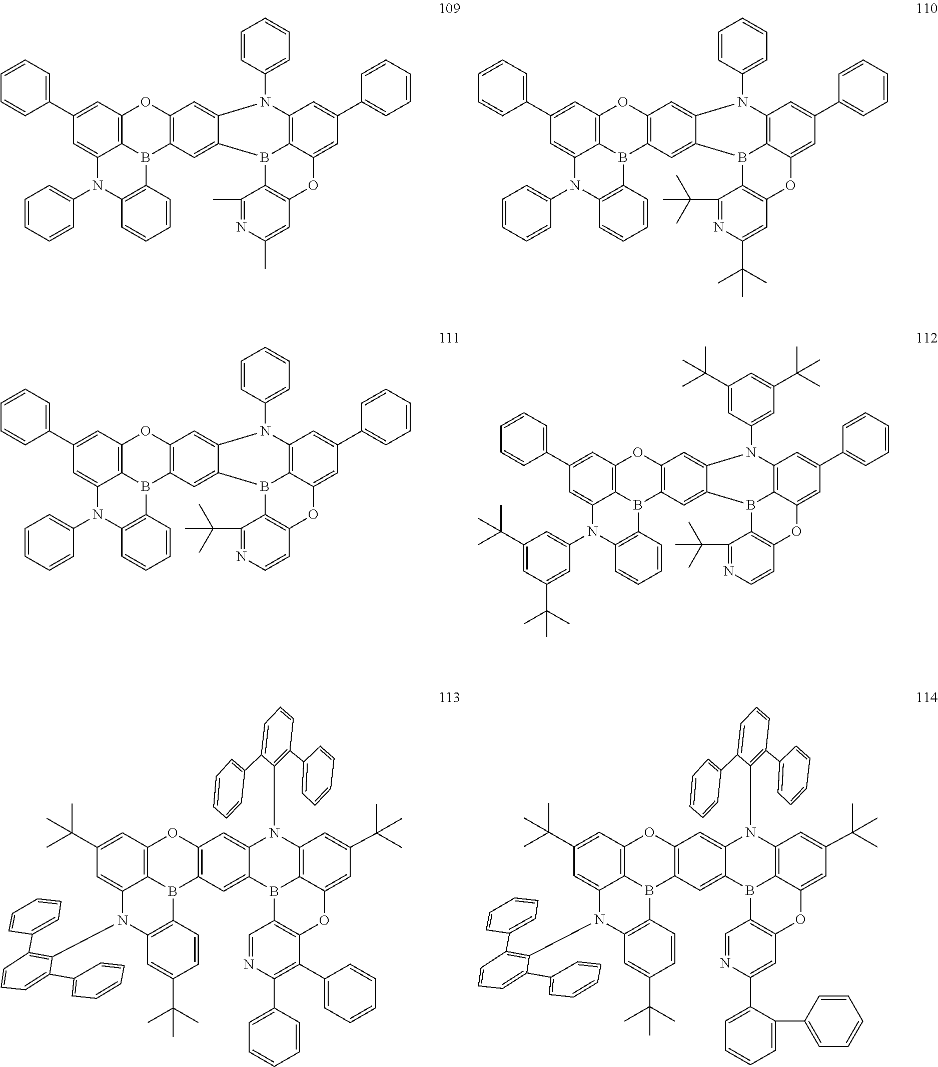

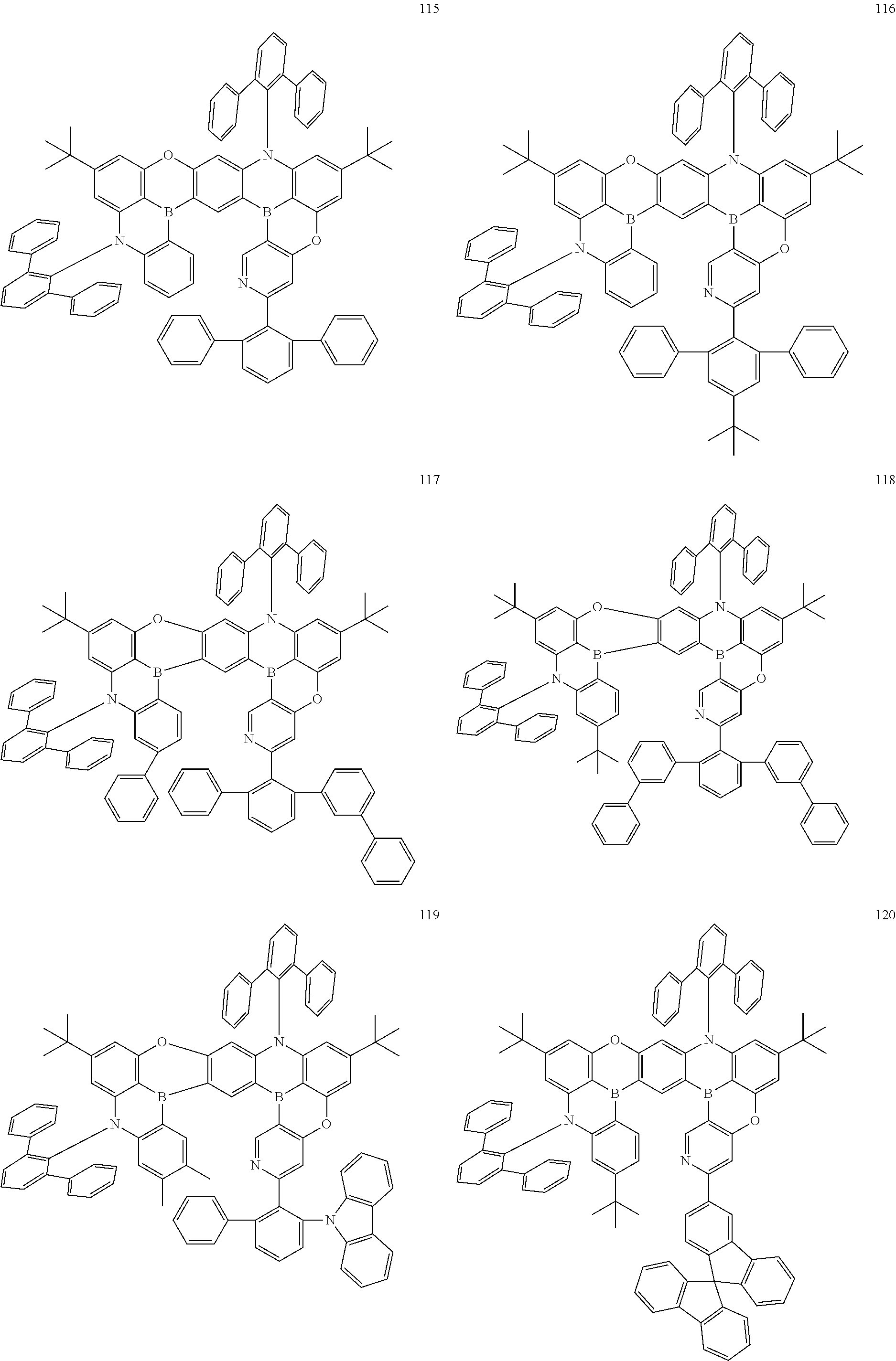

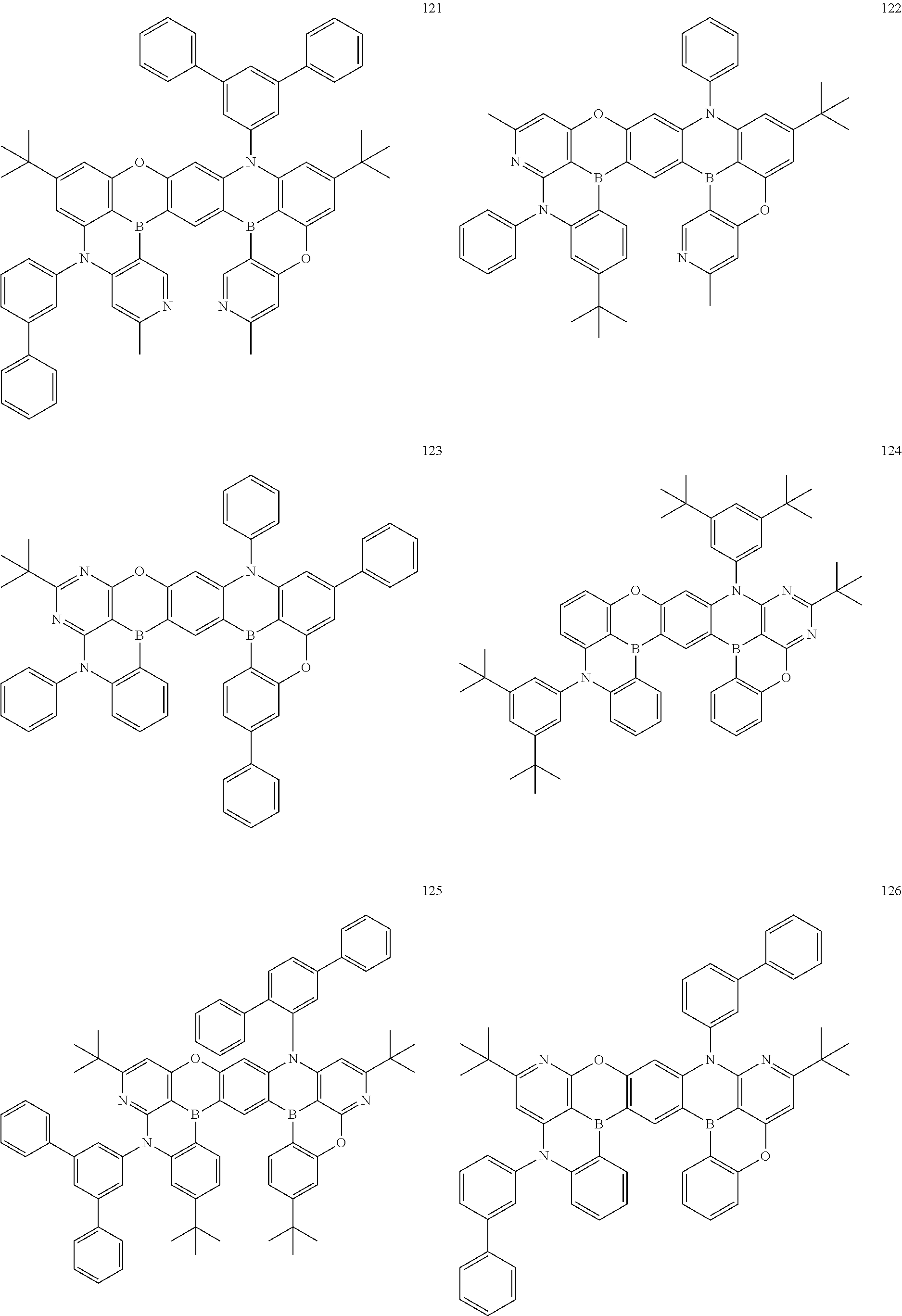

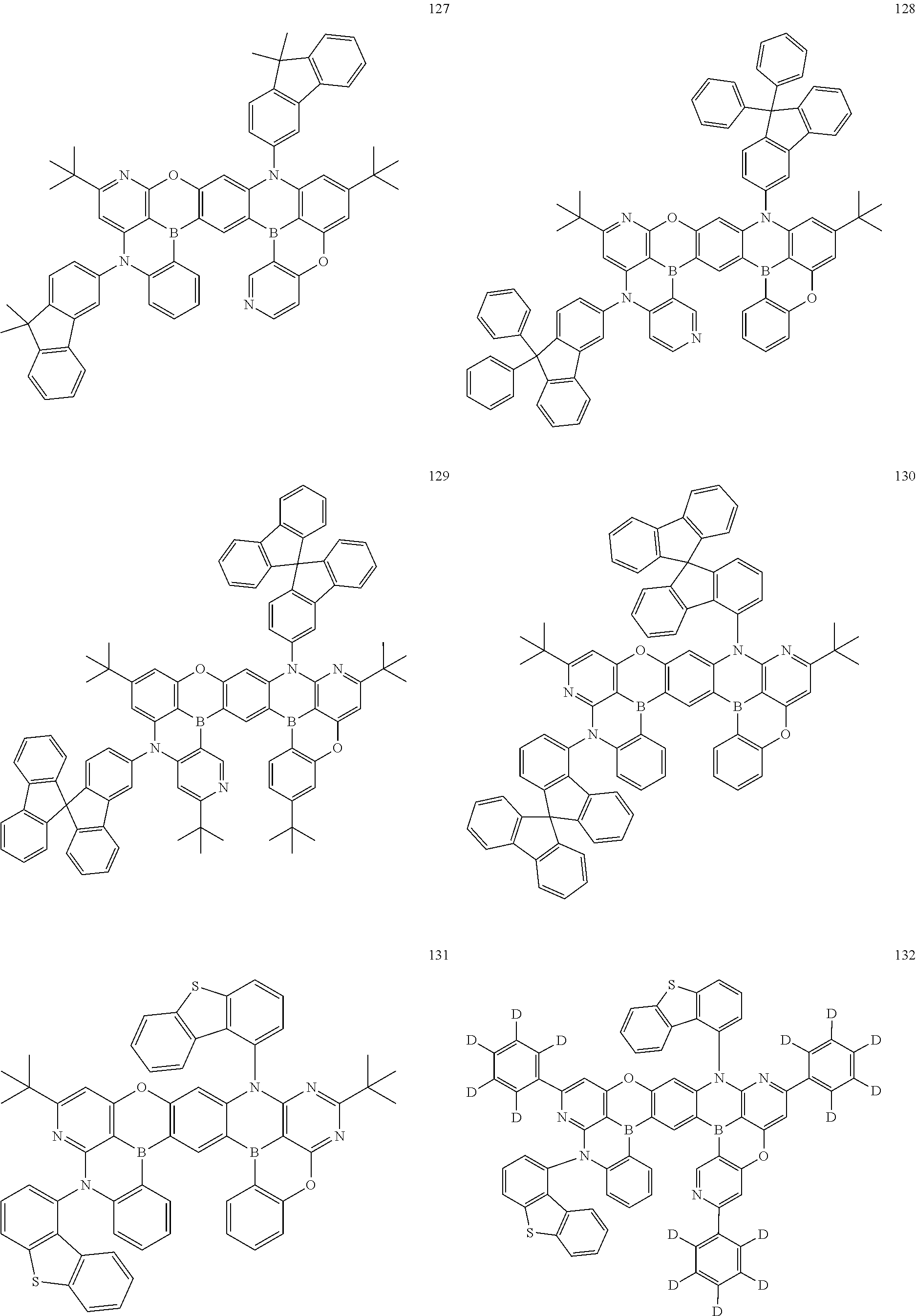

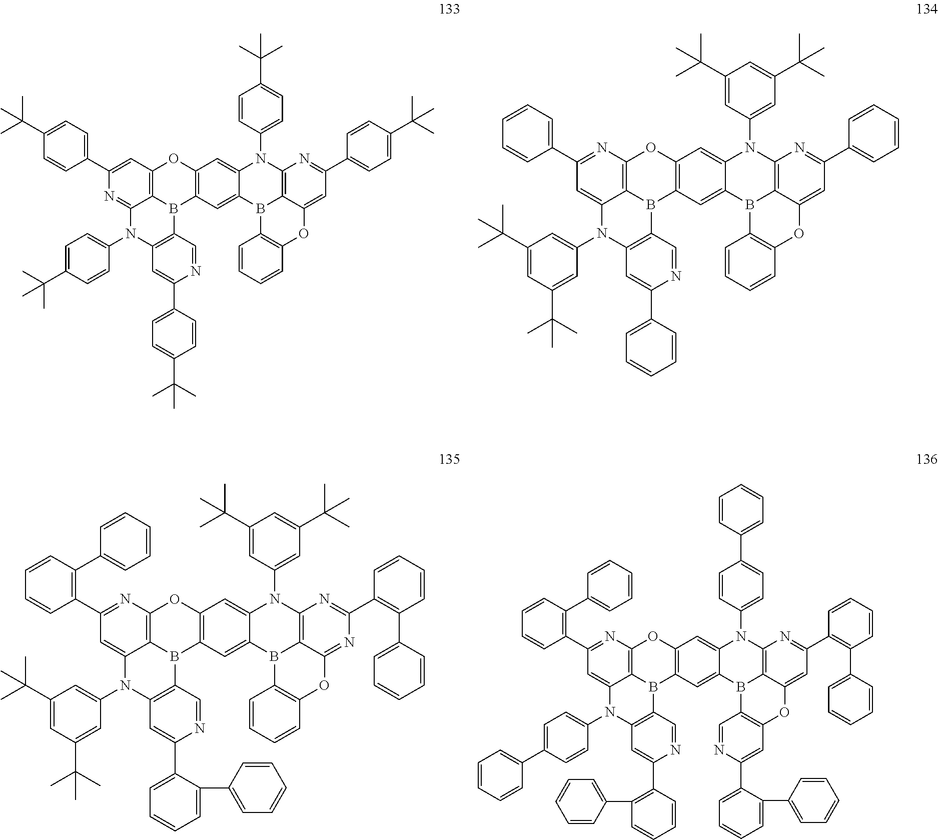

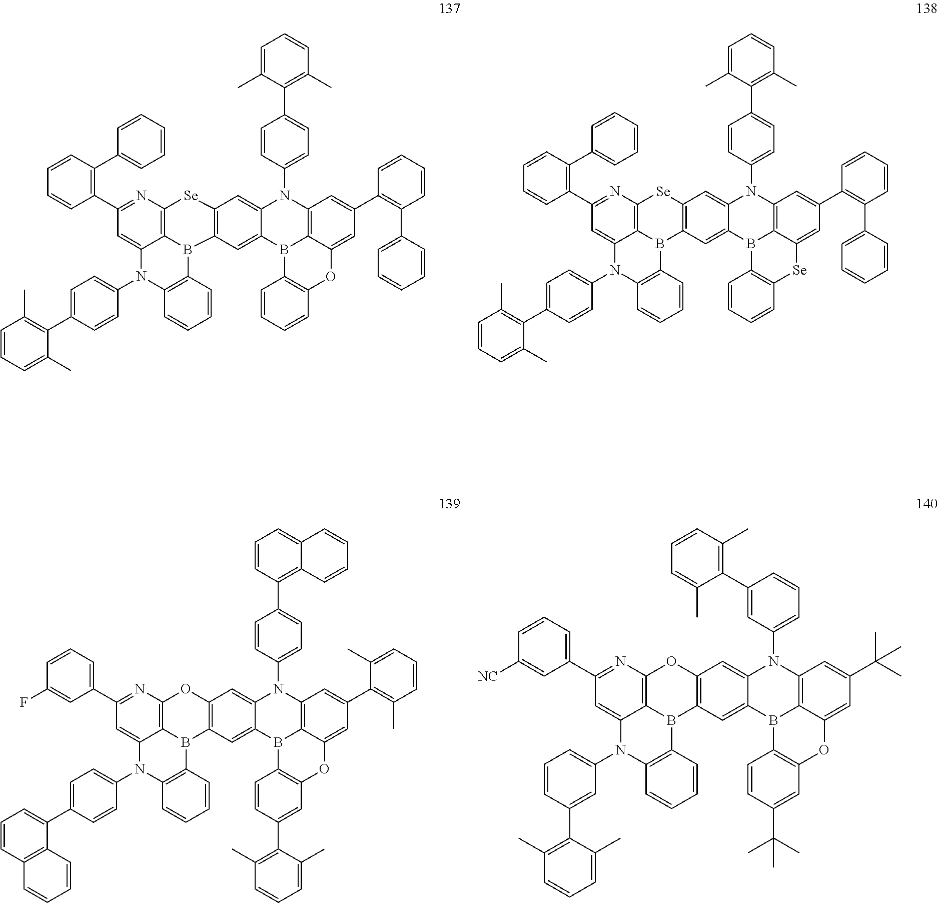

The left-hand structural formula shown below, as included in some of the compounds described above, is identical to the right-hand structural formula. That is, both represent the same functional group. This also applies in cases where both functional groups include the same substituents at the same positions.

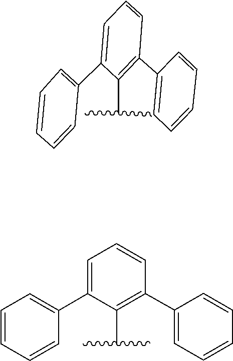

According to embodiments, the polycyclic compound may be used as a thermally activated delayed fluorescence (TADF) dopant.

The polycyclic compound may have a narrow half-width due to the enhanced multiple resonance effect, thereby providing improved color purity.

According to embodiments, the polycyclic compound may be used as a blue light-emitting dopant.

In some embodiments, a maximum emission central wavelength of the blue light may be, e.g., in a range from 440 nm to 480 nm, from 450 nm to 470 nm, or from 450 nm to 460 nm.

In some embodiments, an emission fullwidth at half maximum of the blue light may be 30 nm or less, 28 nm or less, 25 nm or less, from 10 nm to 30 nm, or from 10 nm to 28 nm.

### Light-Emitting Device

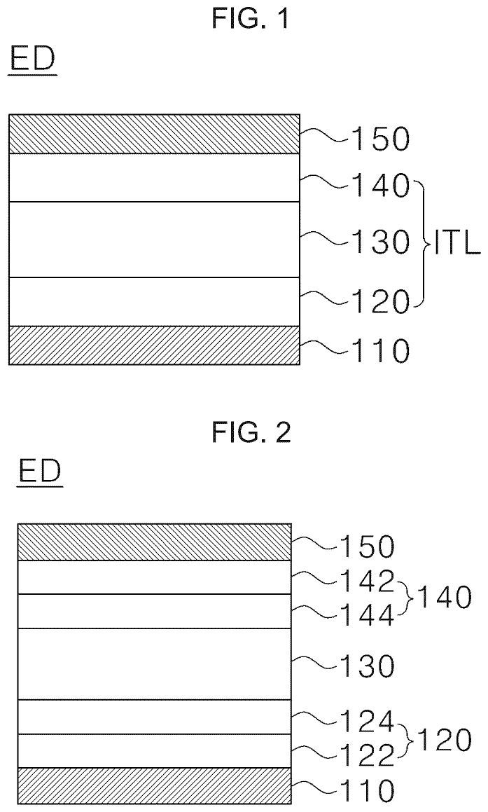

FIGS. 1 to 6 are schematic cross-sectional views illustrating light-emitting devices in accordance with example embodiments.

Referring to FIG. 1, a light-emitting device ED may include a first electrode 110, a second electrode 150, and an emission layer 130 interposed between the first electrode 110 and the second electrode 150. The emission layer 130 may include at least one selected from the polycyclic compounds represented by Chemical Formula 1 as described above.

Accordingly, the light-emitting device may have improved color properties, luminous efficiency and life-span properties.

The light-emitting device ED may include the first electrode 110, the second electrode 150, and an intermediate layer ITL including the emission layer 130 between the first electrode 110 and the second electrode 150. The intermediate layer ITL may further include a hole transfer region 120 and an electron transfer region 140.

In some embodiments, a plurality of the emission layers may be between the first electrode 110 and the second electrode 150, and a charge generation layer may be between adjacent emission layers.

The light-emitting device ED may include two or more light-emitting structures each of which may include the emission layer between the first electrode 110 and the second electrode 150. The light-emitting structure may include, e.g., a stacked structure of the hole transfer region 120, the emission layer 130 and the electron transfer region 140. The charge generation layer may include, e.g., a p-type charge generation layer and/or an n-type charge generation layer.

In some embodiments, the light-emitting device ED may be alight-emitting device of a tandem structure which may include m light-emitting structures (m is an integer of 2 or more) between the first electrode 110 and the second electrode 150, and (m−1) charge generation layers between the adjacent light-emitting structures.

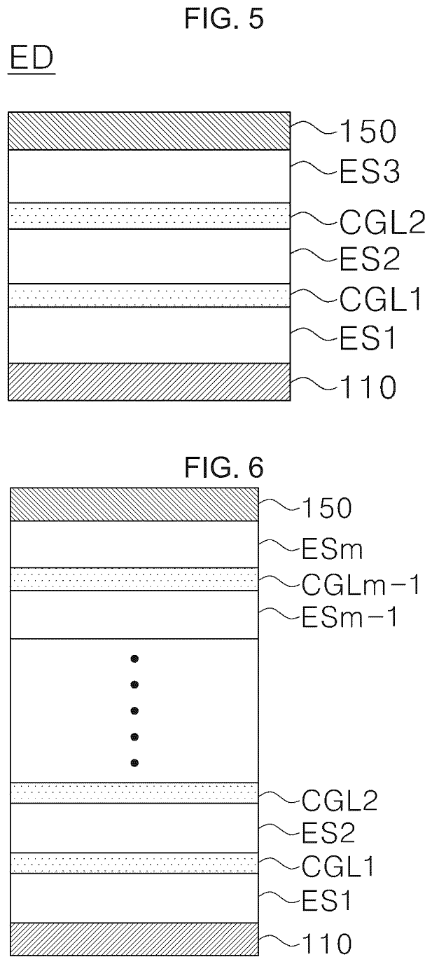

In FIG. 5, a 3-stack tandem structure including three light-emitting structures is provided, but the light-emitting device ED may have a tandem structure of a 2-stack, 4-stack, 5-stack or more stacks.

In some embodiments, the polycyclic compound may be provided as a thermally activated delayed fluorescence (TADF) dopant, a host for a phosphorescent device, or a fluorescent host.

The plurality of the emission layers may include the polycyclic compound, and the polycyclic compound may serve as the TADF dopant. For example, the plurality of the emission layers may include at least one selected from the polycyclic compounds represented by Chemical Formula 1-1 to 1-6.

Accordingly, color properties, luminous efficiency and life-span properties of the light-emitting device ED may be further improved.

The first electrode 110 may be an anode or a cathode. In some embodiments, the first electrode 110 may serve as an anode, and may serve as a pixel electrode. In embodiments, the first electrode 110 may include a conductive material (e.g., an electrically conductive material) having a high work function that promotes hole injection.

In an embodiment, the first electrode 110 may be a transmissive electrode. The first electrode 110 may include a transparent conductive oxide such as indium tin oxide (ITO), indium zinc oxide (IZO), zinc oxide (ZnO), indium tin zinc oxide (ITZO), and/or the like.

In an embodiment, the first electrode 110 may be a translucent electrode or a reflective electrode. The first electrode 110 may include at least one selected from Ag, Mg, Cu, Al, Pt, Pd, Au, Ni, Nd, Ir, Cr, Li, Ca, Mo, Ti, W, In, Sn, Zn, and an alloy or a compound (e.g., LiF) containing at least one therefrom. For example, the first electrode 110 may include Li, Ca, LiF/Ca (a stacked structure of LiF and Ca), LiF/Al (a stacked structure of LiF and Al), a mixture of Ag and Mg, and/or the like.

The first electrode 110 may have a single-layered structure or a multi-layered structure. For example, the first electrode 110 may have a triple-layered structure of ITO/Ag/ITO.

A thickness of the first electrode 110 may be in a range of 700 Å to 10,000 Å. For example, the thickness of the first electrode 110 may be in a range of 1,000 Å to 3,000 Å.

The second electrode 150 may be a cathode or an anode. In some embodiments, the second electrode 150 may serve as an electron injection electrode or as a cathode. The second electrode 150 may include a metal, an alloy, an electrically conductive compound, and/or the like, having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or the like. The second electrode 150 may include one selected from the aforementioned materials, or a combination thereof.

The second electrode 150 may be a transmissive electrode, a translucent electrode, or a reflective electrode. The second electrode 150 may have a single-layered structure or a multi-layered structure.

The emission layer 130 may include a host and a dopant.

The emission layer 130 may include at least one selected from the polycyclic compounds represented by Chemical Formula 1 described above.

In some embodiments, the polycyclic compound may include at least one selected from the compounds represented by the above-described Chemical Formula 1-1.

The emission layer 130 may include the above-described polycyclic compound as the dopant.

In a non-limiting example, the emission layer 130 may include the dopant in an amount of 0.01 parts by weight to 15.00 parts by weight, or 0.01 parts by weight to 12.00 parts by weight, based on 100 parts by weight of the host.

The emission layer 130 may emit a red light, a green light, a blue light and/or a white light. For example, the emission layer 130 may emit a blue light.

In some embodiments, the emission layer 130 may emit a light having a maximum emission central wavelength in a range from 430 nm to 490 nm. The maximum emission central wavelength may be, e.g., in a range from 430 nm to 490 nm, from 440 nm to 480 nm, from 440 nm to 465 nm, or from 445 nm to 460 nm.

In some embodiments, a emission half width (full width at half maximum) of the blue light may be 30 nm or less, 28 nm or less, 25 nm or less, from 10 nm to 30 nm, or from 10 nm to 28 nm.

The emission layer 130 may further include a host material and/or a dopant as described below.

For example, the emission layer 130 may include any suitable host material generally available in the art, such as an anthracene derivative, a pyrene derivative, a fluoranthene derivative, a chrysene derivative, a dihydrobenzanthracene derivative, a triphenylene derivative, and/or the like.

In some embodiments, the emission layer 130 may include, e.g., a host material represented by Chemical Formula FH. For example, the compound represented by Chemical Formula FH may be used as a fluorescent host material.

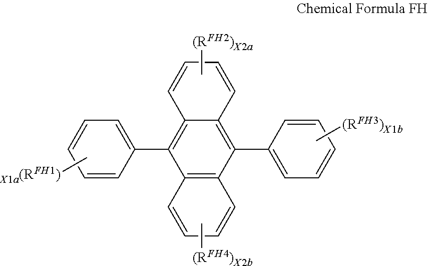

In Chemical Formula FH, R^{FH1} to R^{FH4} may each independently be a hydrogen atom, a deuterium atom, a halogen atom, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₃₀ aryl group, a substituted or unsubstituted C₆-C₃₀ heteroaryl group, or a cyclic group formed through a combination thereof. In an embodiment, in Chemical Formula FH, at least one selected from R^{FH1} to R^{FH4} may form a condensed ring with a bonded benzene ring.

In Chemical Formula FH, x1a and x1b may each independently be an integer from 0 to 5; and x2a and x2b may each independently be an integer from 0 to 4. When x1a, x1b, x2a, and x2b are each 2 or more, two or more of each of R^{FH1} to R^{FH4} may be the same as or different from each other.

In some embodiments, the emission layer 130 may include, e.g., a host material represented by Chemical Formula PH. For example, the compound represented by Chemical Formula PH may be used as a host material for a phosphorescent device.

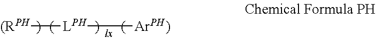

In Chemical Formula PH, R^{PH} may be a substituted or unsubstituted carbazole group. L^{PH} may be a direct linkage (e.g., a single covalent bond), a substituted or unsubstituted C₆-C₃₀ arylene group, or a substituted or unsubstituted C₂-C₃₀ heteroarylene group. Ar^{PH} may be a substituted or unsubstituted C₆-C₃₀ aryl group, or a substituted or unsubstituted C₂-C₃₀ heteroaryl group.

As described above in the definition of terminology, the term “C₆-C₃₀ aryl group” may encompass a group in which a plurality of aryl rings are condensed or bonded through a cyclic group (e.g., an alicyclic hydrocarbon ring). For example, a C₆-C₃₀ aryl group may include a fluorenyl group.

As described above in the definition of terminology, the term “C₂-C₃₀ heteroaryl group” may encompass a group in which a plurality of aryl rings are condensed or bonded through a heterocyclic ring. For example, a C₂-C₃₀ heteroaryl group may include a carbazole group, a dibenzofuran group, a dibenzothiophene group, and/or the like. In an embodiment, a C₂-C₃₀ heteroaryl group may be a group in which a plurality of aryl rings are condensed or bonded to each other through the same or different heterocyclic rings.

In an embodiment, a substituent included in Ar^{PH} may be a silyl group represented by —Si(R^{sa})(R^{sb})(R^{sc}); and R^{sa}, R^{sb}, and R^{sc} may each independently be hydrogen, halogen, a hydroxyl group, a C₁-C₆₀ alkyl group, a C₁-C₆₀ alkoxy group, a C₆-C₆₀ aryl group, or a C₂-C₃₀ heteroaryl group. At least one selected from R^{sa}, R^{sb}, and R^{sc} may be a C₆-C₆₀ aryl group or a C₂-C₃₀ heteroaryl group. For example, R^{sa}, R^{sb} and R^{sc} may each independently be a C₆-C₆₀ aryl group or a C₂-C₃₀ heteroaryl group.

In Chemical Formula PH, Ix may be an integer from 0 to 10. When Ix is 2 or more, two or more of L^{PH} may be the same as or different from each other.

The emission layer 130 may include, e.g., BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl) dibenzo[b,d]furan), TCTA (4,4′,4″-tris(carbazol-9-yl)-triphenylamine), TPBi (1,3,5-tris(1-phenyl-1H-benzo[d]imidazole-2-yl)benzene), Alq3 (tris(8-hydroxyquinolino) aluminum), ADN (9,10-di(naphthalene-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), and/or the like, as a host material.

In an embodiment, in the emission layer 130, the host may include one selected from the materials as described above, or any suitable combination thereof.

Non-limiting examples of the host material are as follows.

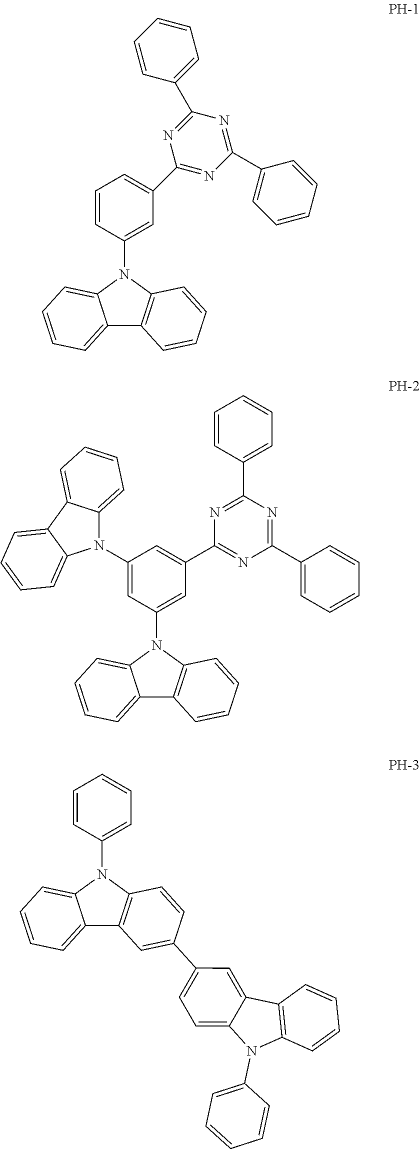 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1ccc(-n2c3ccccc3c3cc(-c4ccc5c(c4)c4ccccc4n5-c4ccccc4)ccc32)cc1]

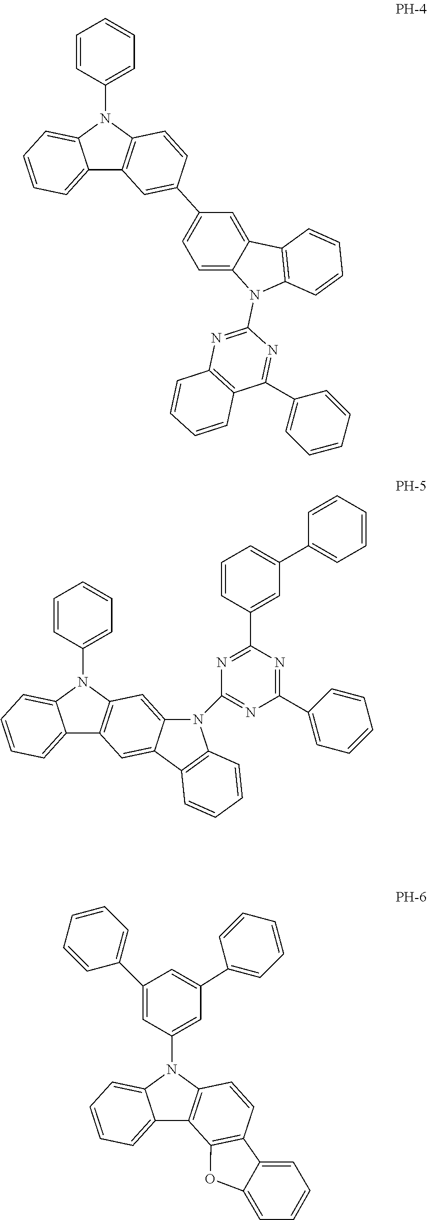 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-c3ccccc3)cc(-n3c4ccccc4c4c5oc6ccccc6c5ccc43)c2)cc1]

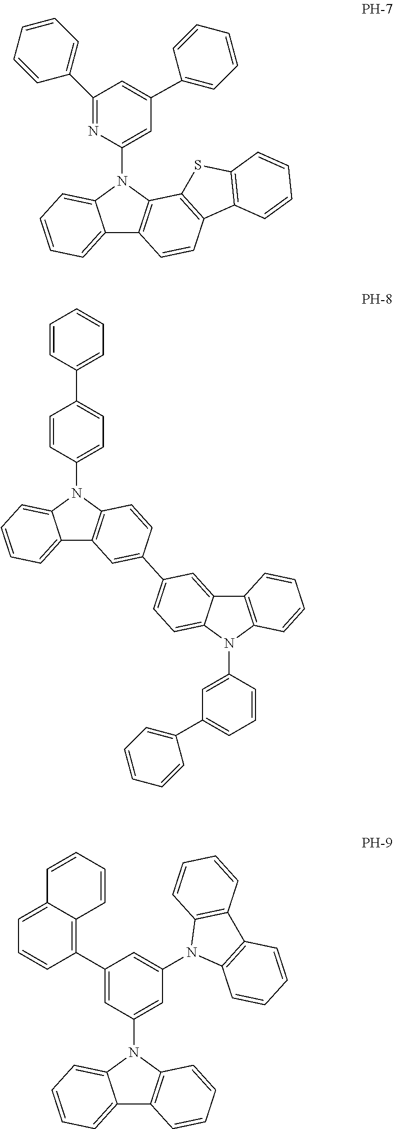 [SMILES: c1ccc(-c2cc(-c3ccccc3)nc(-n3c4ccccc4c4ccc5c6ccccc6sc5c43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

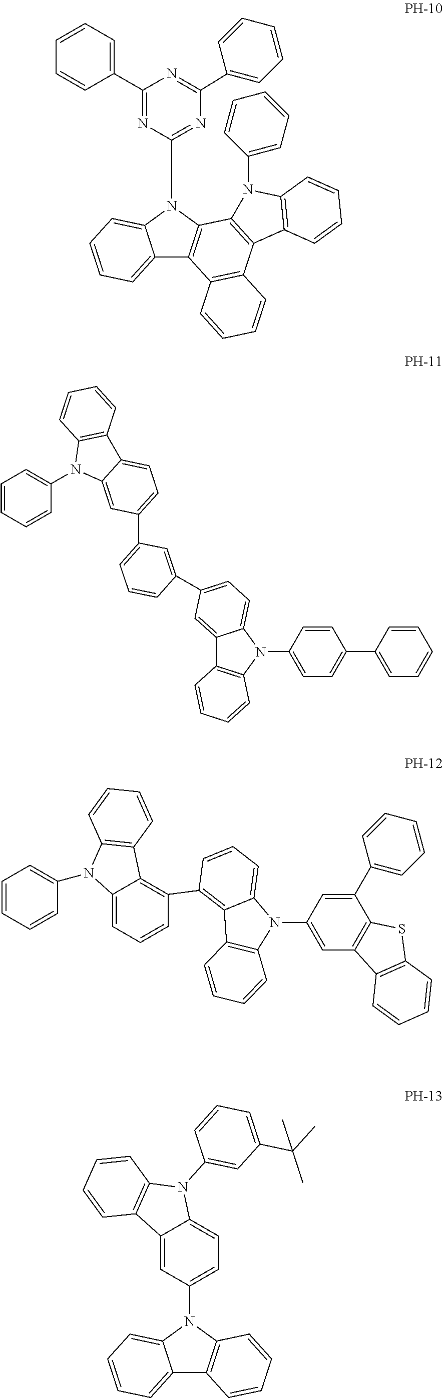 [SMILES: c1ccc(-c2nc(-c3ccccc3)nc(-n3c4ccccc4c4c5ccccc5c5c6ccccc6n(-c6ccccc6)c5c43)n2)cc1 ; c1ccc(-c2ccc(-n3c4ccccc4c4cc(-c5cccc(-c6ccc7c8ccccc8n(-c8ccccc8)c7c6)c5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; CC(C)(C)c1cccc(-n2c3ccccc3c3cc(-n4c5ccccc5c5ccccc54)ccc32)c1]

The emission layer 130 may further include a dopant interacting with the host.

In some embodiments, the emission layer 130 may include a dopant represented by Chemical Formula FD. For example, the compound represented by Chemical Formula FD may be used as a fluorescent dopant.

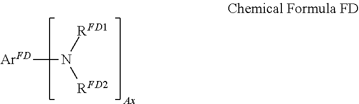

In Chemical Formula FD, Ar^{FD}, R^{FD1}, and R^{FD2} may each independently be a substituted or unsubstituted C₃-C₆₀ carbocyclic group, or a substituted or unsubstituted C₁-C₆₀ heterocyclic group. Ax may be an integer from 1 to 6.

In some embodiments, Ar^{FD} may include a condensed ring structure in which three or more aryl rings or benzene rings are condensed together (e.g., an anthracene group, a chrysene group, a pyrene group, and/or the like).

In some embodiments, the emission layer 130 may include a phosphorescent dopant. The phosphorescent dopant may include an organometallic compound that includes a central metal and at least one ligand bonded to the central metal via a coordination bond (e.g., a coordinate covalent bond or a dative bond). The central metal may include, e.g., a transition metal, and the ligand may include, e.g., a monodentate ligand, a bidentate ligand, a tridentate ligand, a tetradentate ligand, a pentadentate ligand, a hexadentate ligand, or a combination thereof.

The phosphorescent dopant may include, e.g., a compound represented by Chemical Formula PD.

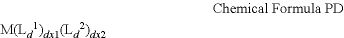

In Chemical Formula PD, M may be a transition metal atom, e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}¹ may be a ligand represented by Chemical Formula LD1.

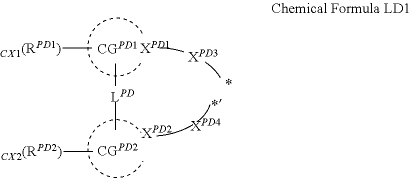

In Chemical Formula LD1, X^{PD1} and X^{PD2} may each independently be C or N.

In an embodiment, one selected from X^{PD1} and X^{PD2} may be C and the other may be N. In an embodiment, X^{PD1} and X^{PD2} may each be N.

In Chemical Formula LD1, CG^{PD1} and CG^{PD2} may each independently be a substituted or unsubstituted C₃-C₆₀ carbocyclic group, or a substituted or unsubstituted C₁-C⁶⁰ heterocyclic group. For example, CG^{PD1} and CG^{PD2} may each independently be a pyrrole group, a pyrazole group, an imidazole group, a triazole group, an oxazole group, an isoxazole group, a thiazole group, an isothiazole group, an oxadiazole group or a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond (e.g., a single covalent bond), a substituted or unsubstituted methylene group, a substituted or unsubstituted ethylene group, *—O—*′, *—S—*′, *—C(═O)—*′, *—N(R^{PD3})—*′, *—C(R^{PD4})═*′, or *═C(R^{PD5})—*′.

In Chemical Formula LD1, X^{PD3} and X^{PD4} may each independently be a chemical bond, O, S, N(R^{PD6}), B(R^{PD7}), P(R^{PD8}), C(R^{PD9})(R^{PD10}), or Si(R^{PD11})(R^{PD12}). The chemical bond may be, e.g., a covalent bond or a coordination bond (e.g., a coordinate covalent bond or a dative bond).

In Chemical Formula LD1, R^{PD1} and R^{PD2} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD13})(R^{PD14}), —C(═O)(R^{PD15}), —S(═O)₂(R^{PD16}), or —P(═O)(R^{PD17})(R^{PD18}). The silyl group may be represented by —Si(R^{sa})(R^{sb})(R^{sc}), as explained above.

R^{PD3} to R^{PD18} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group.

In Chemical Formula LD1, cx1 and cx2 may each independently be an integer from 0 to 10. When at least one selected from cx1 and cx2 is 2 or more, two or more of R^{PD1} or two or more of R^{PD2} may be the same as or different from each other.

The symbols -* and -*′ each represent a binding site where the ligand represented by Chemical Formula LD1 bonds to M.

In Chemical Formula PD, dx1 may be an integer from 1 to 3. When dx1 is 2 or 3, two or three of L_{d}¹ may be the same as or different from each other. Among two or three selected from L_{d}¹, CG^{PD1} and/or CG^{PD2} adjacent to each other may be connected to each other through a connecting group such as L^{PD1}, L^{PD2}, and/or the like. The connecting group such as L^{PD1}, L^{PD2}, and/or the like, may each independently be the same as defined in connection with L^{PD}.

In Chemical Formula PD, L_{d}² may be an organic ligand. L_{d}² may include, e.g., a halogen group, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or a combination thereof.

In Chemical Formula PD, dx2 is an integer of 0 to 4. When dx2 is 2 or more, two or more of L_{d}² may be the same as or different from each other.

Non-limiting examples of the phosphorescent dopant are as follows.

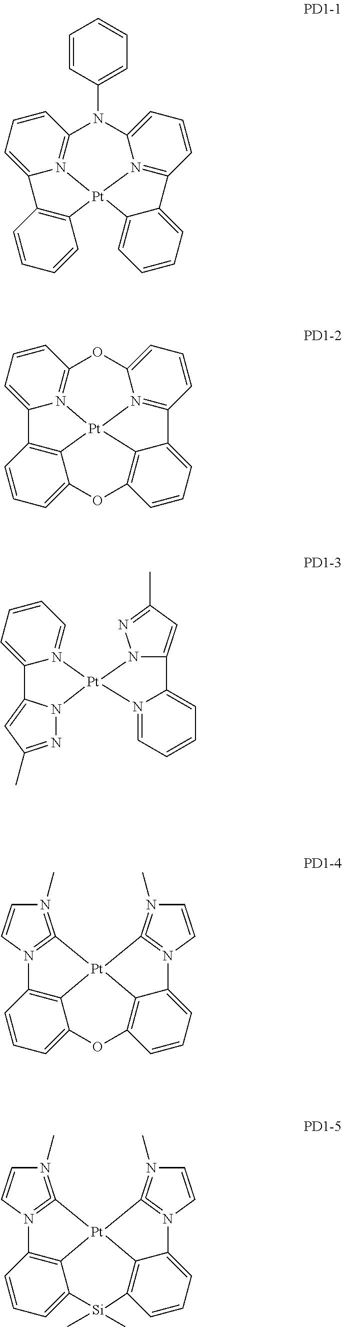

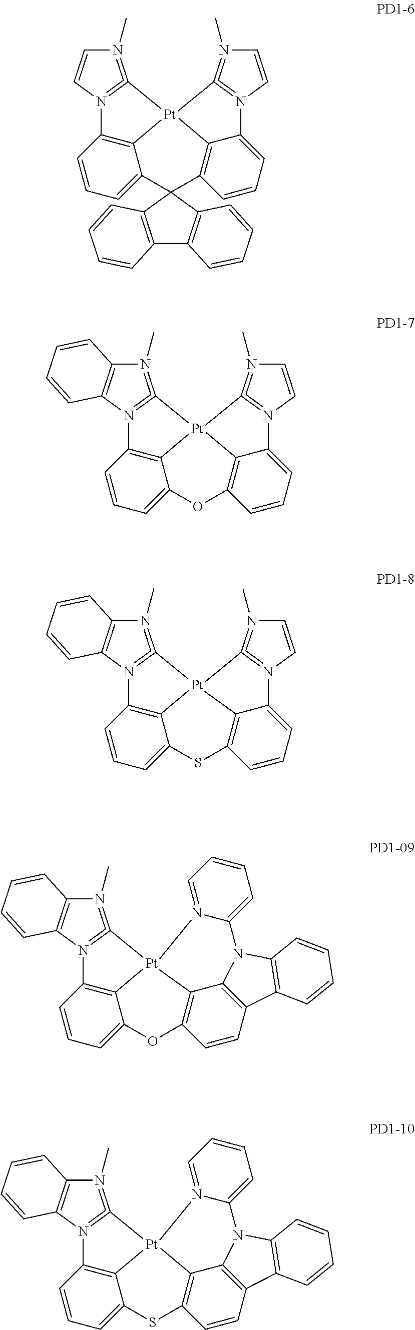

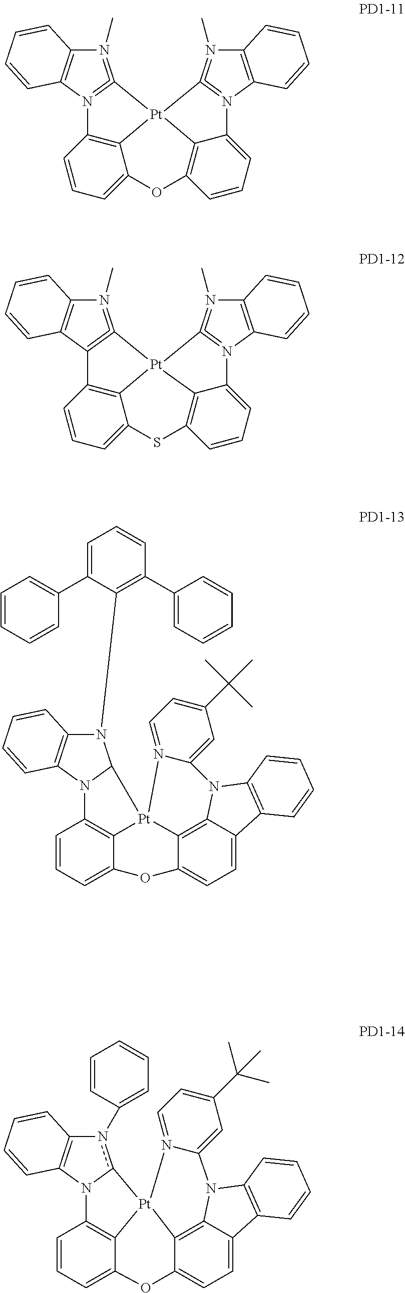

In some embodiments, the emission layer 130 may include a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi), and/or the like), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), and/or the like), and/or the like, as a fluorescent dopant material.

The emission layer 130 may include a metal complex that includes iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant, in addition to the materials described above. For example, FIrpic (iridium(III) bis(4,6-difluorophenylpyridinato-N,C2′)picolinate), FIr6 (bis(2,4-difluorophenylpyridinato)-tetrakis(1-pyrazolyl)borate iridium (III)), PtOEP (platinum octaethyl porphyrin), and/or the like, may be used as the phosphorescent dopant.

In embodiments, the emission layer 130 may include a boron-containing dopant represented by Chemical Formula BD.

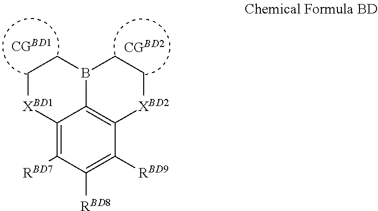

In Chemical Formula BD, X^{BD1} and X^{BD2} may each independently be N(R^{BD1}), P(R^{BD2}), C(R^{BD3})(R^{BD4}), Si(R^{BD5})(R^{BD6}), S or O. In an embodiment, X^{BD1} and X^{BD2} may each be N(R^{BD1}). R^{BD1} to R^{BD6} may each independently be hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group. R^{BD7}, R^{BD8}, and R^{BD9} may each independently be hydrogen, deuterium, halogen, a cyano group, a substituted or unsubstituted amine group, a substituted or unsubstituted boryl group, a substituted or unsubstituted oxy group, a substituted or unsubstituted thio group, a substituted or unsubstituted C₁-C₂₀ alkyl group, a substituted or unsubstituted C₆-C₃₀ aryl group, or a substituted or unsubstituted C₂-C₃₀ heteroaryl group. R^{BD3}, R^{BD4} and/or R^{BD5} may be bonded to an adjacent group to form a ring.

In Chemical Formula BD, CG^{BD1} and CG^{BD2} represent a cyclic group, and CG^{BD1} and CG^{BD2} may each independently be a substituted or unsubstituted C₃-C₆₀ carbocyclic group, or a substituted or unsubstituted C₁-C₆₀ heterocyclic group. In some embodiments, CG^{BD1} and CG^{BD2} may each independently be a substituted or unsubstituted C₆-C₃₀ aryl group, or a substituted or unsubstituted C₂-C₃₀ heteroaryl group.

In an embodiment, CG^{BD1} and CG^{BD2} may each independently be a substituted or unsubstituted benzene ring. In embodiments, the boron-containing dopant may serve as a thermally activated delayed fluorescence (TADF) dopant.

In an embodiment, one selected from CG^{BD1} and CG^{BD2} may be a non-condensed aryl group or a non-condensed heteroaryl group, and the other one thereof may be a condensed polycyclic aryl group or a condensed polycyclic heteroaryl group. In embodiments, the boron-containing dopant may serve as a fluorescent dopant.

In an embodiment, the emission layer 130 may include one selected from the dopant materials as described above, or any suitable combination thereof.

In some embodiments, the emission layer 130 may include two or more host materials. For example, the emission layer 130 may include a hole transporting host and an electron transporting host. In embodiments, the emission layer 130 may include a hole transporting host, an electron transporting host, a photosensitive agent, and a dopant. In example embodiments, the hole transporting host and the electron transporting host may form an exciplex, and energy may be transferred from the exciplex to the photosensitive agent and from the photosensitive agent to the dopant, thereby inducing a light emission.

Non-limiting examples of the hole transporting host may include a compound represented by Chemical Formula HT as described below. Non-limiting examples of the electron transporting host may include a compound represented by Chemical Formula ET as described below.

In some embodiments, the emission layer 130 may include quantum dots. A quantum dot may include a Group II-VI compound, a Group III-VI compound, a Group I-III-VI compound, a Group III-V group compound, a Group III-II-V group compound, a Group IV-VI compound, a Group IV element, a Group IV compound, or a combination thereof.

The quantum dot may include a core that includes the compound as described above, and a shell around (e.g., surrounding) the core. The shell may include an inorganic oxide or a semiconductor compound. Examples of the semiconductor compound may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, and/or the like.

In example embodiments, a color of light from a quantum dot may be adjusted according to a particle size of the quantum dot. The quantum dot may be a blue quantum dot, a red quantum dot, or a green quantum dot.

The hole transfer region 120 may be formed between the first electrode 110 and the emission layer 130. The hole transfer region 120 may have a single-layered structure or a multi-layered structure including different materials.

The hole transfer region 120 may include a hole injection layer, a hole transport layer, and/or an electron blocking layer, and may further include an auxiliary emission layer.

In some embodiments, as illustrated in FIG. 2, the hole transfer region 120 may include a hole injection layer 122 and a hole transport layer 124, sequentially stacked from the first electrode 110.

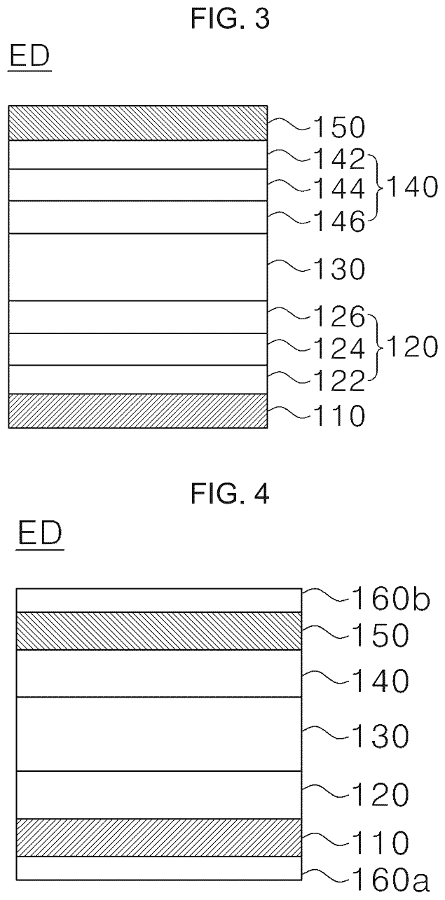

In some embodiments, as illustrated in FIG. 3, the hole transfer region 120 may include a hole injection layer 122, a hole transport layer 124, and an electron blocking layer 126, sequentially stacked from the first electrode 110. The electron blocking layer 126 may block or reduce an electron transfer from the electron transfer region 140 to the hole transfer region 120. Accordingly, the generation of excitons in the emission layer 130 may be increased, and light-emission efficiency may be further increased.

For example, the hole transfer region 120 may include a compound represented by Chemical Formula HT.

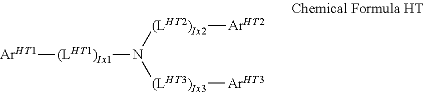

In Chemical Formula HT, L^{HT1}, L^{HT2}, and L^{HT3} may each independently be a direct linkage (e.g., a single covalent bond), a substituted or unsubstituted C₆-C₃₀ arylene group, or a substituted or unsubstituted C₂-C₃₀ heteroarylene group.

In Chemical Formula HT, Ix1 to Ix3 may each independently be an integer from 0 to 10. When Ix1, Ix2, or Ix3 is 2 or more, two or more of each of L^{HT1}, L^{HT2}, or L^{HT3} may be directly connected by, e.g., carbon atoms (e.g., sp2 carbons) of each aryl ring, to form a substituted or unsubstituted C₆-C₃₀ arylene group, or a substituted or unsubstituted C₂-C₃₀ heteroarylene group.

In Chemical Formula HT, Ar^{HT1} and Ar^{HT2} may each independently be a substituted or unsubstituted C₆-C₃₀ aryl group, or a substituted or unsubstituted C₂-C₃₀ heteroaryl group. Ar^{HT3} may be a substituted or unsubstituted C₆-C₃₀ aryl group.

In an embodiment, the compound represented by Chemical Formula HT may be a monoamine compound. In an embodiment, the compound represented by Chemical Formula HT may be a diamine compound in which at least one selected from Ar^{HT1} to Ar^{HT3} includes an amine group as a substituent.

In some embodiments, the compound represented by Chemical Formula HT may be a carbazole-based compound in which at least one selected from Ar^{HT1} and Ar^{HT2} includes a substituted or unsubstituted carbazole group. or a fluorene-based compound in which at least one selected from Ar^{HT1} and Ar^{HT2} includes a substituted or unsubstituted fluorene group.

In some embodiments, two adjacent groups selected from among Ar^{HT1} to Ar^{HT3} may be condensed together to form a ring.

In non-limiting examples, the hole transfer region 120 may include at least one selected from compounds as follows.

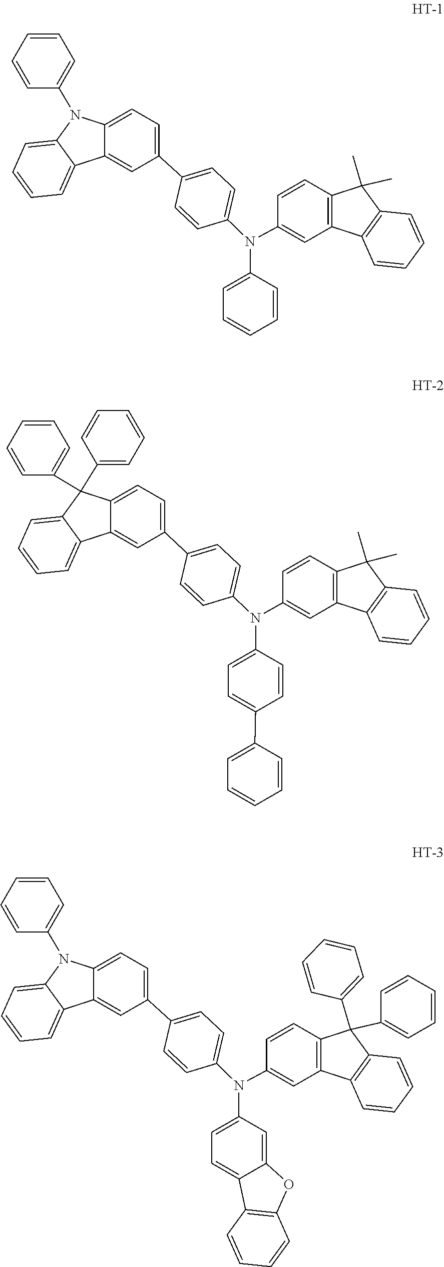 [SMILES: CC1(C)c2ccccc2-c2cc(N(c3ccccc3)c3ccc(-c4ccc5c(c4)c4ccccc4n5-c4ccccc4)cc3)ccc21 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; c1ccc(-n2c3ccccc3c3cc(-c4ccc(N(c5ccc6c(c5)-c5ccccc5C6(c5ccccc5)c5ccccc5)c5ccc6c(c5)oc5ccccc56)cc4)ccc32)cc1]

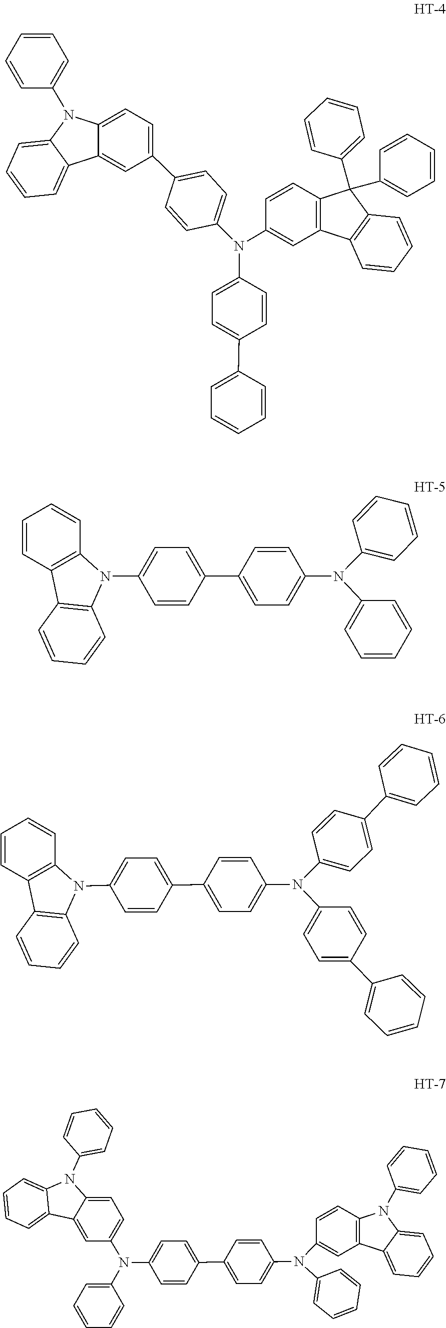 [SMILES: c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(N(c2ccccc2)c2ccc(-c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

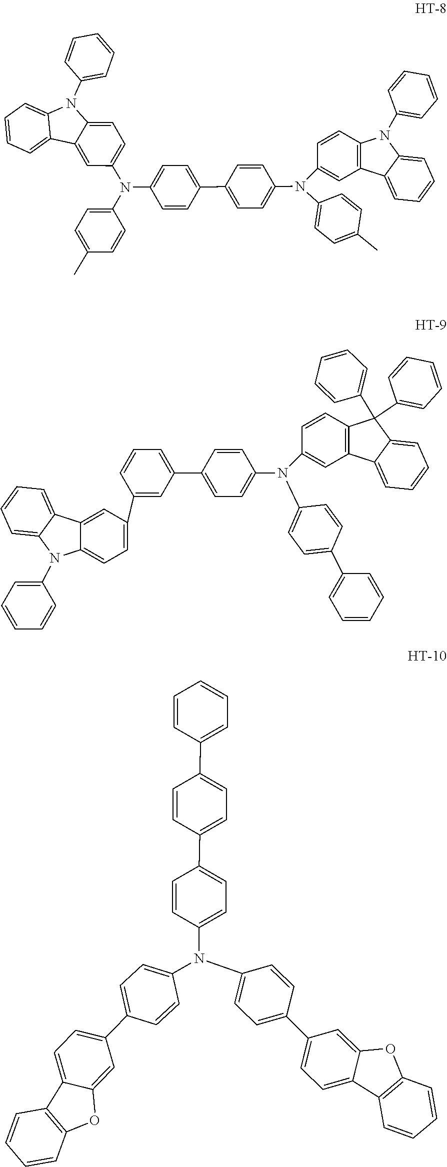 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; c1ccc(-c2ccc(N(c3ccc(-c4cccc(-c5ccc6c(c5)c5ccccc5n6-c5ccccc5)c4)cc3)c3ccc4c(c3)-c3ccccc3C4(c3ccccc3)c3ccccc3)cc2)cc1 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

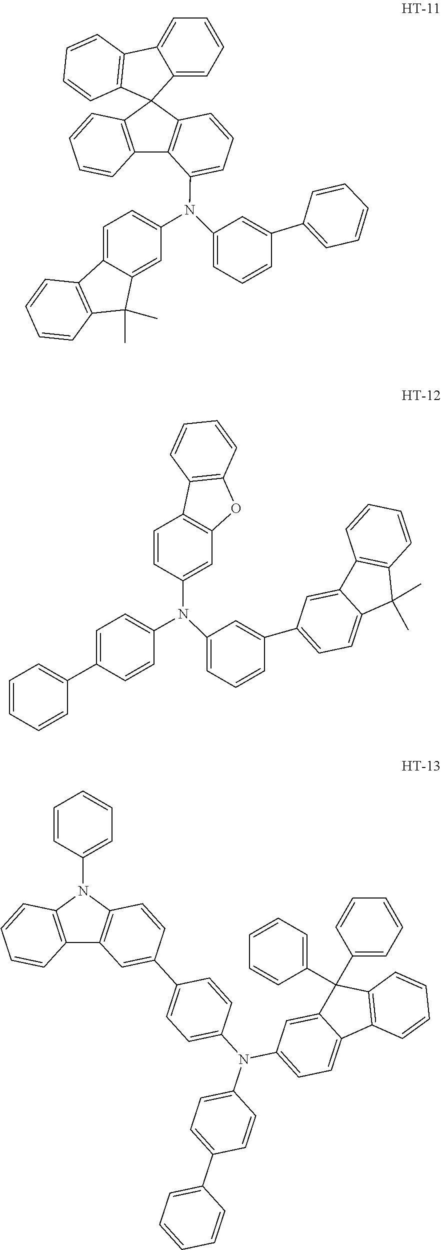 [SMILES: CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

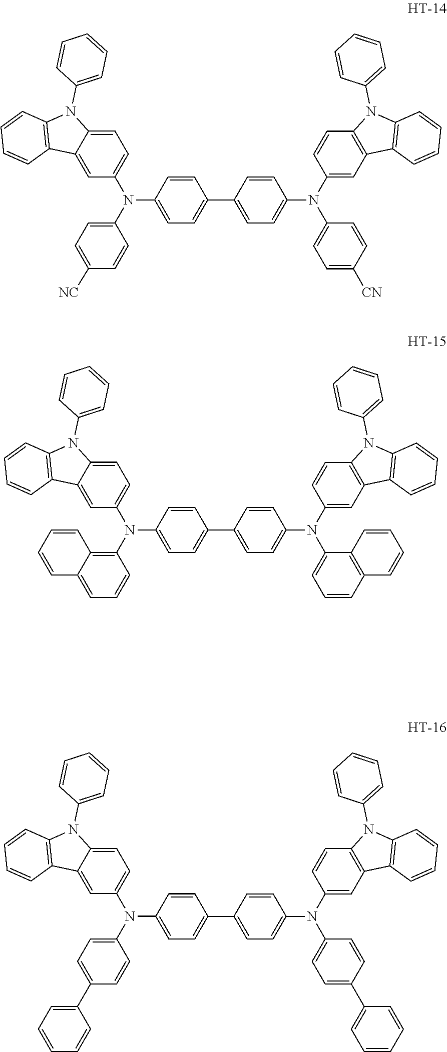 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

For example, the hole transfer region 120 may include m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N^{1′}-([1,1′-biphenyl]-4,4′-diyl)bis(N¹-phenyl-N⁴,N⁴-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), TCTA (4,4′,4″-tris(N-carbazolyl)triphenylamine), PANI/DBSA (polyaniline/dodecylbenzenesulfonic acid), PEDOT/PSS (poly(3,4-ethylenedioxythiophene)/poly(4-styrenesulfonate)), PANI/CSA (polyaniline/Camphor sulfonic acid), PANI/PSS (polyaniline/poly(4-styrenesulfonate)), a phthalocyanine compound, a carbazole compound (N-phenylcarbazole, polyvinylcarbazole, CzSi (9-(4-tert-butylphenyl)-3,6-bis(triphenylsilyl)-9H-carbazole), CCP (9-phenyl-9H-3,9′-bicarbazole), mDCP (1,3-bis(1,8-dimethyl-9H-carbazol-9-yl)benzene, and/or the like), a fluorene compound, and/or the like. The hole transfer region 120 may include one selected from the hole transfer materials described above, or a combination thereof.

The hole transfer materials described above may be included in at least one selected from the hole injection layer 122, the hole transport layer 124, and the electron blocking layer 126.

The hole transfer region 120 may further include a charge generating material. The charge generating material may be a dopant material such as a p-dopant, so that conductivity (e.g., electrical conductivity) of the hole transfer region 120 may be improved.

Examples of the dopant material may include a halogenated metal compound such as LiF, NaCl, CsF, RbCl, RbI, CuI, and KI; a quinone derivative such as TCNQ (tetracyanoquinodimethane), F4-TCNQ (2,3,5,6-tetrafluoro-7,7,8,8-tetracyanoquinodimethane), and/or the like; a cyano-containing compound such as HATCN (dipyrazino[2,3-f: 2′,3′-h] quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), and/or the like; a tungsten (W) oxide; a molybdenum (Mo) oxide; and/or the like. The hole transfer region 120 may include one selected from the dopant materials described above, or a combination thereof.

A thickness of the hole transfer region 120 may be in a range of 100 Å to 10,000 Å. For example, the thickness of the hole transfer region 120 may be in a range of 100 Å to 1,500 Å.

When the hole transfer region 120 includes the hole injection layer 122 or the hole transport layer 124, a thickness of the hole injection layer 122 may be in a range from 100 Å to 9,000 Å, from 100 Å to 3,000 Å, or from 100 Å to 1,000 Å. A thickness of the hole transport layer 124 may be in a range from 50 Å to 2,000 Å, from 100 Å to 1,500 Å, from 100 Å to 1,000 Å, or from 100 Å to 600 Å.

In the thickness ranges described above, hole transfer properties may be enhanced even at a low voltage operation, and a life-span of the device may be further improved.

Each layer of the hole transfer region 120 may be formed by a process such as a thermal evaporation deposition, a vacuum deposition, a spin coating, an inkjet printing, a laser printing, a casting, a laser thermal transfer, and/or the like.

The electron transfer region 140 may be between the second electrode 150 and the emission layer 130. The electron transfer region 140 may have a single-layered, or a multi-layered structure including different materials.

The electron transfer region 140 may include an electron injection layer, an electron transport layer, and/or a hole blocking layer, and may further include an auxiliary emission layer.

In embodiments, as illustrated in FIG. 2, the electron transfer region 140 may include an electron injection layer 142 and an electron transport layer 144, stacked from the second electrode 150 to the emission layer 130.

In some embodiments, as illustrated in FIG. 3, the electron transfer region 140 may include an electron injection layer 142, an electron transport layer 144, and a hole blocking layer 146, sequentially stacked from the second electrode 150. The hole blocking layer 146 may block, suppress, or reduce a hole transfer from the hole transfer region 120. Accordingly, emission energy and luminescence efficiency in the emission layer 130 may be further improved.

For example, the electron transfer region 140 may include a compound represented by Chemical Formula ET.

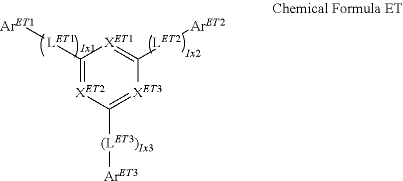

In Chemical Formula ET, at least one selected from X^{ET1} to X^{ET3} may be N; and the remainder of X^{ET1} to X^{ET3} may each independently be C(R^{ET}). R^{ET} may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group.

When one selected from X^{ET1} to X^{ET3} is N, the compound represented by Chemical Formula ET may include a pyridine group. When two selected from X^{ET1} to X^{ET3} are N, the compound represented by Chemical Formula ET may include a pyrimidine group. When X^{ET1} to X^{ET3} are each N, the compound represented by Chemical Formula ET may include a triazine group.

In Chemical Formula ET, Ix1 to Ix3 may each independently be an integer from 0 to 10. L^{ET1} to L^{ET3} may each independently be a direct linkage (e.g., a single covalent bond), a substituted or unsubstituted C₆-C₃₀ arylene group, or a substituted or unsubstituted C₂-C₃₀ heteroarylene group.

When Ix1, Ix2, or Ix3 is 2 or more, two or more of each of L^{ET1}, L^{ET2}, or L^{ET3}, respectively, may be directly linked together, e.g., by carbon atoms of each aryl ring (e.g., sp2 carbons), to form a substituted or unsubstituted C₆-C₃₀ arylene group, or a substituted or unsubstituted C₂-C₃₀ heteroarylene group.

In Chemical Formula ET, Ar^{ET1} to Ar^{ET3} may each independently be a hydrogen atom, a deuterium atom, a substituted or unsubstituted C₁-C₂₀ alkyl group, a substituted or unsubstituted C₆-C₆₀ aryl group, or a substituted or unsubstituted C₂-C₃₀ heteroaryl group. For example, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by —Si(R^{sa})(R^{sb})(R^{sc}), as explained above.

Non-limiting examples of the electron transfer material included in the electron transfer region 140 are as follows.

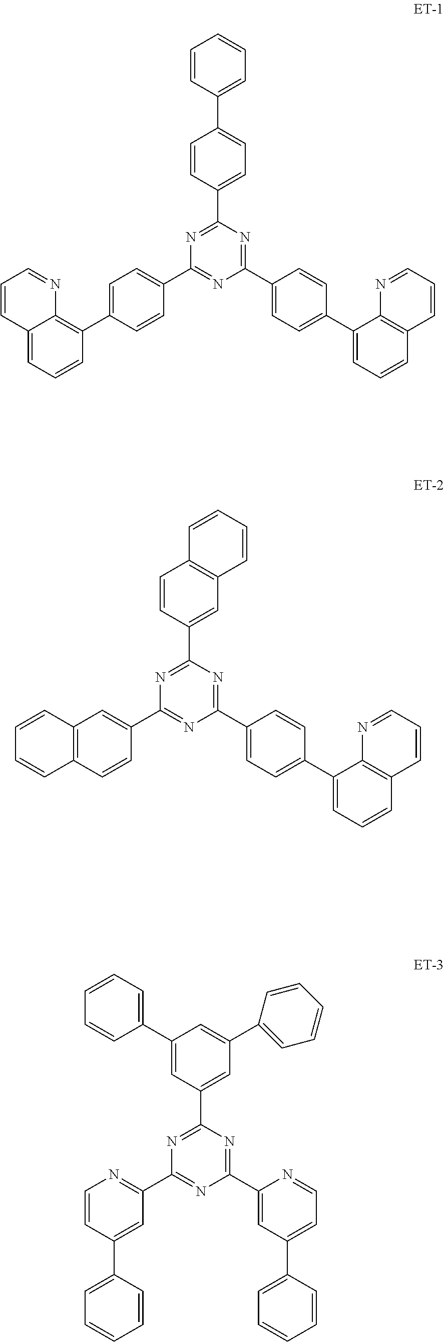 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; c1ccc(-c2cc(-c3ccccc3)cc(-c3nc(-c4cc(-c5ccccc5)ccn4)nc(-c4cc(-c5ccccc5)ccn4)n3)c2)cc1]

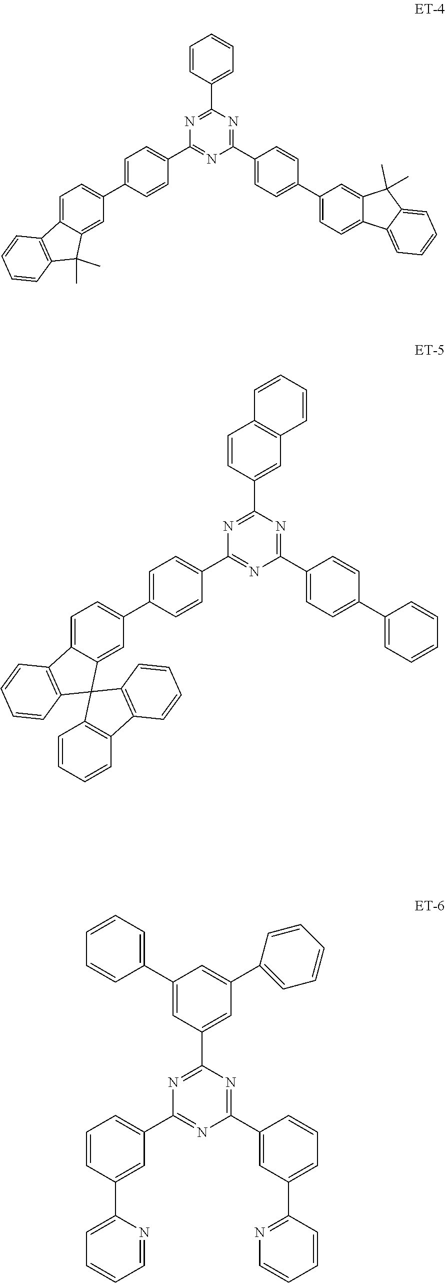 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

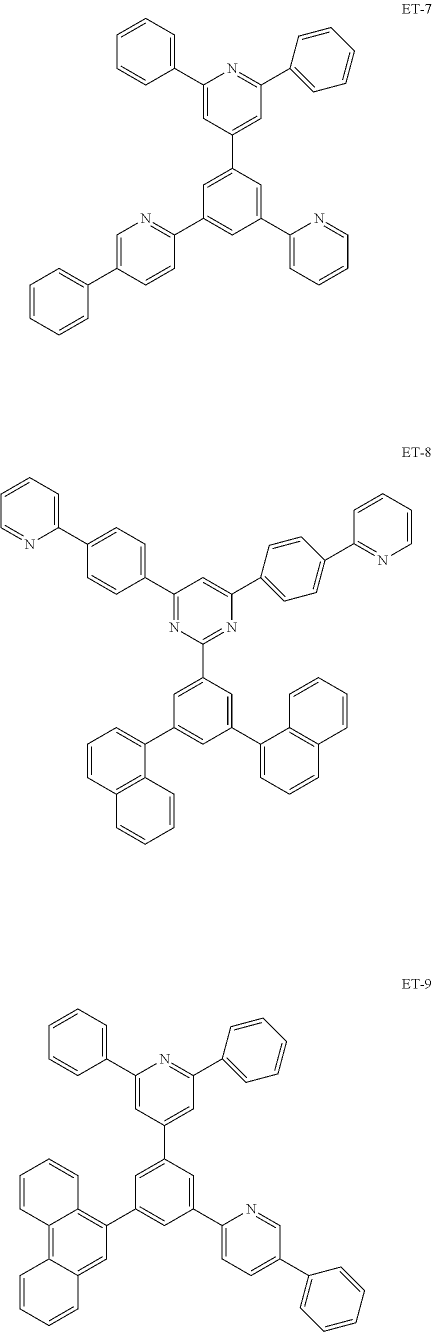 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

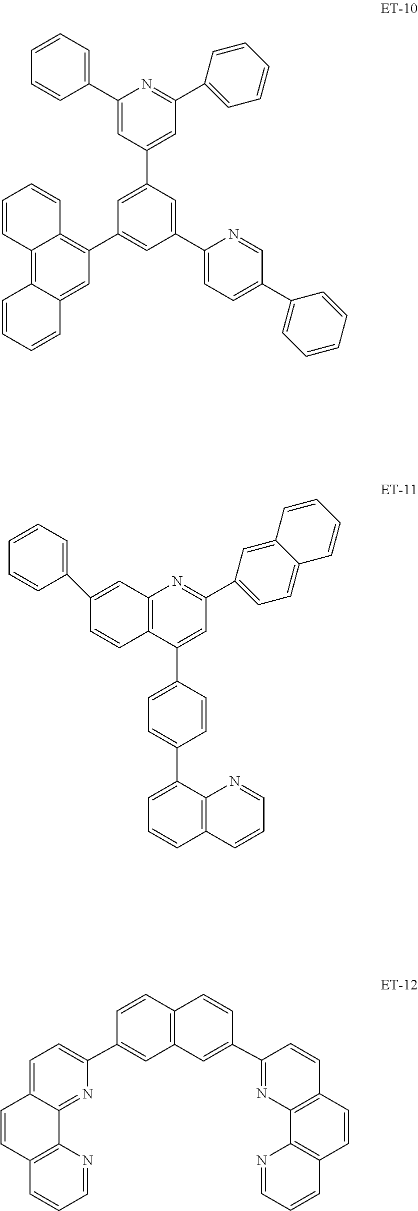 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

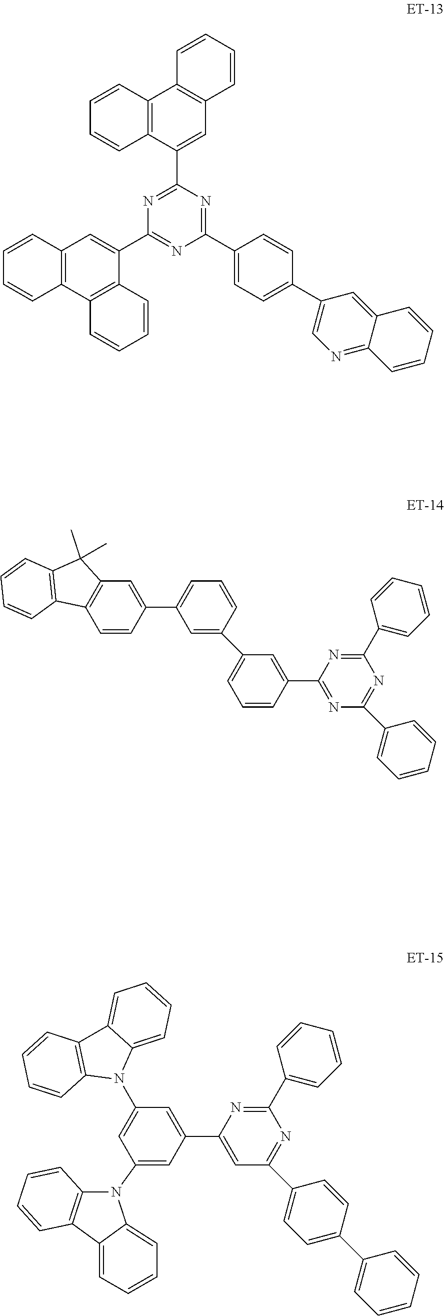 [SMILES: c1ccc2ncc(-c3ccc(-c4nc(-c5cc6ccccc6c6ccccc56)nc(-c5cc6ccccc6c6ccccc56)n4)cc3)cc2c1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

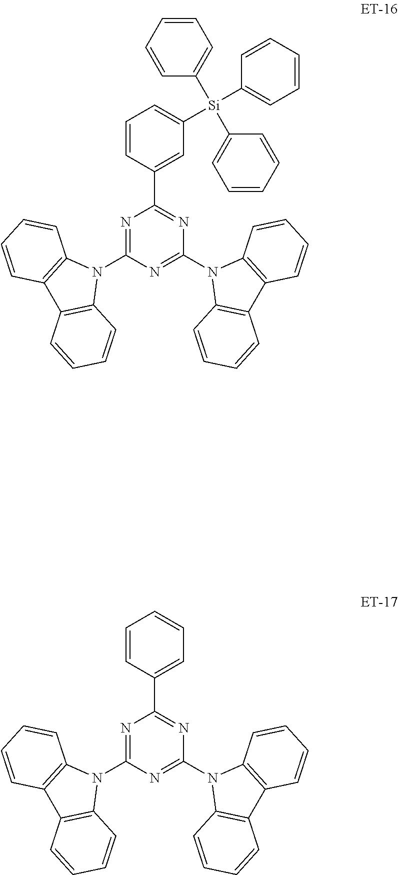 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1]

For example, the electron transfer region 140 may include an anthracene compound, Alq₃ (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (Bis(2-methyl-8-quinolinolato-N1,O8)-(1,1′-biphenyl-4-olato)aluminum), Bebq₂ (beryllium bis(benzoquinolin-10-olate)), AND (9,10-di(naphthalene-2-yl)anthracene), BmPyPhB (1,3-bis[3,5-di(pyridin-3-yl)phenyl]benzene), TSPO1 (diphenyl(4-(triphenylsilyl)phenyl)phosphine oxide), and/or the like. The electron transfer region 140 may include one selected from the electron transfer materials described above, or a combination thereof.

The above-mentioned material may be included in at least one selected from the electron injection layer 142, the electron transport layer 144, and the hole blocking layer 146.

The electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In an embodiment, the above-mentioned material may be included electron injection layer 142.

The alkali metal may include Li, Na, K, Rb, Cs, or any suitable combination thereof. The alkaline earth metal may include Mg, Ca, Sr, Ba, or any suitable combination thereof. The rare earth metal may include Sc, Y, Ce, Tb, Yb, Gd, or any suitable combination thereof.

The alkali metal-containing compound, the alkaline earth metal-containing compound, and the rare earth metal-containing compound may include an oxide, a halide (e.g., a fluoride, a chloride, a bromide, an iodide, and/or the like), a telluride, or a combination thereof of the alkali metal, the alkaline earth metal, and the rare earth metal, respectively.

The alkali metal complex, the alkaline earth metal complex, and the rare earth metal complex may include a metal ion such as an alkali metal ion, an alkaline earth metal ion or a rare earth metal ion, and a ligand bonded to the metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or a combination thereof.

A thickness of the electron transfer region 140 may be in a range from 100 Å to 1,000 Å, e.g., from 150 Å to 500 Å.

When the electron transfer region 140 includes an electron injection layer 142 or an electron transport layer 144, a thickness of the electron injection layer 142 may be in a range from 1 Å to 100 Å, from 1 Å to 90 Å or from 5 Å to 50 Å, and a thickness of the electron transport layer 144 may be in a range from 10 Å to 900 Å, from 10 Å to 500 Å or from 100 Å to 400 Å.

Within any of the thickness ranges described above, electron injection and electron transport properties may be further improved without an excessive increase in driving voltage, and stability of the electron transfer region 140 may be improved.

Each layer of the electron transfer region 140 may be formed by a process such as a thermal evaporation deposition, a vacuum deposition, a spin coating, an inkjet printing, a laser printing, a casting, a laser thermal transfer, and/or the like.

The light-emitting device ED may further include a capping layer. Light emission efficiency to an outside of the light-emitting device ED may be improved through the capping layer.

As illustrated in FIG. 4, a second capping layer 160b may be on an outer surface of the second electrode 150. In some embodiments, a first capping layer 160a may be on an outer surface of the first electrode 110.

A refractive index of the first capping layer 160a and/or the second capping layer 160b may be 1.6 or more. For example, the refractive index of the first capping layer 160a and/or the second capping layer 160b may be 1.6 or more, 1.8 or more, or 2.0 or more for a light in a wavelength range of 550 nm to 660 nm.

The first capping layer 160a and the second capping layer 160b may each be formed as an organic capping layer including an organic material, an inorganic capping layer including an inorganic material, or an organic-inorganic hybrid capping layer including both the organic and inorganic materials.

The first capping layer 160a and/or the second capping layer 160b may each have a single-layered structure or a multi-layered structure including different materials.

In some embodiments, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkaline metal complex, an alkaline earth metal complex, and/or the like. The first capping layer 160a and the second capping layer 160b may each independently include one selected from the aforementioned materials, or a combination thereof.

In an embodiment, the first capping layer 160a and/or the second capping layer 160b may each independently include an amine group-containing compound.

In a non-limiting example, the first capping layer 160a and/or the second capping layer 160b may include at least one selected from the compounds represented by Chemical Formulae P1 to P4 and/or at least one selected from the compounds HT-7, HT-8, HT-14, HT-15 and HT-16.

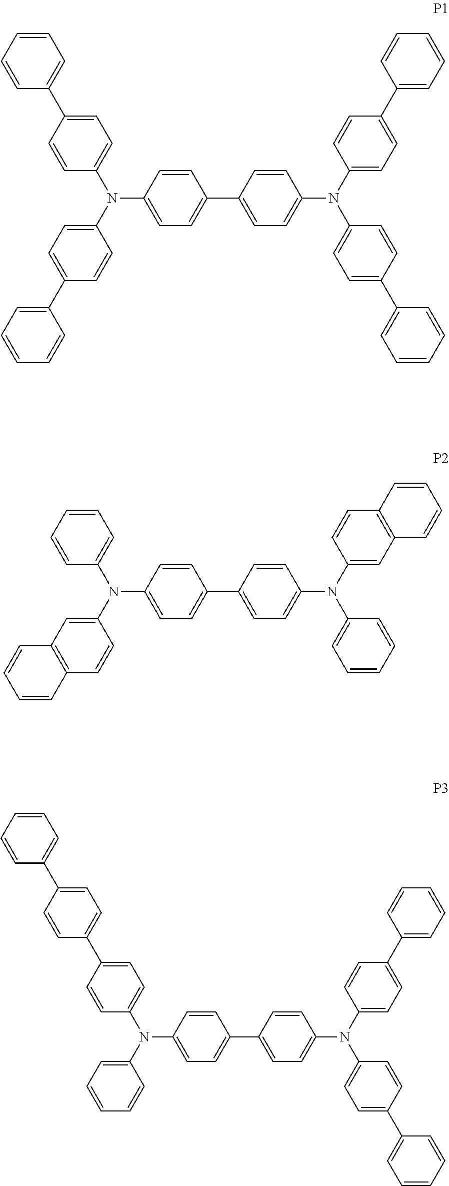 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

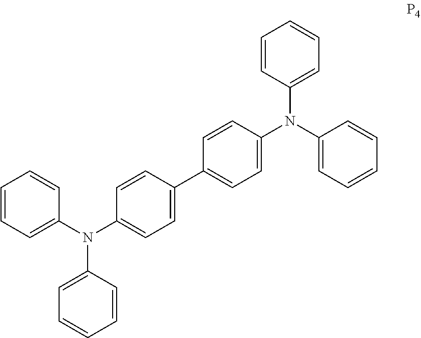 [SMILES: c1ccc(N(c2ccccc2)c2ccc(-c3ccc(N(c4ccccc4)c4ccccc4)cc3)cc2)cc1]

Referring to FIG. 5, the light-emitting device ED may include a plurality of light-emitting structures (e.g., the light-emitting structures ES1, ES2 and ES3). The light-emitting structures ES1, ES2, and ES3 may each include a stacked structure of the hole transfer region 120, the emission layer 130, and the electron transfer region 140, as described with reference to FIGS. 1 to 4. In example embodiments, the light-emitting device ED of FIG. 5 may be a light-emitting device having a tandem structure.

Charge generation layers CGL1 and CGL2 may each be between adjacent structures selected from among the light-emitting structures ES1, ES2 and ES3. Charge generation layers CGL1 and CGL2 may each independently include a p-type charge generation layer and/or an n-type charge generation layer.

The p-type charge generation layer may include a hole transport host compound, such as NPB. For example, the p-type charge generation layer may include a compound represented by Chemical Formula HT as described above. The p-type charge generation layer may further include a p-dopant, such as TCNQ.

In some embodiments, the n-type charge generation layer may include at least one selected from the group consisting of an alkali metal, an alkaline earth metal, a lanthanide metal, a rare earth metal, a transition metal, a post-transition metal, and an alloy thereof.

The n-type charge generation layer may further include, e.g., a metal complex, and the metal complex can include the above-described metal and at least one organic ligand. The organic ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxydiphenyloxadiazole, hydroxydiphenylthiadiazole, hydroxyphenylpyridine, hydroxyphenylbenzimidazole, hydroxyphenylbenzothiazole, bipyridine, phenanthroline, cyclopentadiene, and/or the like.

The n-type charge generation layer may further include an electron transport host compound. For example, the n-type charge generation layer may include a compound represented by Chemical Formula ET as described above. In an embodiment, the n-type charge generation layer may include a phenanthroline-based compound.

For example, a thickness of the n-type charge generation layer and a thickness of the p-type charge generation layer may each independently be in a range from 20 Å to 1000 Å, from 20 Å to 700 Å, or from 30 Å to 500 Å.

The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third-light emitting structure ES3.

In example embodiments, the first light-emitting structure ES1, the first charge generation layer CGL1, the second light-emitting structure ES2, the second charge generation layer CGL2, the third light-emitting structure ES3, and the second electrode 150 may be sequentially stacked from a top surface of the first electrode 110.

Colors emitted from the first light-emitting structure ES1, the second light-emitting structure ES2 and the third light-emitting structure ES3 may be the same or different from each other. In some embodiments, the first light-emitting structure ES1, the second light-emitting structure ES2 and the third light-emitting structure ES3 may include a red light-emitting layer, a green light-emitting layer and a blue light-emitting layer, respectively, and a white light-emitting structure may be implemented through the tandem structure, but is not limited thereto.

In FIG. 5, the 3-stack tandem structure in which three light-emitting structures are stacked is illustrated as an example, but the tandem structure of the light-emitting device of the present disclosure is not limited to the structure illustrated in FIG. 5. For example, 2-stack structure, or a 4-stack structure, a 5-stack structure, or more stacked structure as will be described with reference FIG. 6 may also be implemented.

Referring to FIG. 6, as described with reference to FIG. 5, a tandem structure in which the light-emitting structure and a charge generation layer are alternately and repeatedly stacked may be between the first electrode 110 and the second electrode 150.

In example embodiments, first to m^{th} light-emitting structures ES1 to ESm may be sequentially stacked from the top surface of the first electrode 110 with the charge generation layer respectively interposed therebetween. The charge generation layer may include a first charge generation layer CGL1 to an (m−1)th charge generation layer CGLm−1 sequentially stacked from the top surface of the first electrode 110.

As illustrated in FIG. 6, the first light-emitting structure ES1, the first charge generation layer CGL1, the second light-emitting structure ES2, the second charge generation layer CGL2, . . . , an (m−1)th light-emitting structure ESm−1, an (m−1)th charge generation layer CGLm−1, an mth light-emitting structure ESm, and the second electrode 150 may be sequentially stacked from the top surface of the first electrode 110.

In some embodiments, m is 4, and an intermediate layer of the light-emitting device may have a 4-stack tandem structure, and may include first to fourth light-emitting structures ES1, ES2, ES3 and ES4, and first to third charge generation layers CGL1, CGL2 and CGL3. Colors of light generated from the first to fourth light-emitting structures ES1, ES2, ES3 and ES4 may be the same or different from each other.

In an embodiment, the first to fourth light emitting structures ES1, ES2, ES3 and ES4 may include at least one blue light-emitting structure and at least one green-light emitting structure. In a non-limiting example, the first to third light emitting structures ES1, ES2 and ES3 may correspond to the blue light-emitting structure, and the fourth light emitting structure ES4 may correspond to the green-light emitting structure.

In some embodiments, m is 5, and an intermediate layer of the light-emitting device may have a 5-stack tandem structure, and may include first to fifth light-emitting structures ES1, ES2, ES3, ES4 and ES5, and first to fourth charge generation layers CGL1, CGL2, CGL3 and CGL4. Colors of light generated from the first to fifth light-emitting structures ES1, ES2, ES3, ES4, and ES5 may be the same or different from each other.

In an embodiment, the first to fifth light-emitting structures ES1, ES2, ES3, ES4 and ES5 may include at least one blue light emitting structure and at least one green light emitting structure. In a non-limiting example, the first to fifth light-emitting structures ES1, ES2, ES3, ES4 and ES5 may include three blue light-emitting structures and two green light-emitting structures. For example, the first, third and fifth light-emitting structures ES1, ES3 and ES5 may correspond to the blue light-emitting structure, and the second and fourth light-emitting structures ES2 and ES4 may correspond to the green light-emitting structure.

### Electronic Device

The above-described light-emitting device ED may be applied to an electronic device and may be provided as a light-emitting portion and/or a light-emitting unit of the electronic device.

The electronic device may include the light-emitting device ED including the polycyclic compound of Chemical Formula 1 described above, thereby providing improved color properties, luminous efficiency, and life-span properties.

The electronic device may further include, e.g., a functional layer on the light-emitting device, and the functional layer may include a sensor layer, a polarizing layer, a color conversion layer, a color filter layer, or a combination of at least two thereof.

Examples of an electronic device may include a display device, a billboard, a signboard, a light source, a lighting device, a personal computer such as a laptop computer or a desktop computer, a mobile phone, an electronic book, an electronic dictionary, an electronic notebook, a health-care device including a diagnostic device and various suitable sensors, and/or various suitable display parts for transportation means (automobile, aircraft, ship, train, and/or the like).

In example embodiments, the light-emitting device ED may be applied to an organic light emitting diode (OLED) display device and/or a quantum dot (QD)-OLED display device.

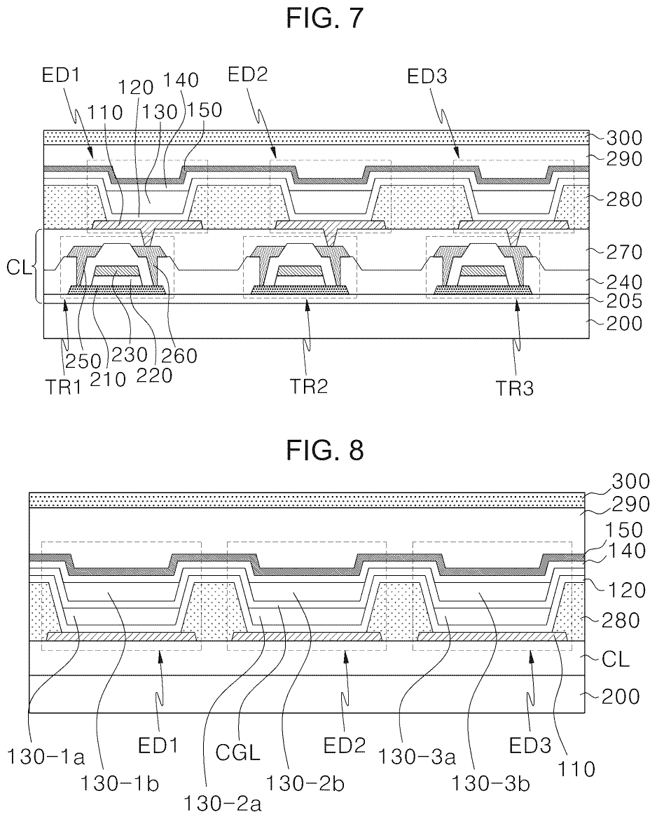

FIG. 7 is a schematic cross-sectional view illustrating a display device in accordance with example embodiments.

Referring to FIG. 7, the display device may include a circuit layer CL on a base substrate 200, and light-emitting devices ED1, ED2 and ED3 on the circuit layer CL.

The base substrate 200 may serve as a supporting substrate and/or as a back-plane substrate of a display device. The base substrate 200 may be a glass substrate and/or a plastic substrate.

In some embodiments, the base substrate 200 may include a polymer material having transparent and flexible properties. When the base substrate 200 includes a polymer material, the base substrate 200 may be used in a transparent flexible display device. For example, the base substrate 200 may include a polymer material such as polyimide, polysiloxane, an epoxy resin, an acrylic resin, polyester, and/or the like. In an embodiment, the base substrate 200 may include polyimide.

The circuit layer CL may include transistors TR1, TR2 and TR3. The circuit layer CL may include wiring layers and insulating layers (e.g., electrically insulating layers) that form a thin film transistor array (TFT-Array).

The circuit layer CL may further include a buffer layer 205 on a top surface of the base substrate 200. The buffer layer 205 may block or reduce the penetration of moisture through the base substrate 200, and may also block or reduce the diffusion of impurities between the base substrate 200 and the structures formed thereon.

The buffer layer 205 may include, e.g., silicon oxide, silicon nitride, and/or silicon oxynitride. The buffer layer 205 may include one selected from the aforementioned materials, or a combination thereof. In some embodiments, the buffer layer 205 may have a stacked structure that includes a silicon oxide layer and a silicon nitride layer.

The transistors TR1, TR2 and TR3 may be on the buffer layer 205. A first transistor TR1, a second transistor TR2 and a third transistor TR3 may be electrically connected to a first light-emitting device ED1, a second light-emitting device ED2 and a third light-emitting device ED3, respectively.

The transistors TR1, TR2 and TR3 may each include an active layer 210, a gate insulation layer 220, and a gate electrode 230.

The active layer 210 may be on the buffer layer 205, and may be patterned for each pixel. The active layer 210 may include a silicon compound such as amorphous silicon and/or polysilicon. A p-type dopant or an n-type dopant may be doped in a region of the active layer 210, and the active layer 210 may include a source region, a drain region, and a channel region.

The active layer 210 may include an oxide semiconductor, such as indium gallium zinc oxide (IGZO), zinc tin oxide (ZTO), and/or ITZO.

The gate insulation layer 220 may be on the active layer 210, and the gate electrode 230 may be stacked on the gate insulation layer 220. As illustrated in FIG. 7, the gate insulation layer 220 may be patterned to partially cover each active layer 210. In embodiments, the gate insulation layer 220 may extend continuously over a plurality of pixels or light-emitting regions, and may be provided as a common layer for the first, second, and third transistors TR1, TR2 and TR3.

The gate electrode 230 may overlap the channel region of the active layer 210 in a thickness direction.

An insulating interlayer 240 may be on the active layer 210 to cover the gate electrode 230 and the gate insulation layer 220. Connection electrodes 250 and 260 which may be in contact with or electrically connected to the active layer 210 may each be on the insulating interlayer 240.

The connection electrodes 250 and 260 may extend through the insulating interlayer 240 to be in contact with or electrically connected to the active layer 210. When the gate insulation layer 220 is provided as a common layer for a plurality of light-emitting regions, the connection electrodes 250 and 260 may also extend through the gate insulation layer 220.

The connection electrodes 250 and 260 may include a source electrode 250 that may be in contact with or connected to the source region of the active layer 210, and a drain electrode 260 that may be in contact with or connected to the drain region of the active layer 210.

The gate insulation layer 220 and the insulating interlayer 240 may each independently include silicon oxide, silicon nitride, and/or silicon oxynitride, and may each have a stacked structure that includes a silicon oxide layer and a silicon nitride layer.

The gate electrode 230 and the connection electrodes 250 and 260 may include a metal such as Ag, Mg, Al, W, Cu, Ni, Cr, Mo, Ti, Pt, Ta, Nd, Sc, an alloy thereof, and/or a nitride thereof.

A via insulation layer 270 may be on the insulating interlayer 240 to cover the connection electrodes 250 and 260.

The via insulation layer 270 may accommodate a via structure electrically connecting the first electrode 110 and the drain electrode 260. The via insulation layer 270 may serve as a planarization layer of the circuit layer CL. In embodiments, the via insulation layer 270 may include an organic material such as polyimide, an epoxy resin, an acrylic resin, polyester, and/or the like.

The light-emitting devices ED1, ED2 and ED3 may be on the via insulation layer 270. For example, as described with reference to FIGS. 1 to 4, the light-emitting devices ED1, ED2 and ED3 may include the first electrode 110, the hole transfer region 120, the emission layer 130, the electron transfer region 140, and the second electrode 150 which are sequentially stacked from the via insulation layer 270.

The first electrode 110 may be electrically connected to the transistors TR1, TR2 and TR3 or the connection electrodes 250 and 260 in the circuit layer CL through the via structure. As illustrated in FIG. 7, the first electrode 110 may be in contact with or connected to the drain electrode 260 to serve as a pixel electrode patterned for each light-emitting region or pixel.

A pixel defining layer 280 may be on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

The pixel defining layer 280 may partially cover the first electrode 110 of each light-emitting region.

As illustrated in FIG. 7, the hole transfer region 120 and the electron transfer region 140 may each be provided as a common layer that continuously extends over the pixel defining layer 280 and the first electrodes 110. The emission layer 130 may be provided within each light emitting-region or pixel, and may be separated by the pixel defining layer 280.

In some embodiments, the emission layer 130 may also be provided as a common layer that continuously extends over the light emitting-regions or pixels. In some embodiments, the hole transfer region 120, the emission layer 130, and the electron transfer region 140 may each be patterned and separately formed for each light-emitting region or pixel.

The second electrode 150 may be provided as a common electrode that continuously extends over the light-emitting regions or the pixels.

An encapsulation layer 290 may be on the pixel defining layer 280 and the light-emitting devices ED1, ED2 and ED3 to protect the light-emitting devices ED1, ED2 and ED3 from moisture and/or oxygen. The encapsulation layer 290 may be a thin film encapsulation (TFE) having a single-layered structure or multi-layered structure.

The encapsulation layer 290 may include an inorganic layer that includes silicon nitride (SiNₓ), silicon oxide (SiOₓ), indium tin oxide, indium zinc oxide, or any suitable combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, and/or the like), an epoxy resin (e.g., an aliphatic glycidyl ether (AGE)) or any suitable combination thereof; or a combination of the inorganic layer and the organic layer.

The display device may further include a functional layer 300 on the encapsulation layer 290. The functional layer 300 may include a sensor layer such as a touch sensor layer, an optical layer such as a polarizing layer, a color conversion layer, a color filter layer, a window film, or any suitable combination thereof.

FIG. 8 is a schematic cross-sectional view illustrating a display device in accordance with example embodiments.

Referring to FIG. 8, each of the light-emitting devices ED1, ED2 and ED3 may have a tandem structure, e.g., a 2-stack tandem structure.

In some embodiments, the hole transfer region 120 and the electron transfer region 140 may be continuously and commonly formed and included in an intermediate layer of each light-emitting structure. In embodiments, a charge generation layer CGL may continuously extend across a plurality of pixels and may be commonly included in the intermediate layer of each light-emitting structure.

The first light-emitting device ED1 may include a first lower emission layer 130-1a between the hole transfer region 120 and the charge generation layer CGL, and a first upper emission layer 130-1b between the charge generation layer CGL and the electron transfer region 140.

The second light-emitting device ED2 may include a second lower emission layer 130-2a between the hole transfer region 120 and the charge generation layer CGL, and a second upper emission layer 130-2b between the charge generation layer CGL and the electron transfer region 140.

The third light-emitting device ED3 may include a third lower emission layer 130-3a between the hole transfer region 120 and the charge generation layer CGL, and a third upper emission layer 130-3b between the charge generation layer CGL and the electron transfer region 140.

The lower and upper emission layers included in each light-emitting structure may generate light of the same color. In an embodiment, each of the first lower emission layer 130-1a and the first upper emission layer 130-1b included in the first light-emitting device ED1 may correspond to a red emission layer. Each of the second lower emission layer 130-2a and the second upper emission layer 130-2b included in the second light-emitting device ED2 may correspond to a green emission layer. Each of the third lower emission layer 130-3a and the third upper emission layer 130-3b included in the third light-emitting device ED3 may correspond to a blue emission layer.

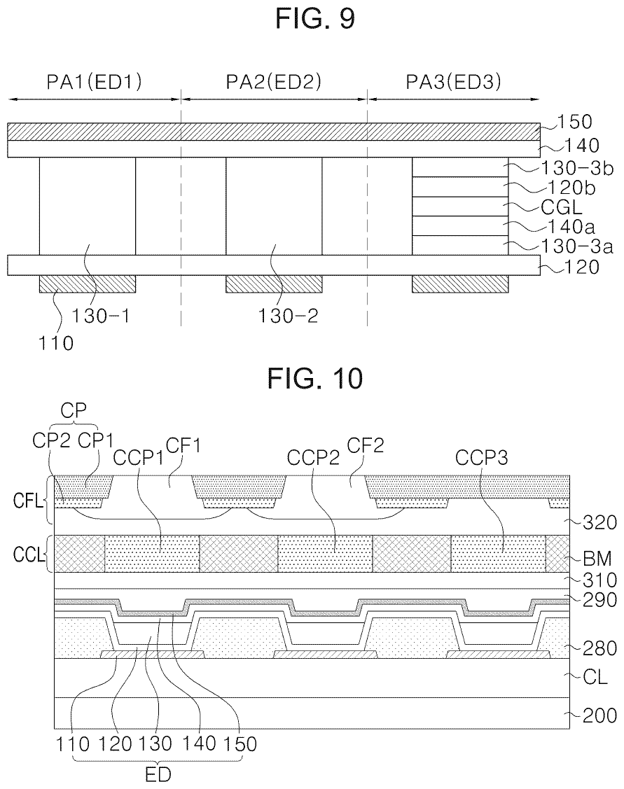

FIG. 9 is a schematic cross-sectional view illustrating a stack construction of light-emitting structure in a display device in accordance with example embodiments. For convenience of illustration and description, illustration of the circuit layer, the base substrate, the pixel defining layer, and/or the like, is omitted from FIG. 9, and a shape of each layer or element in the light-emitting structure is briefly shown as a rectangle.

Referring to FIG. 9, at least one selected from the light-emitting devices ED1, ED2 and ED3 or pixel areas PA1, PA2 and PA3 may have a tandem structure including a plurality of emission layers, and at least one selected from the remainder may have a single emission layer structure.

In some embodiments, one selected from the light-emitting devices ED1, ED2 and ED3 or the pixel areas PA1, PA2 and PA3 may have a tandem structure, and the remainder may have a single emission layer structure.

As illustrated in FIG. 9, the first light-emitting device ED1, the second light-emitting device ED2, and the third light-emitting device ED3 may be included in the first pixel area PA1, the second pixel area PA2, and the third pixel area PA3, respectively. In some embodiments, the first pixel area PA1, the second pixel area PA2, and the third pixel area PA3 may correspond to a red pixel area, a green pixel area, and a blue pixel area, respectively.

The hole transfer region 120, the electron transfer region 140, and the second electrode 150 may each be provided as a common layer continuously extending over the first pixel area PA1, the second pixel area PA2, and the third pixel area PA3.

The first-light emitting device ED1 included in the first pixel area PA1 may include a first emission layer 130-1, and the second light-emitting device ED2 included in the second pixel area PA2 may include a second emission layer 130-2. Each of the first emission layer 130-1 and the second emission layer 130-2 may be a single-layered emission layer.

The third light-emitting device ED3 included in the third pixel area PA3 may have, e.g., a 2-stack tandem structure. The third light-emitting device ED3 may include a third lower emission layer 130-3a and a third upper emission layer 130-3b separated with the charge generation layer CGL interposed therebetween. Each of the third lower emission layer 130-3a and the third upper emission layer 130-3b may correspond to a blue emission layer.

A lower electron transfer region 140a may be between the charge generation layer CGL and the third lower emission layer 130-3a. An upper hole transfer region 120b may be between the charge generation layer CGL and the third upper emission layer 130-3b.

Accordingly, a tandem light-emitting structure in which the first electrode 110, the hole transfer region 120, the third lower emission layer 130-3a, the lower electron transfer region 140a, the charge generation layer CGL, the upper hole transfer region 120b, the third upper emission layer 130-3b, the electron transfer region 140, and the second electrode 150 are sequentially stacked may be provided in the third pixel area PA3.

FIG. 10 is a schematic cross-sectional view illustrating a display device in accordance with example embodiments.

FIG. 10 illustrates a display device having a QD-OLED structure according to embodiments. Detailed descriptions regarding elements and structures that are the same as or substantially similar to those described with reference to FIG. 7 will not be repeated here.

Referring to FIG. 10, the pixel defining layer 280 and the light-emitting device ED may be on the circuit layer CL, as described above with reference to FIG. 7. In example embodiments, each pixel may emit light of the same wavelength region. In an embodiment, each light-emitting device ED may emit a blue light.

In some embodiments, each light-emitting region may include the light-emitting device having the tandem structure, as described above with respect to FIG. 5. In embodiments, the intermediate layer of each light-emitting device ED may be provided as a common layer that continuously extends over a plurality of the light-emitting regions.

A color control layer CCL may be on the encapsulation layer 290, and the color control layer CCL may include color control portions CCP1, CCP2, and CCP3.

The color control portions CCP1, CCP2 and CCP3 may each include a light transformer such as a quantum dot and/or a phosphor. In each of the color control portions CCP1, CCP2 and CCP3, the light transformer may convert a wavelength of a provided light and emit a resulting light.

The color control portions CCP1, CCP2 and CCP3 may be separated or spaced apart from each other by a bank BM. The bank BM may substantially overlap the pixel defining layer 280, and the color control portions CCP1, CCP2 and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In some embodiments, the first color light, the second color light, and the third color light may be a blue light, a red light, and a green light, respectively. The first quantum dot and the second quantum dot may respectively be a red quantum dot and a green quantum dot.

The color control portions CCP1, CCP2 and CCP3 may each further include a light scattering material such as inorganic particles. The third color control portion CCP3 may not include quantum dots and may include the light scattering material. The scattering material may include TiO₂, ZnO, Al₂O₃, SiO₂, hollow silica, and/or the like. The scattering material may be one selected from the aforementioned materials or a combination thereof.

The color control portions CCP1, CCP2, and CCP3 may each further include a binder resin that disperses the quantum dot and the light scattering material. The binder resin may include an acrylic resin, a urethane resin, a silicone resin, an epoxy resin, and/or the like.

A color filter layer CFL that includes color filters CF1 and CF2 and a light-shielding portion CP may be on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment and/or dye, and the second filter CF2 may include a green pigment and/or dye.

The light-shielding portion CP may be between the color filters. In some embodiments, the light-shielding portion may include a first light-shielding portion CP1 and a second light-shielding portion CP2 that includes colorants of different colors.

In some embodiments, the first light-shielding portion CP1 may include a blue colorant, and the second light-shielding portion CP2 may include a red colorant and/or a black colorant. In an embodiment, in the blue light-emitting region, a portion of the first light-shielding portion CP1 may be provided as a blue color filter and may be exposed between the second light-shielding portions CP2, so that an additional color filter (e.g., the third filter) may be omitted.

A first barrier layer 310 may be between the color control layer CCL and the light-emitting device ED (or the encapsulation layer 290). A second barrier layer 320 may be between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or the like.

In an embodiment, the barrier layers 310 and 320 may each have a multi-layered structure that further includes an organic layer.

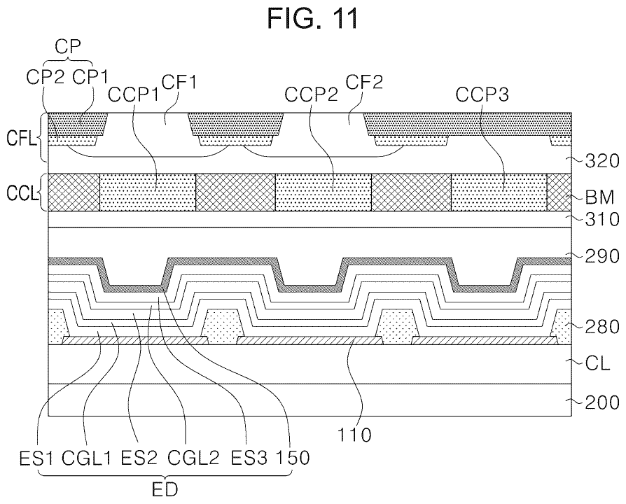

FIG. 11 is a schematic cross-sectional view illustrating a display device in accordance with example embodiments. Detailed descriptions of elements and structures substantially the same as or similar to those described with reference to FIG. 10 are omitted herein.

Referring to FIG. 11, the light-emitting device ED corresponding to the color control portions CCP1, CCP2 and CCP3 may be on the first electrode 110 serving as the pixel electrode, and the light-emitting device ED may have a tandem structure.

In some embodiments, as described with reference to FIG. 5, the first light-emitting structure ES1, the first charge generation layer CGL1, the second light-emitting structure ES2, the second charge generation layer CGL2, and the third light-emitting structure ES3 may be sequentially stacked between the first electrode 110 and the second electrode 150. The first light-emitting structure ES1, the first charge generation layer CGL1, the second light-emitting structure ES2, the second charge generation layer CGL2, and the third light-emitting structure ES3 may be continuously and commonly formed in a plurality of pixel areas or light-emitting regions.

In an embodiment, the first light-emitting structure ES1, the second light-emitting structure ES2, and the third light-emitting structure ES3 may generate different color lights, and the light-emitting device ED may generate a white light. In an embodiment, the first light-emitting structure ES1, the second light-emitting structure ES2, and the third light-emitting structure ES3 may all generate blue lights.

In some embodiments, as described with reference to FIG. 6, the light-emitting device ED may include a tandem structure of 4-stack, 5-stack, or more of the stacked number.

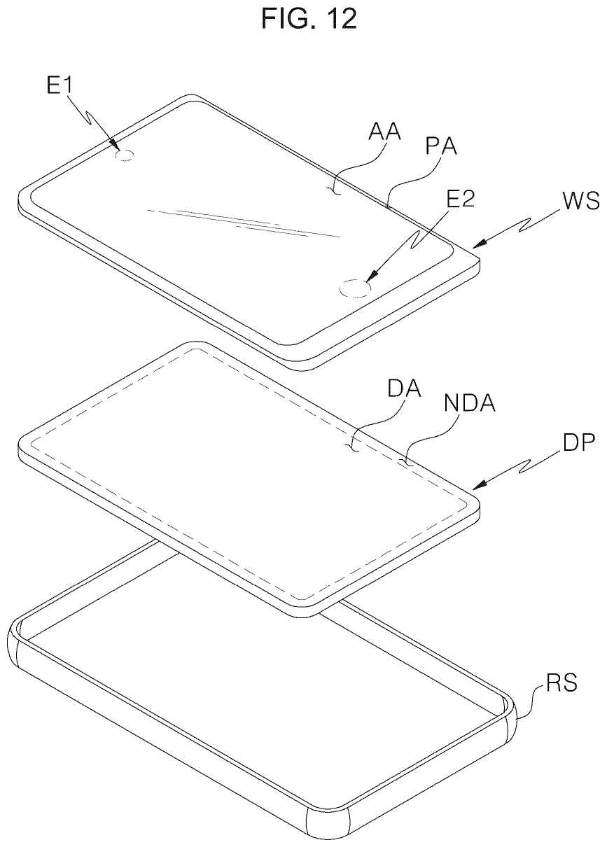

FIG. 12 is a schematic exploded perspective view illustrating an electronic device in accordance with example embodiments.

According to example embodiments, the electronic device may be implemented in the form of a mobile phone (smart phone), a tablet, a PC, and/or the like, including the above-described display device.

Referring to FIG. 12, the electronic device may include a window structure WS, a display panel DP, and a rear structure RS.

The window structure WS may provide an external display surface recognized by a user, such as a viewing surface of a mobile phone, and may include a transparent material film. For example, the window structure WS may include glass (e.g., ultra-thin glass (UTG), a hard coating film, a plastic film, and/or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display panel DP may include the above-described display device and may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for a touch sensing and/or a fingerprint sensing may be provided in the display panel DP and/or between the window structure WS and the display panel DP.

The rear structure RS may serve as a frame structure and/or a housing of the display device or the electronic device. A cover panel may be between the rear structure RS and the display panel DP.

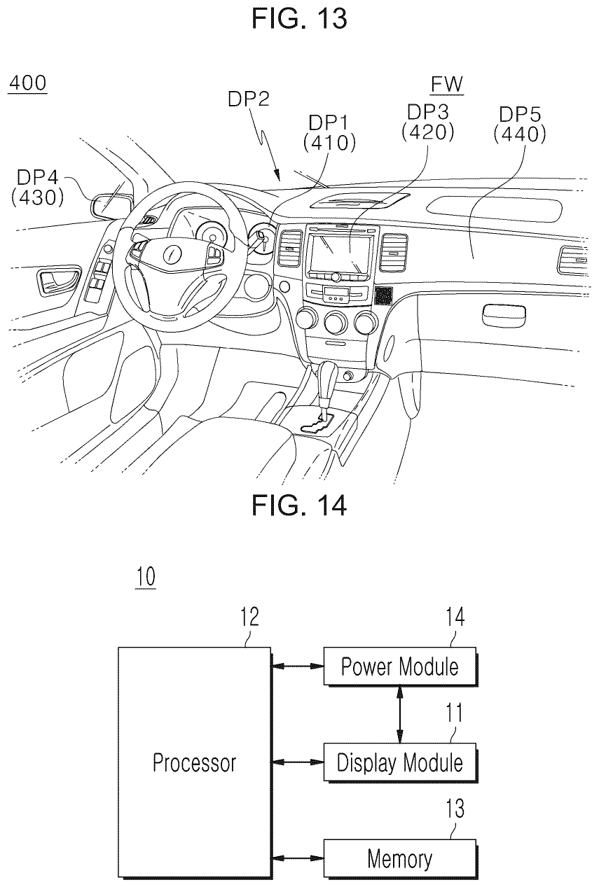

FIG. 13 is a schematic cross-sectional view illustrating an electronic device in accordance with an example embodiment.

The electronic device may be installed in, embedded in, attached to, or integrated with a vehicle 400. However, the vehicle 400 is not limited to the embodiment illustrated in FIG. 13. Further examples of the vehicle 400 may include a transportation means such as a three-wheeled or four-wheeled vehicle, a construction machine, a two-wheeled vehicle, a motor vehicle, a bicycle, a train, and/or the like. Other examples of the vehicle 400 may include an electric vehicle, a hybrid vehicle, and/or the like.

Referring to FIG. 13, at least one selected from first to fifth display devices DP1, DP2, DP3, DP4, and DP5 may be applied to the vehicle 400.

In example embodiments, the first display device DP1 may be provided in a cluster area 410. Driving information such as a driving distance and speed, and various suitable warning lights may be displayed in the cluster area 410.

The second display device DP2 may be on a front window FW of the vehicle 400. For example, the second display device DP2 may be installed as a head-up display (HUD).

The third display device DP3 may be on a center fascia 420 of the vehicle 400. In the center fascia 420, a button and/or a switch to control an image display and/or a music player, an air conditioner, a heater, and/or the like, may be displayed, and vehicle information may be displayed thereon.

The fourth display device DP4 may be applied to side mirrors 430 of the vehicle 400. A side mirror 430 may be installed at each of both sides of an exterior of the vehicle 400, and the fourth display device DP4 may be applied to at least one selected from the side mirrors 430 installed at each of the both sides.

The fifth display device DP5 may be on a passenger seat dashboard 440. Information/image identical to or different from information/image displayed on the cluster area 410 and/or the center fascia 420 may be displayed at the passenger seat dashboard 440.

The electronic device may include, e.g., a flat panel display, a curved display, a computer monitor, a medical monitor, a television, a billboard, a light for indoor or outdoor lighting, a signal light, a head-up display, a full or partial transparent display, a flexible display, a rollable display, a foldable display, a stretchable display, a laser printer, a phone, a mobile phone, a tablet, a phablet, a personal digital assistant (PDA), a wearable device, a laptop computer, a digital camera, a camcorder, a viewfinder, a micro display, a 3D display, a virtual reality and/or augmented reality display, a vehicle, a video wall including a plurality of displays tiled together, a theater and/or stadium screen, a phototherapy device, and/or a signage.

The display device according to the embodiments of the present disclosure may be applied to various suitable electronic devices. The electronic device according to an embodiment includes the above-described display device, and may further include a module and/or device having another additional function in addition to the display device.

FIG. 14 is a block diagram of an electronic device in accordance with an embodiment.

Referring to FIG. 14, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power utilized or required for the operation of the electronic device 10.

At least one selected from components of the electronic device 10 as described above may be included in the display device according to the above-described embodiments. In embodiments, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

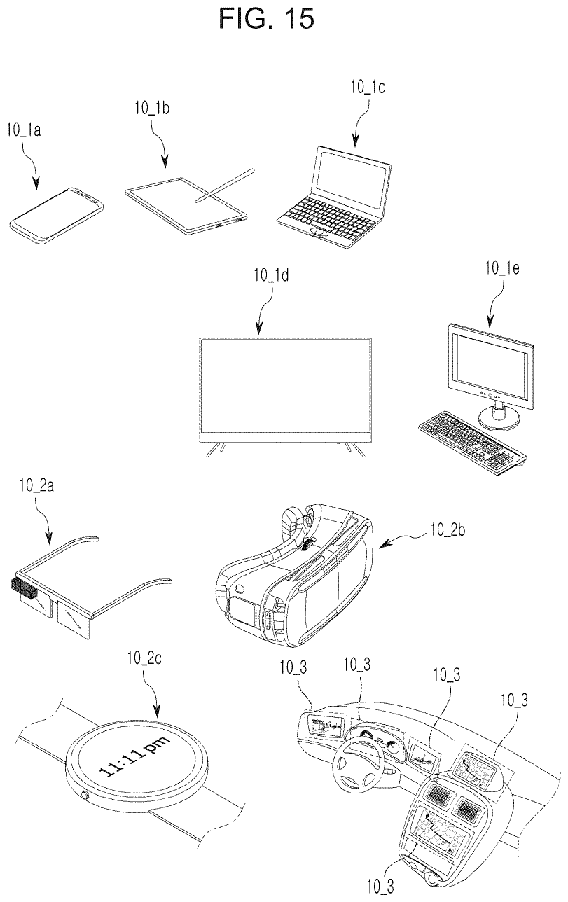

FIG. 15 shows schematic diagrams of electronic device in accordance with various suitable embodiments.

Referring to FIG. 15, non-limiting examples of various suitable electronic devices to which the display device according to the above-described embodiments is applied include an electronic device to display an image such as a smartphone 10_1a, a tablet PC 10_1b, a laptop 10_1c, a TV 10_1d, a desk monitor 10_1e, and/or the like; a wearable electronic device including a display module such as smart glasses 10_2a, a head mounted display 10_2b, a smart watch 10_2c, and/or the like; a vehicle electronic device 10_3 including a display module such as a center information display (CID) provided at a vehicle instrument panel, a center fascia, a dashboard, and/or the like, a room mirror display, a head-up display, and/or the like. The electronic device may include a virtual reality glass and/or an augmented reality glass.

Hereinafter, an organometallic compound according to an embodiment will be described in more detail with reference to the Examples and the Comparative Examples. The Examples are provided to assist in understanding the subject matter of the present disclosure, but they are provided as non-limiting examples, and the scope of the disclosure is not limited thereto. It will be clear to those skilled in the art that various suitable changes and modifications to the disclosed examples can be made within the scope of the disclosure.

### Synthesis Example 1: Synthesis of Compound 1

Compound 1 was synthesized according to a reaction scheme as follows.

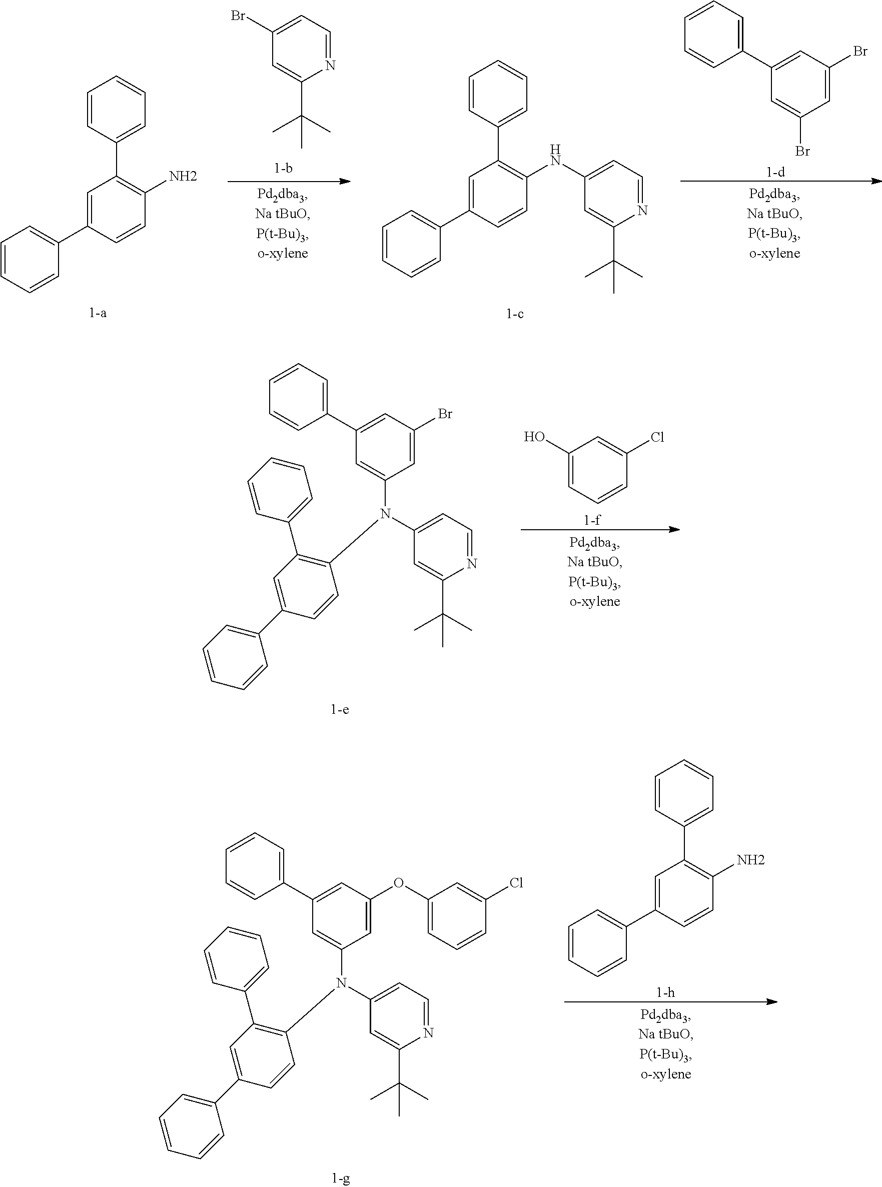

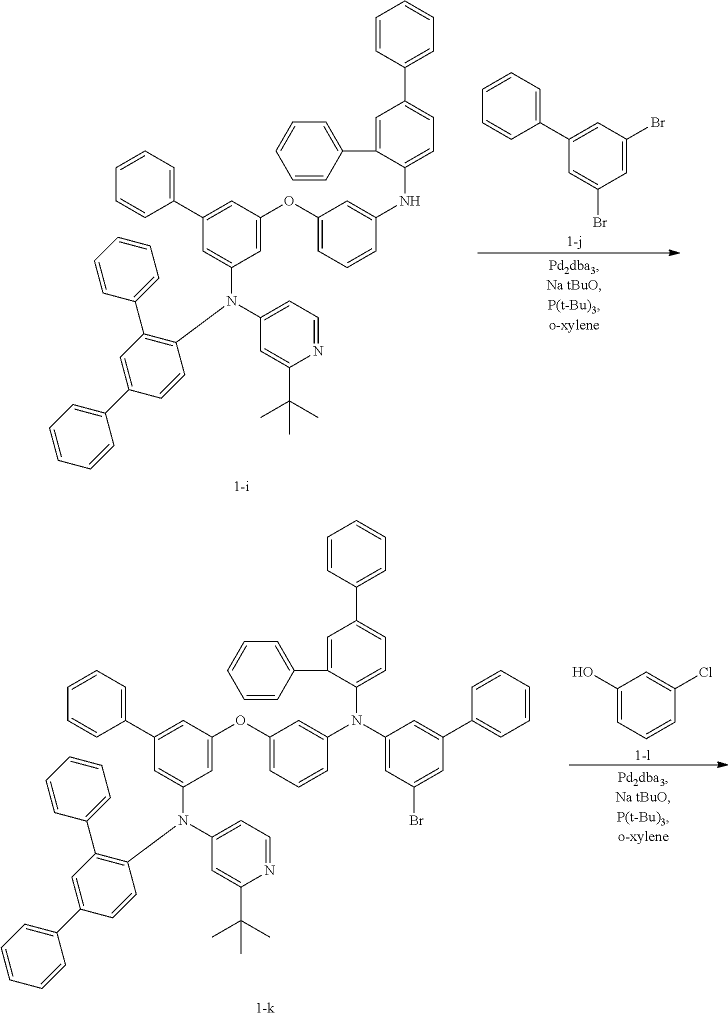

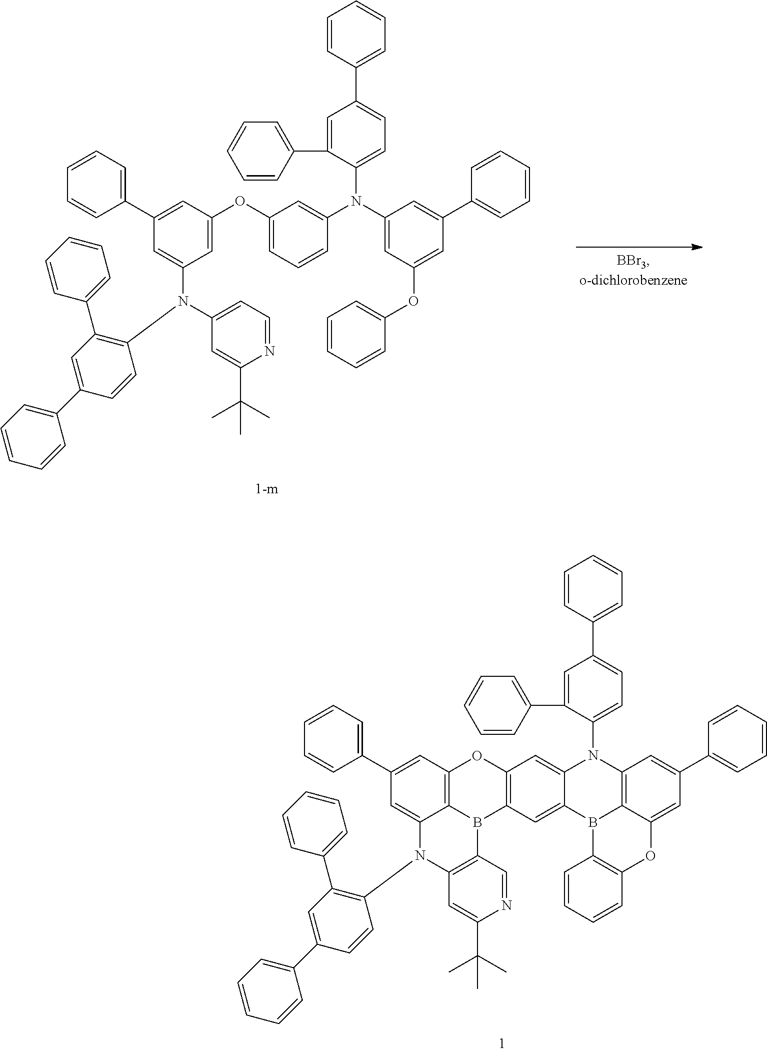 [SMILES: CC(C)(C)c1cc(N(c2cc(Oc3cccc(N(c4cc(Oc5ccccc5)cc(-c5ccccc5)c4)c4ccc(-c5ccccc5)cc4-c4ccccc4)c3)cc(-c3ccccc3)c2)c2ccc(-c3ccccc3)cc2-c2ccccc2)ccn1 ; CC(C)(C)c1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2]

### Synthesis of Intermediate Compound 1-c

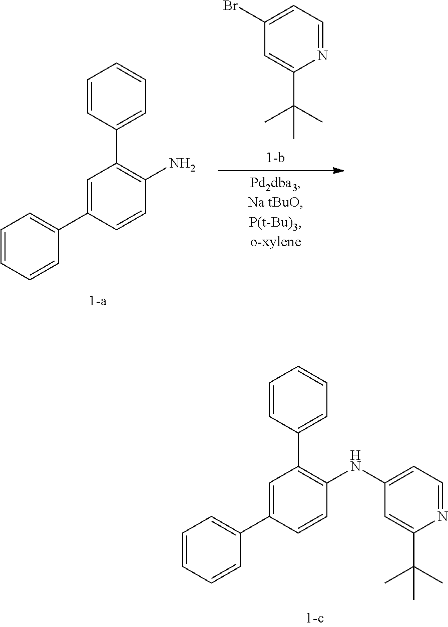 [SMILES: Nc1ccc(-c2ccccc2)cc1-c1ccccc1 ; CC(C)(C)c1cc(Br)ccn1 ; CC(C)(C)c1cc(Nc2ccc(-c3ccccc3)cc2-c2ccccc2)ccn1]

Under an argon atmosphere, [1,1′:3′,1″-terphenyl]-4′-amine (50.0 g, 204 mmol, the compound 1-a), 4-bromo-2-(tert-butyl)pyridine (47.9 g, 224 mmol, the compound 1-b), pd₂dba₃ (9.3 g, 10 mmol), tris-tert-butyl phosphine (4 mL, 20 mmol), sodium tert-butoxide (39.1 g, 408 mmol), dissolved in 1000 mL of o-xylene was put in a 2 L flask to be dissolved in 1,000 mL of o-xylene, and then the resultant reaction solution was stirred at 120° C. for 4 hours. After cooling, water and ethyl acetate were added for extraction. An organic layer was collected, and then dried over MgSO₄ and filtered. The resultant filtered solution was depressurized to remove the solvent, and the obtained solid was purified and separated by column chromatography using silica gel and using CH₂Cl₂ and hexane as a developing solvent to obtain an intermediate compound 1-c (white solid, 52.4 g, 68%).

ESI-LCMS: [M]₊: C₂₇H₂₆N₂. 378.5.

### Synthesis of Intermediate Compound 1-e

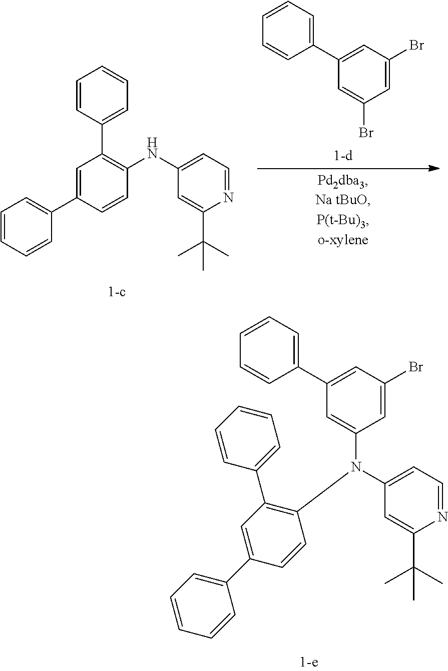 [SMILES: CC(C)(C)c1cc(Nc2ccc(-c3ccccc3)cc2-c2ccccc2)ccn1 ; Brc1cc(Br)cc(-c2ccccc2)c1 ; CC(C)(C)c1cc(N(c2cc(Br)cc(-c3ccccc3)c2)c2ccc(-c3ccccc3)cc2-c2ccccc2)ccn1]

Under an argon atmosphere, the compound 1-c (50.0 g, 132 mmol), 3,5-dibromo-1,1′-biphenyl (61.8 g, 198 mmol, the compound 1-d), pd₂dba₃ (6.0 g, 6.6 mmol), tris-tert-butyl phosphine (2.7 mL, 13.2 mmol), sodium tert-butoxide (25.3 g, 264 mmol) was put in a 2 L flask to be dissolved in 1000 mL of o-xylene, and the resultant reaction solution was stirred at 120° C. for 4 hours. After cooling, water and ethyl acetate were added for extraction. An organic layer was collected, and then dried over MgSO₄ and filtered. The resultant filtered solution was depressurized to remove the solvent, and the obtained solid was purified and separated by column chromatography using silica gel and using CH₂Cl₂ and hexane as a developing solvent to obtain an intermediate compound 1-e (white solid, 41.0 g, 51%).

ESI-LCMS: [M]₊: C₃₉H₃₃BrN₂. 609.6.

### Synthesis of Intermediate Compound 1-g

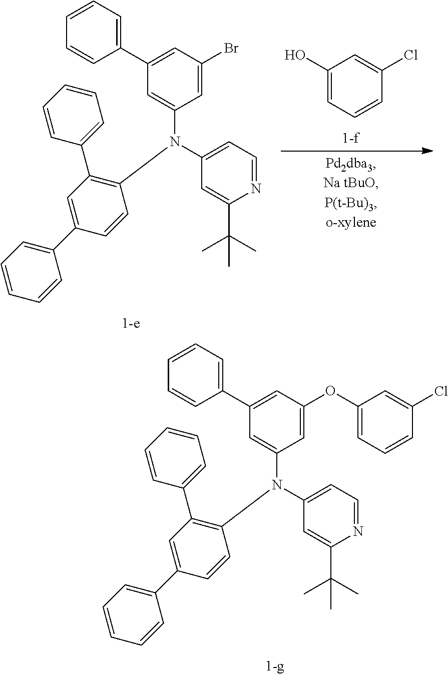 [SMILES: CC(C)(C)c1cc(N(c2cc(Br)cc(-c3ccccc3)c2)c2ccc(-c3ccccc3)cc2-c2ccccc2)ccn1 ; Oc1cccc(Cl)c1 ; CC(C)(C)c1cc(N(c2cc(Oc3cccc(Cl)c3)cc(-c3ccccc3)c2)c2ccc(-c3ccccc3)cc2-c2ccccc2)ccn1]

Under an argon atmosphere, the compound 1-e (40.0 g, 65.7 mmol), 3-chlorophenol (16.9 g, 131 mmol, the compound 1-f), picolinic acid (8.1 g, 65.7 mmol), copper(I) iodide (12.5 g, 65.7 mmol), cesium carbonate (64.2 g, 197 mmol) were added to a 2 L flask, dissolved in 650 mL of DMF, and the resultant reaction solution was stirred at 150° C. for 8 hours. After cooling, water and ethyl acetate were added for extraction. An organic layer was collected, and then dried over MgSO₄ and filtered. The solvent was removed from the resultant filtered solution under reduced pressure, and the obtained solid was purified by column chromatography using silica gel and using CH₂Cl₂ and hexane as a developing solvent to obtain an intermediate compound 1-g (white solid, 21.1 g, 49%).

ESI-LCMS: [M]₊: C₄₅H₃₇ClN₂O. 657.2.

### Synthesis of Intermediate Compound 1-i

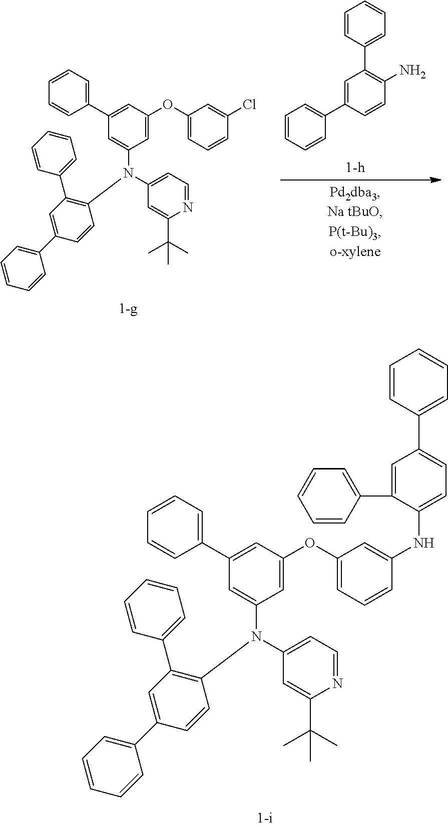

Under an argon atmosphere, the compound 1-g (20.0 g, 30.4 mmol), [1,1′:3′,1″-terphenyl]-4′-amine (8.2 g, 33.4 mmol, the compound 1-h), pd₂dba₃ (1.4 g, 1.5 mmol), tris-tert-butyl phosphine (0.6 mL, 3.0 mmol), sodium tert-butoxide (8.8 g, 91.2 mmol) was put in a 1 L flask, dissolved in 300 mL of o-xylene, and the resultant reaction solution was stirred at 120° C. for 4 hours. After cooling, water and ethyl acetate were added for extraction. An organic layer was collected, and then dried over MgSO₄ and filtered. The resultant filtered solution was depressurized to remove the solvent, and the obtained solid was purified and separated by column chromatography using silica gel and using CH₂Cl₂ and hexane as a developing solvent to obtain an intermediate compound 1-i (white solid, 20.5 g, 78%).

ESI-LCMS: [M]₊: C₆₃H₅₁N₃O. 866.1.

### Synthesis of Intermediate Compound 1-k

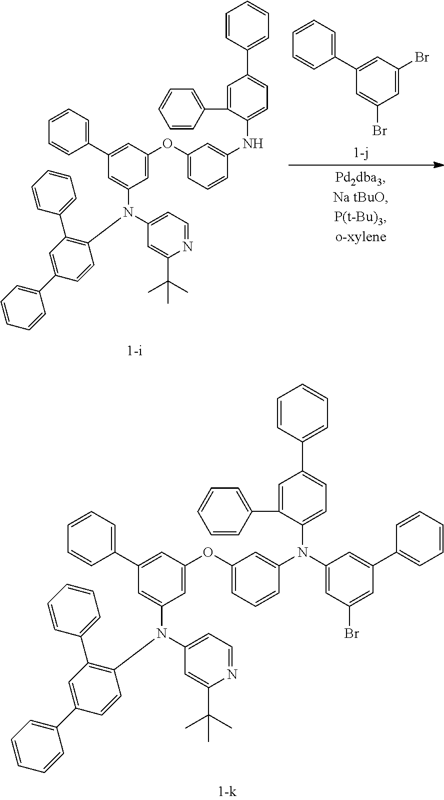

Under an argon atmosphere, the compound 1-i (20.0 g, 23.1 mmol), 3,5-dibromo-1,1′-biphenyl (10.8 g, 34.7 mmol, the compound 1-j), pd₂dba₃ (1.1 g, 1.1 mmol), tris-tert-butyl phosphine (0.4 mL, 2.2 mmol), sodium tert-butoxide (4.4 g, 46.2 mmol), were put a 1 L flask to be dissolved in 230 mL of o-xylene, and the resultant reaction solution was stirred at 120° C. for 4 hours. After cooling, water and ethyl acetate were added for extraction. An organic layer was collected, and then dried over MgSO₄ and filtered. The resultant filtered solution was depressurized to remove the solvent, and the obtained solid was purified and separated by column chromatography using silica gel and using CH₂Cl₂ and hexane as a developing solvent to obtain an intermediate compound 1-k (white solid, 14.7 g, 58%).

ESI-LCMS: [M]₊: C₇₅H₅₈BrN₃O. 1097.2.

### Synthesis of Intermediate Compound 1-m

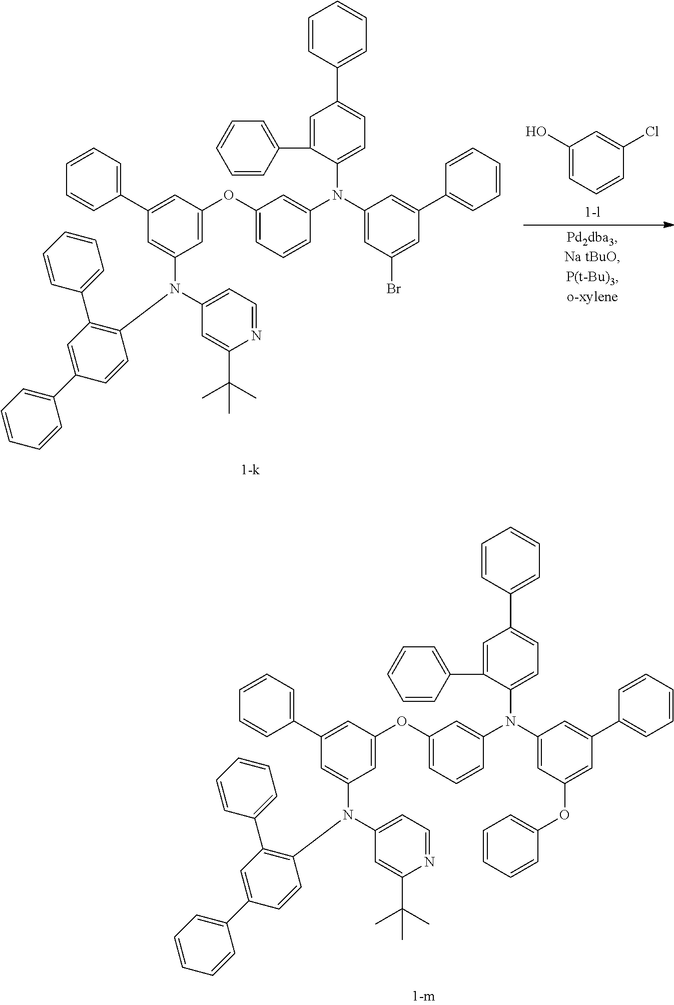 [SMILES: CC(C)(C)c1cc(N(c2cc(Oc3cccc(N(c4cc(Br)cc(-c5ccccc5)c4)c4ccc(-c5ccccc5)cc4-c4ccccc4)c3)cc(-c3ccccc3)c2)c2ccc(-c3ccccc3)cc2-c2ccccc2)ccn1 ; Oc1cccc(Cl)c1 ; CC(C)(C)c1cc(N(c2cc(Oc3cccc(N(c4cc(Oc5ccccc5)cc(-c5ccccc5)c4)c4ccc(-c5ccccc5)cc4-c4ccccc4)c3)cc(-c3ccccc3)c2)c2ccc(-c3ccccc3)cc2-c2ccccc2)ccn1]

Under an argon atmosphere, the compound 1-k (14.0 g, 12.7 mmol), phenol (3.6 g, 38.3 mmol, the compound of 1-l), picolinic acid (1.6 g, 12.7 mmol), copper(I) iodide (2.4 g, 12.7 mmol), cesium carbonate (12.5 g, 38.3 mmol) were added to a 500 mL flask to be dissolved in 130 mL of DMF, and the resultant reaction solution was stirred at 150° C. for 8 hours. After cooling, water and ethyl acetate were added for extraction. An organic layer were collected, and then dried over MgSO₄ and filtered. The solvent was removed from the resultant filtered solution under reduced pressure, and the obtained solid was purified by column chromatography using silica gel and using CH₂Cl₂ and hexane as a developing solvent to obtain an intermediate compound 1-m (white solid, 7.8 g, 55%).

ESI-LCMS: [M]₊: C₈₁H₆₃N₃O₂. 1110.4.

### Synthesis of Compound 1

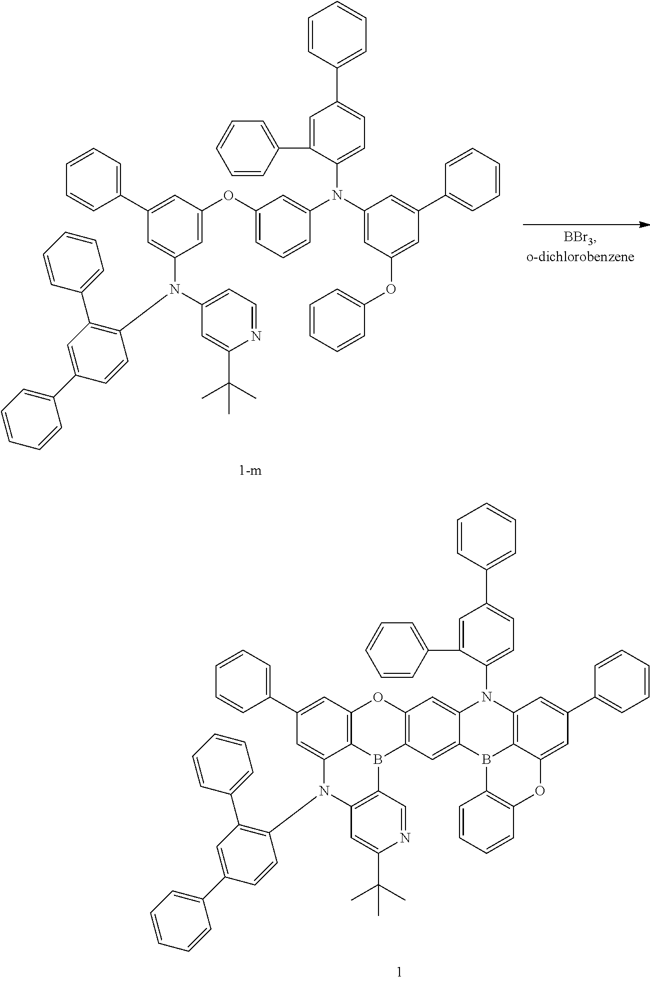 [SMILES: CC(C)(C)c1cc(N(c2cc(Oc3cccc(N(c4cc(Oc5ccccc5)cc(-c5ccccc5)c4)c4ccc(-c5ccccc5)cc4-c4ccccc4)c3)cc(-c3ccccc3)c2)c2ccc(-c3ccccc3)cc2-c2ccccc2)ccn1 ; CC(C)(C)c1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2]

Under an argon atmosphere, the compound 1-m (7.5 g, 6.8 mmol) was added to a 250 mL flask, dissolved in 70 mL of o-dichlorobenzene, and then BBr₃ (3.0 equiv.) was added. The resultant reaction solution was stirred at 140° C. for 12 hours. After cooling, triethylamine was added, and the solvent was removed under reduced pressure. The obtained solid was purified by column chromatography using silica gel and using CH₂Cl₂ and hexane as a developing solvent to obtain a compound 1 (yellow solid, 1.5 g, 20%).

ESI-LCMS: [M]₊: C₈₁H₅₇B₂N₃O₂. 1125.9

1H-NMR (CDCl₃): δ=8.24 (s, 1H), 7.90 (s, 2H), 7.75-7.65 (m, 11H), 7.56-7.41 (m, 21H), 7.25 (s, 1H), 7.08-6.99 (m, 10H), 6.86 (s, 1H), 6.46 (s, 1H), 1.36 (s, 9H).

### Synthesis Examples 2 to 9: Synthesis of Compounds 5, 20, 36, 68, 73, 90, 94, and 114

Compounds 5, 20, 36, 68, 73, 90, 94, and 114 were synthesized using the same synthetic conditions as those of the synthesis scheme of the compound 1 described above, except that compounds described in Table 1 below were used. The obtained compounds were confirmed as shown in Table 2 by a mass spectrometry using ESI-LCMS.

TABLE 1

| | Synthesis | Synthesis | Synthesis | Synthesis |
|---|---|---|---|---|
| | Example 2 | Example 3 | Example 4 | Example 5 |
| | compound 5 | compound 20 | compound 36 | compound 68 |
| 1-a | 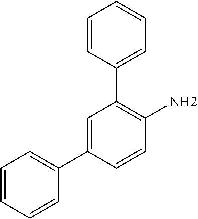 [SMILES: Nc1ccc(-c2ccccc2)cc1-c1ccccc1] | 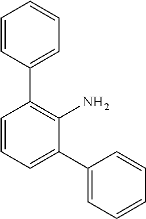 [SMILES: Nc1c(-c2ccccc2)cccc1-c1ccccc1] | 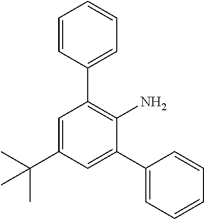 [SMILES: CC(C)(C)c1cc(-c2ccccc2)c(N)c(-c2ccccc2)c1] | 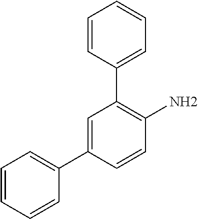 [SMILES: Nc1ccc(-c2ccccc2)cc1-c1ccccc1] |
| 1-b | 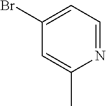 | 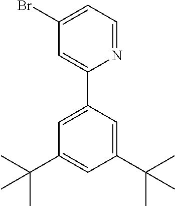 [SMILES: CC(C)(C)c1cc(-c2cc(Br)ccn2)cc(C(C)(C)C)c1] | 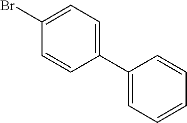 [SMILES: Brc1ccc(-c2ccccc2)cc1] | 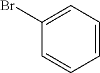 |
| 1-d | 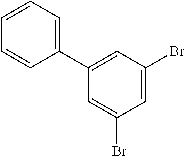 [SMILES: Brc1cc(Br)cc(-c2ccccc2)c1] | 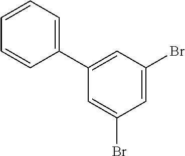 [SMILES: Brc1cc(Br)cc(-c2ccccc2)c1] | 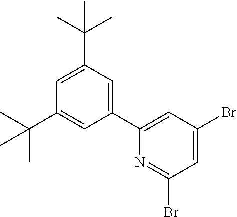 [SMILES: CC(C)(C)c1cc(-c2cc(Br)cc(Br)n2)cc(C(C)(C)C)c1] | 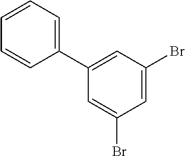 [SMILES: Brc1cc(Br)cc(-c2ccccc2)c1] |
| 1-f | 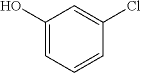 | 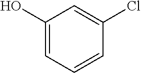 | 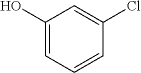 | 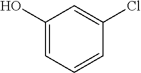 |
| 1-h | 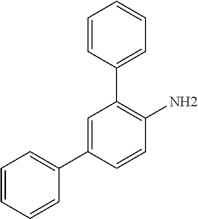 [SMILES: Nc1ccc(-c2ccccc2)cc1-c1ccccc1] | 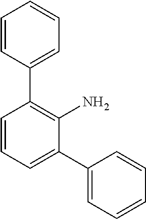 [SMILES: Nc1c(-c2ccccc2)cccc1-c1ccccc1] | 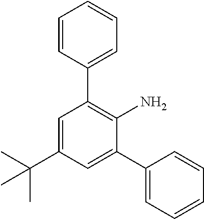 [SMILES: CC(C)(C)c1cc(-c2ccccc2)c(N)c(-c2ccccc2)c1] | 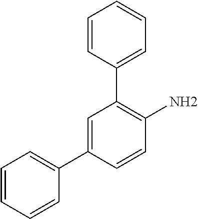 [SMILES: Nc1ccc(-c2ccccc2)cc1-c1ccccc1] |
| 1-j | 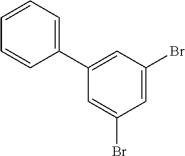 [SMILES: Brc1cc(Br)cc(-c2ccccc2)c1] | 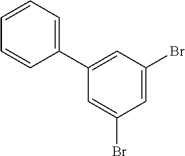 [SMILES: Brc1cc(Br)cc(-c2ccccc2)c1] | 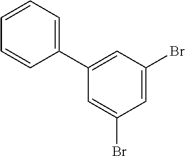 [SMILES: Brc1cc(Br)cc(-c2ccccc2)c1] | 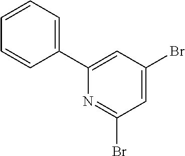 [SMILES: Brc1cc(Br)nc(-c2ccccc2)c1] |
| 1-l | 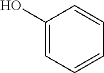 | 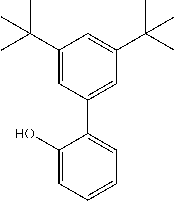 [SMILES: CC(C)(C)c1cc(-c2ccccc2O)cc(C(C)(C)C)c1] | 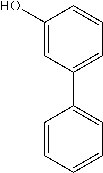 [SMILES: Oc1cccc(-c2ccccc2)c1] | 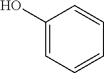 |
| | Synthesis | Synthesis | Synthesis | Synthesis |
| | Example 6 | Example 7 | Example 8 | Example 9 |
| | compound 73 | compound 90 | compound 94 | compound 114 |
| 1-a | 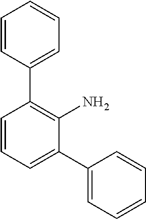 [SMILES: Nc1c(-c2ccccc2)cccc1-c1ccccc1] | 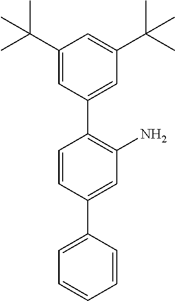 [SMILES: CC(C)(C)c1cc(-c2ccc(-c3ccccc3)cc2N)cc(C(C)(C)C)c1] | 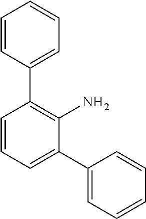 [SMILES: Nc1c(-c2ccccc2)cccc1-c1ccccc1] | 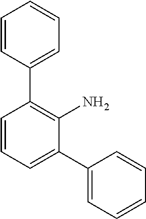 [SMILES: Nc1c(-c2ccccc2)cccc1-c1ccccc1] |
| 1-b | 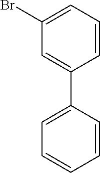 [SMILES: Brc1cccc(-c2ccccc2)c1] | 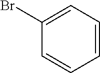 | 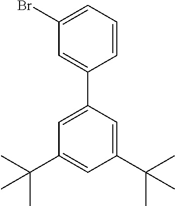 [SMILES: CC(C)(C)c1cc(-c2cccc(Br)c2)cc(C(C)(C)C)c1] | 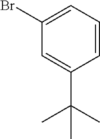 |
| 1-d | 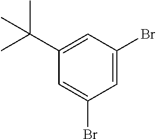 | 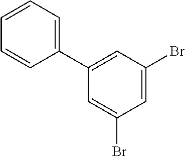 [SMILES: Brc1cc(Br)cc(-c2ccccc2)c1] | 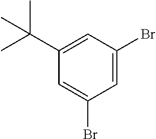 | 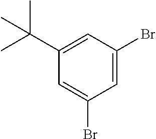 |
| 1-f | 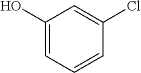 | 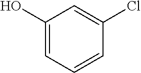 | 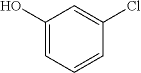 | 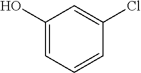 |
| 1-h | 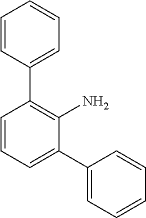 [SMILES: Nc1c(-c2ccccc2)cccc1-c1ccccc1] | 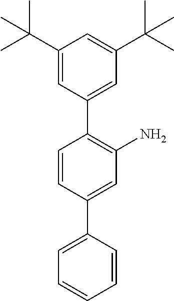 [SMILES: CC(C)(C)c1cc(-c2ccc(-c3ccccc3)cc2N)cc(C(C)(C)C)c1] | 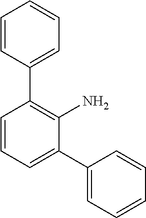 [SMILES: Nc1c(-c2ccccc2)cccc1-c1ccccc1] | 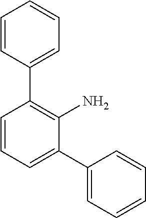 [SMILES: Nc1c(-c2ccccc2)cccc1-c1ccccc1] |
| 1-j | 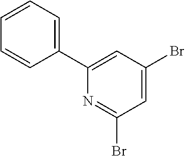 [SMILES: Brc1cc(Br)nc(-c2ccccc2)c1] | 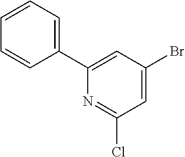 [SMILES: Clc1cc(Br)cc(-c2ccccc2)n1] | 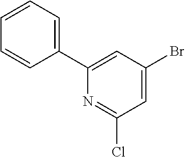 [SMILES: Clc1cc(Br)cc(-c2ccccc2)n1] | 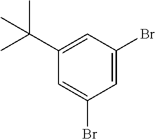 |
| 1-l | 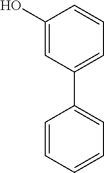 [SMILES: Oc1cccc(-c2ccccc2)c1] | 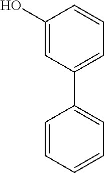 [SMILES: Oc1cccc(-c2ccccc2)c1] | 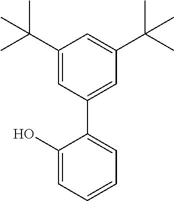 [SMILES: CC(C)(C)c1cc(-c2ccccc2O)cc(C(C)(C)C)c1] | 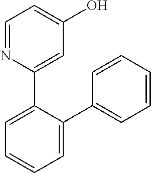 [SMILES: Oc1ccnc(-c2ccccc2-c2ccccc2)c1] |

TABLE 2
ESI-LCMS [M+]

| compound 5 | compound 20 | compound 36 | compound 68 |
|---|---|---|---|
| C₇₈H₅₁B₂N₃O₂. | C₁₀₅H₈₉B₂N₃O₂. | C₁₀₅H₈₉B₂N₃O₂. | C₇₇H₄₉B₂N₃O₂. |
| 1083.9 | 1446.5 | 1446.5 | 1069.8 |
| compound 73 | compound 90 | compound 94 | compound 114 |
| C₈₇H₆₁B₂N₃O₂. | C₉₉H₈₅B₂N₃O₂. | C₁₀₃H₉₃B₂N₃O₂. | C₈₉H₇₃B₂N₃O₂. |
| 1202.1 | 1370.4 | 1426.5 | 1238.2 |

### Fabrication of Light-Emitting Device

As the first electrode, a glass substrate (Corning product) on which a 15 Ω/cm² (1200 Å) ITO electrode was formed was cut into a size of 50 mm×50 mm×0.7 mm, and the cut substrate was ultrasonically cleaned for 5 minutes using isopropyl alcohol and pure water. The ultrasonically cleaned substrate was irradiated with an ultraviolet ray for 30 minutes and exposed to ozone, and then mounted on a vacuum deposition device.

Thereafter, NPB (N,N′-di(naphthalene-1-yl)-N,N′-diphenyl-benzidine) was deposited on the anode to form a hole injection layer having a thickness of 300 Å. HT-13 was deposited on the hole injection layer to form a hole transport layer having a thickness of 200 Å. CzSi (9-(4-tert-butylphenyl)-3,6-bis(triphenylsilyl)-9H-carbazole) was deposited on the hole transport layer to form an auxiliary emission layer having a thickness of 100 Å.

A host mixture of PH-13 and ET-16 mixed in a weight ratio of 1:1, PD1-13 and a dopant compound were co-deposited in a weight ratio of 82:15:3 on the auxiliary emission layer a to form an emission layer having a thickness of 200 Å.

TSPO1 (diphenyl (4-(triphenylsilyl)phenyl) phosphine oxide) was deposited on the emission layer to form a hole blocking layer having a thickness of 200 Å. TPBi (1,3,5-tri(1-phenyl-1H-benzo[d]imidazol-2-yl)benzene) was deposited on the hole blocking layer to form an electron transport layer having a thickness of 300 Å. LiF was deposited on the electron transport layer to form an electron injection layer having a thickness of 10 Å. Al was deposited on the electron injection layer to form a cathode having a thickness of 3000 Å, and HT-7 was deposited on the cathode to form a capping layer having a thickness of 700 Å to obtain a light-emitting device. Each layer was formed by a vacuum deposition method.

As the above-mentioned dopant compound, compounds of Examples synthesized according to the above-described Synthesis Examples and commercially available compounds of Comparative Examples as shown below were used.

### Compounds of Examples

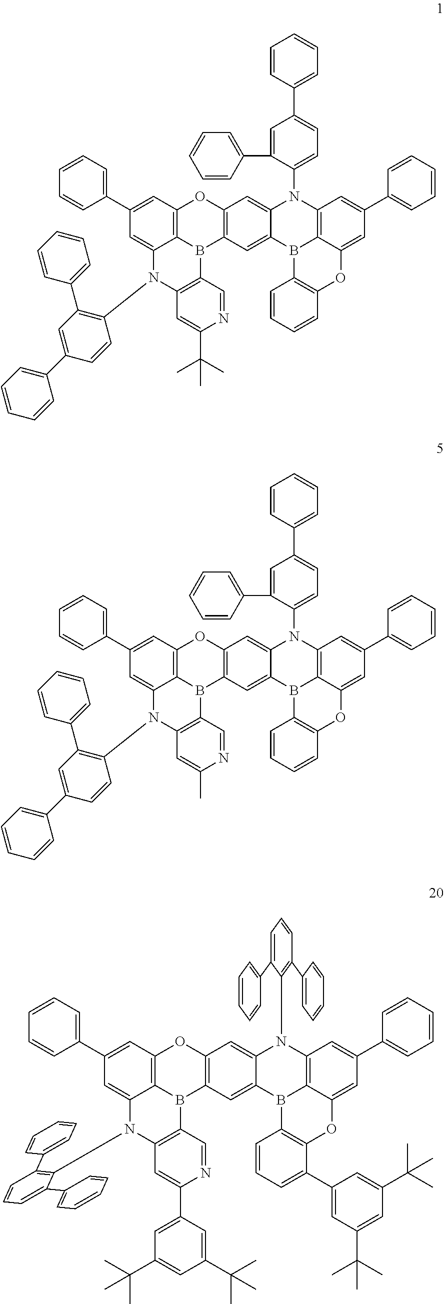 [SMILES: CC(C)(C)c1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2 ; Cc1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2 ; CC(C)(C)c1cc(-c2cc3c(cn2)B2c4cc5c(cc4Oc4cc(-c6ccccc6)cc(c42)N3c2c(-c3ccccc3)cccc2-c2ccccc2)N(c2c(-c3ccccc3)cccc2-c2ccccc2)c2cc(-c3ccccc3)cc3c2B5c2cccc(-c4cc(C(C)(C)C)cc(C(C)(C)C)c4)c2O3)cc(C(C)(C)C)c1]

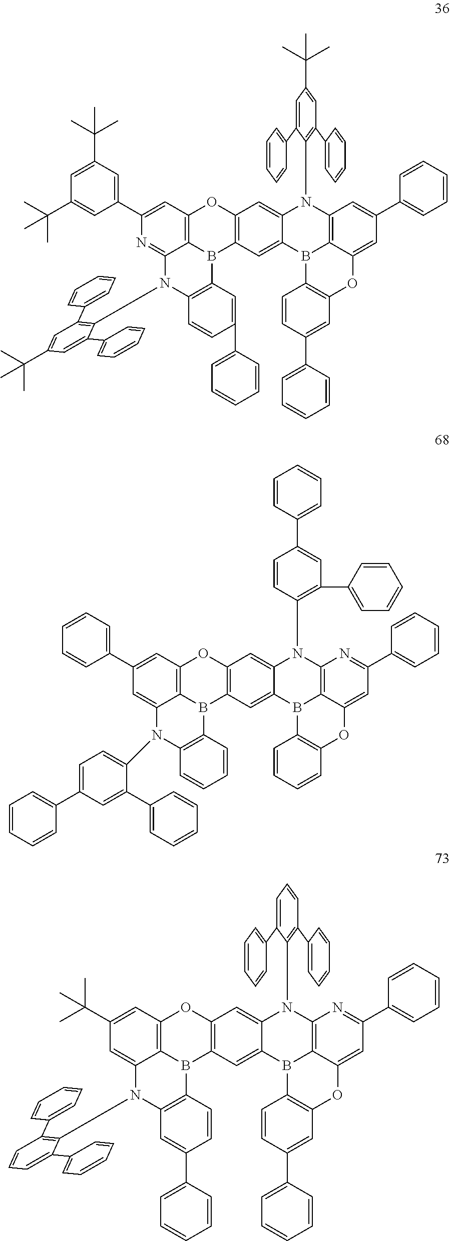

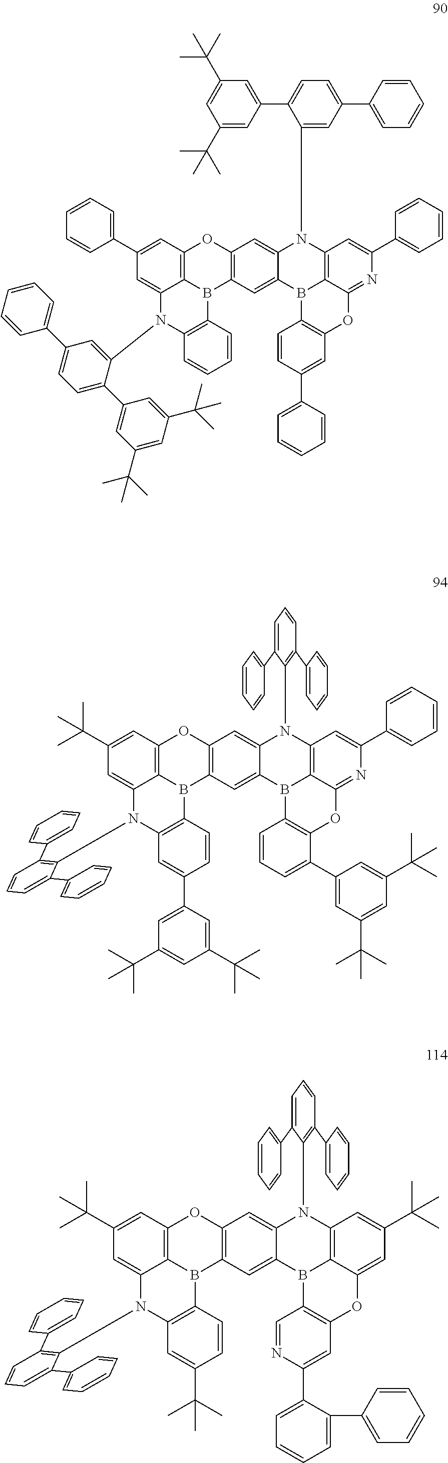

### Compounds of Comparative Examples

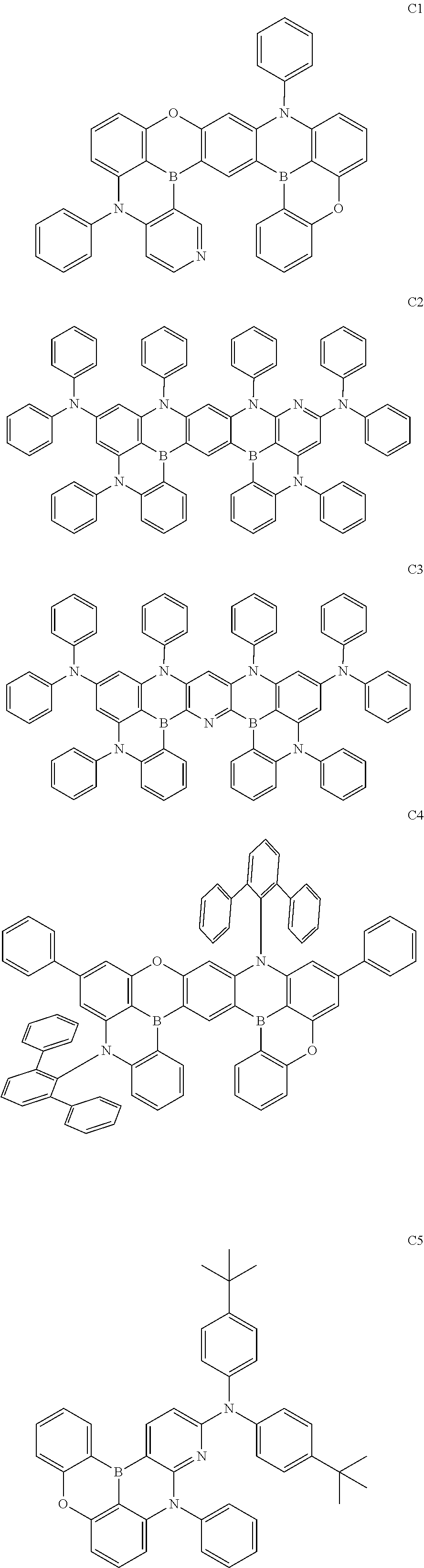

The following compounds were used in the fabrication of the light-emitting device. Specifically, the commercially available products were used after sublimation purification.

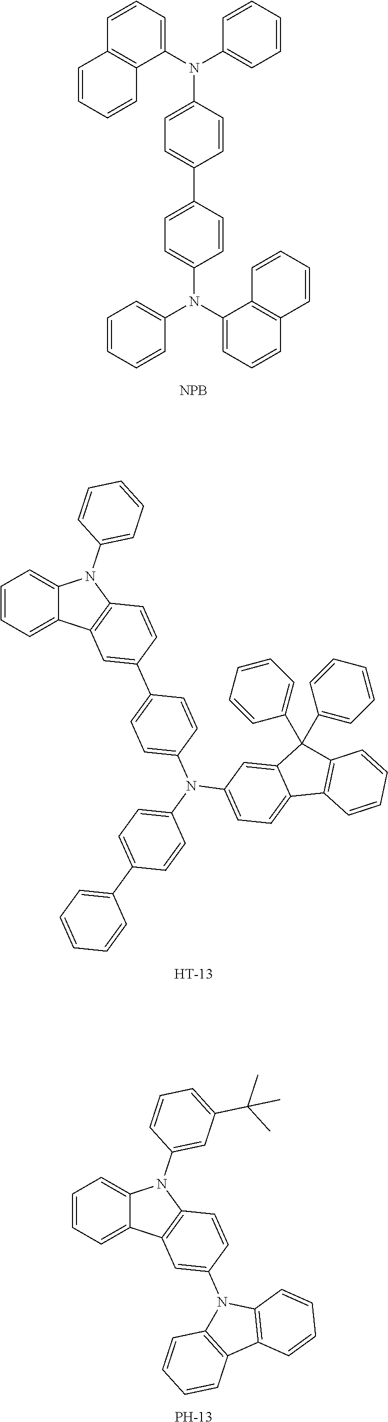

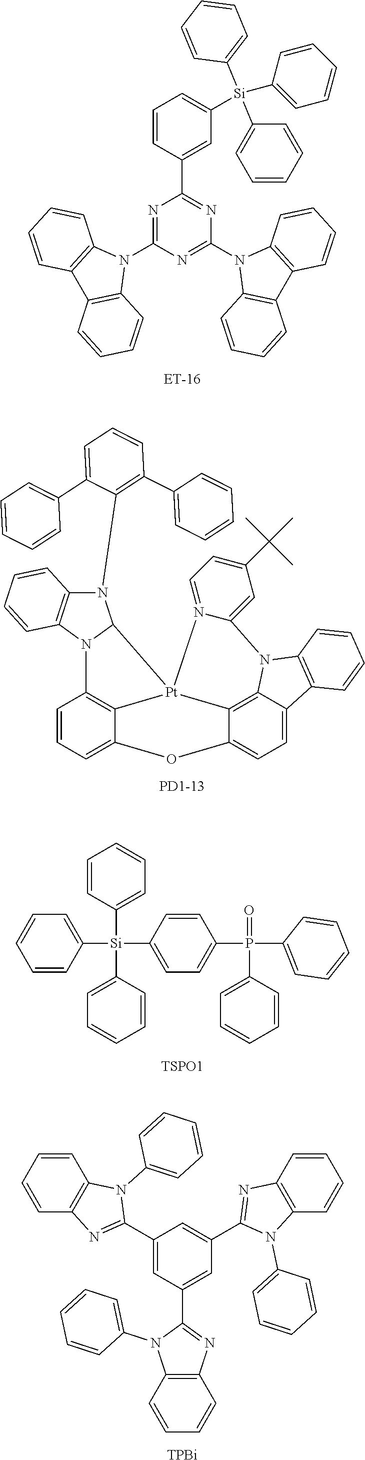

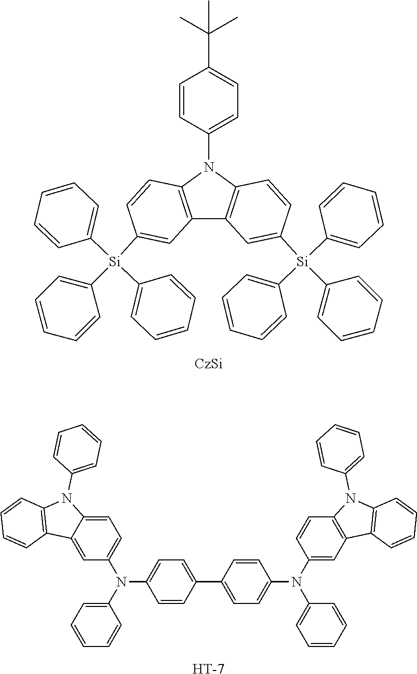

### EVALUATION EXAMPLE

### Evaluation Example 1: Evaluation on Luminescent Core Properties of Polycyclic Compounds

Properties of the compounds of Examples and Comparative Examples were evaluated.

HOMO and LUMO energy levels (eV), and energy levels (eV) of a singlet state of the compounds were evaluated by a density functional theory (DFT) method calculated utilizing a Gaussian 09 program which was structure-optimized at a hybrid functional/basis set of B3LYP/6-311G** level. In the molecular orbital calculation, Gaussian09 (a product of Gaussian) was used, B3LYP was utilized as a hybrid functional and 6-31G was utilized as a basis set, and the calculations were performed using DFT (density functional theory).

The results are shown in Table 3 below.

TABLE 3

| | | S1 | HOMO |
|---|---|---|---|
| | structure | (eV) | (eV) |
| A-1 | 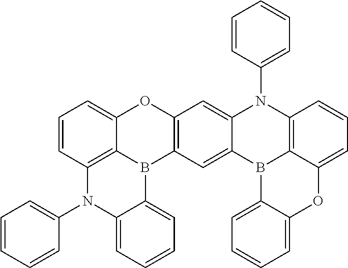 [SMILES: c1ccc(N2c3ccccc3B3c4cc5c(cc4Oc4cccc2c43)N(c2ccccc2)c2cccc3c2B5c2ccccc2O3)cc1] | 2.99 | −5.27 |
| A-2 | 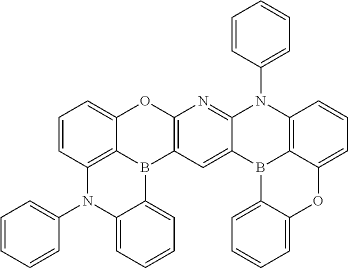 [SMILES: c1ccc(N2c3ccccc3B3c4cc5c(nc4Oc4cccc2c43)N(c2ccccc2)c2cccc3c2B5c2ccccc2O3)cc1] | 2.92 | −5.37 |
| A-3 | 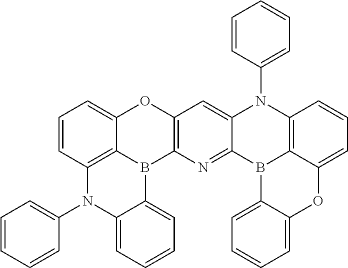 [SMILES: c1ccc(N2c3ccccc3B3c4nc5c(cc4Oc4cccc2c43)N(c2ccccc2)c2cccc3c2B5c2ccccc2O3)cc1] | 2.94 | −5.32 |
| A-4 | 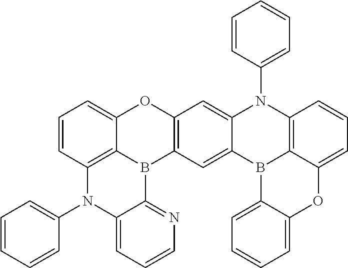 [SMILES: c1ccc(N2c3cc4c(cc3B3c5ccccc5Oc5cccc2c53)B2c3ncccc3N(c3ccccc3)c3cccc(c32)O4)cc1] | 2.90 | −5.24 |
| A-5 | 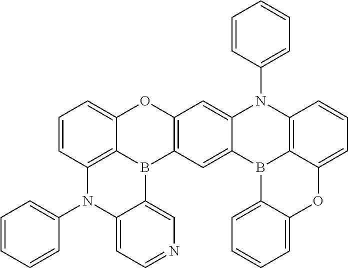 [SMILES: c1ccc(N2c3ccncc3B3c4cc5c(cc4Oc4cccc2c43)N(c2ccccc2)c2cccc3c2B5c2ccccc2O3)cc1] | 3.00 | −5.39 |
| A-6 | 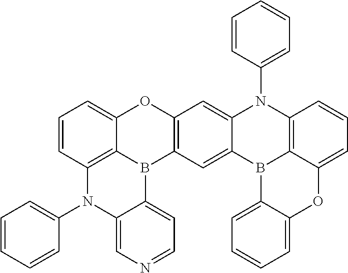 [SMILES: c1ccc(N2c3cnccc3B3c4cc5c(cc4Oc4cccc2c43)N(c2ccccc2)c2cccc3c2B5c2ccccc2O3)cc1] | 2.92 | −5.40 |
| A-7 | 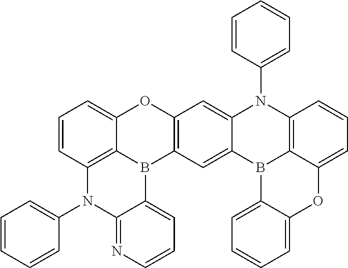 [SMILES: c1ccc(N2c3cc4c(cc3B3c5ccccc5Oc5cccc2c53)B2c3cccnc3N(c3ccccc3)c3cccc(c32)O4)cc1] | 2.95 | −5.40 |
| A-8 | 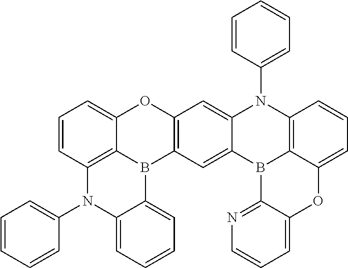 [SMILES: c1ccc(N2c3ccccc3B3c4cc5c(cc4Oc4cccc2c43)N(c2ccccc2)c2cccc3c2B5c2ncccc2O3)cc1] | 2.90 | −5.22 |
| A-9 | 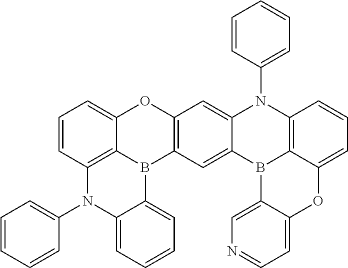 [SMILES: c1ccc(N2c3ccccc3B3c4cc5c(cc4Oc4cccc2c43)N(c2ccccc2)c2cccc3c2B5c2cnccc2O3)cc1] | 2.98 | −5.35 |
| A-10 | 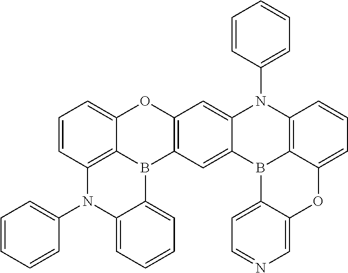 [SMILES: c1ccc(N2c3ccccc3B3c4cc5c(cc4Oc4cccc2c43)N(c2ccccc2)c2cccc3c2B5c2ccncc2O3)cc1] | 2.92 | −5.40 |
| A-11 | 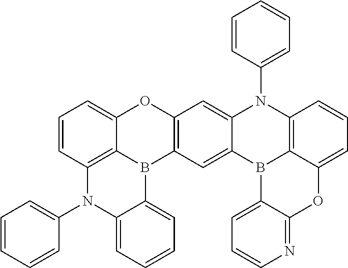 [SMILES: c1ccc(N2c3ccccc3B3c4cc5c(cc4Oc4cccc2c43)N(c2ccccc2)c2cccc3c2B5c2cccnc2O3)cc1] | 2.95 | −5.37 |
| A-12 | 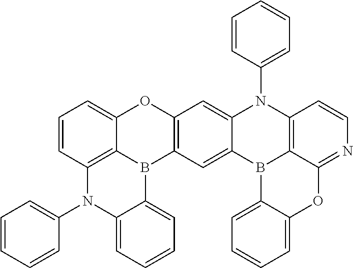 [SMILES: c1ccc(N2c3ccccc3B3c4cc5c(cc4Oc4cccc2c43)N(c2ccccc2)c2ccnc3c2B5c2ccccc2O3)cc1] | 3.03 | −5.43 |
| A-13 | 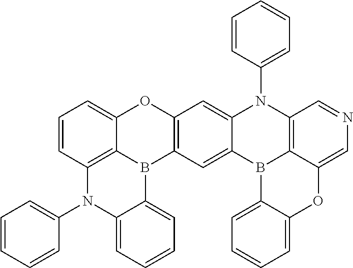 [SMILES: c1ccc(N2c3ccccc3B3c4cc5c(cc4Oc4cccc2c43)N(c2ccccc2)c2cncc3c2B5c2ccccc2O3)cc1] | 2.92 | −5.40 |
| A-14 | 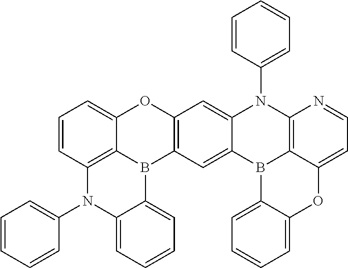 [SMILES: c1ccc(N2c3ccccc3B3c4cc5c(cc4Oc4cccc2c43)N(c2ccccc2)c2nccc3c2B5c2ccccc2O3)cc1] | 3.02 | −5.40 |
| A-15 | 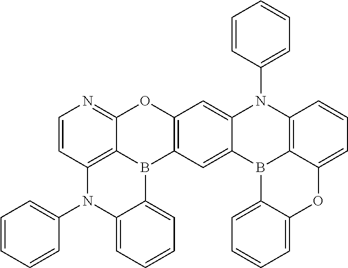 [SMILES: c1ccc(N2c3cc4c(cc3B3c5ccccc5Oc5cccc2c53)B2c3ccccc3N(c3ccccc3)c3ccnc(c32)O4)cc1] | 3.01 | −5.39 |
| A-16 | 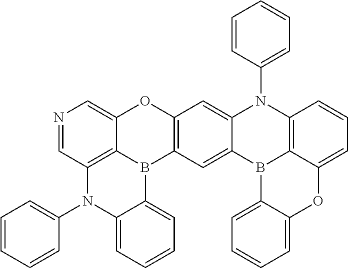 [SMILES: c1ccc(N2c3cc4c(cc3B3c5ccccc5Oc5cccc2c53)B2c3ccccc3N(c3ccccc3)c3cncc(c32)O4)cc1] | 2.92 | −5.41 |
| A-17 | 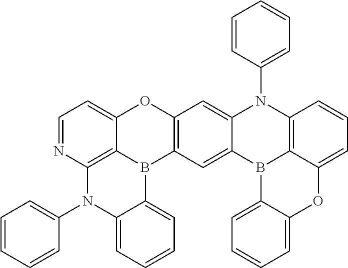 [SMILES: c1ccc(N2c3cc4c(cc3B3c5ccccc5Oc5cccc2c53)B2c3ccccc3N(c3ccccc3)c3nccc(c32)O4)cc1] | 3.00 | −5.43 |

The luminescent cores included in the compounds of Examples are the structures indicated by A-5 (Examples 1, 2 and 5), A-9 (Example 9), A-12 (Examples 4 and 8), A-14 (Examples 3 and 7), A-15 and A-17 (Example 6). In the luminescent cores of A-5, A-9, A-12, A-14, A-15, and A-17, the HOMO energy level was deep below −5.35 eV, and the energy level (S1) of the singlet state was high as being 2.98 eV or more.

In the structure indicated by A-1 (Comparative Example 4) devoid of the electron-deficient nitrogen atom, the HOMO energy level was excessively shallow.

However, in the luminescent cores of A-5, A-9, A-12, A-14, A-15 and A-17, both deep HOMO energy and high S1 energy were implemented by replacing a C atom having a dominant HOMO distribution relatively to the LUMO with the electron-deficient N atom.

Accordingly, in the polycyclic compounds according to the Examples, the chemical stability can be improved by the deep HOMO energy level, and the color purity can be improved by the high singlet state energy level.

Additionally, in the luminescent cores having the structures indicated as A-2 to A-4, A-6 to A-8, A-10, A-11, A-13, and A-16, in which a C atom other than the C atom having the dominant HOMO distribution relatively to the LUMO is replaced with the N atom, deep HOMO energy and high S1 energy were not both implemented.

### Evaluation Example 2. Evaluation of Properties of Polycyclic Compounds

The properties of the compounds of Examples and Comparative Examples were evaluated as follows.

The HOMO energy level (eV) was measured using Smart Manager software in SP2 electrochemical workstation of ZIVE LAB. A maximum emission central wavelength (nm) was measured using HORIBA fluoromax+ spectrometer equipped with a xenon light source and a monochromator, and FluorEssence software. The results are shown in Table 4 below.

TABLE 4

| | | | maximum emission |
|---|---|---|---|
| | Dopant | HOMO(eV) | wavelength (nm) |
| Example 1 | compound 5 | −5.44 | 456 |
| Example 2 | compound 1 | −5.44 | 456 |
| Example 3 | compound 68 | −5.44 | 456 |
| Example 4 | compound 90 | −5.43 | 458 |
| Example 5 | compound 20 | −5.4 | 459 |
| Example 6 | compound 36 | −5.42 | 462 |
| Example 7 | compound 73 | −5.4 | 459 |
| Example 8 | compound 94 | −5.42 | 458 |
| Example 9 | compound 114 | −5.39 | 458 |
| Comparative | compound C1 | −5.43 | 445 |
| Example 1 | | | |
| Comparative | compound C2 | −5.19 | 451 |
| Example 2 | | | |
| Comparative | compound C3 | −5.11 | 499 |
| Example 3 | | | |
| Comparative | compound C4 | −5.33 | 455 |
| Example 4 | | | |
| Comparative | compound C5 | −5.3 | 440 |
| Example 5 | | | |

Referring to Table 4, the HOMO energy level became deep in the polycyclic compounds according to Examples, and the maximum emission central wavelength was in a range of 450 nm to 470 nm, thereby inducing a short-wavelength effect.

The polycyclic compounds of Comparative Examples 2, 4 and 5 provided shallow HOMO energy levels.

The polycyclic compound of Comparative Example 3 provided an excessively shallow HOMO energy level, and the maximum emission central wavelength was greater than 490 nm (green emission region).

### Evaluation Example 3. Evaluation of Structural Features of Polycyclic Compounds

The comparison results of structural features of the compounds according to Examples 1, 4, 7, and Comparative Examples 1 to 4 using a molecular orbital calculation are shown in Table 5 below.

Evaluations were conducted on the compound 5 of Example 1 and the compound 73 of Example 7 as examples of the polycyclic compounds in which Ar₁ and Ar₂ in Chemical Formula 1 are represented by Chemical Formula 2-10. Evaluations were conducted on the compound 90 of Example 4 as examples of compounds in which Ar₁ and Ar₂ in Chemical Formula 1 are represented by Chemical Formula 2-8.

TABLE 5

| structure | horizontal direction |
|---|---|
| 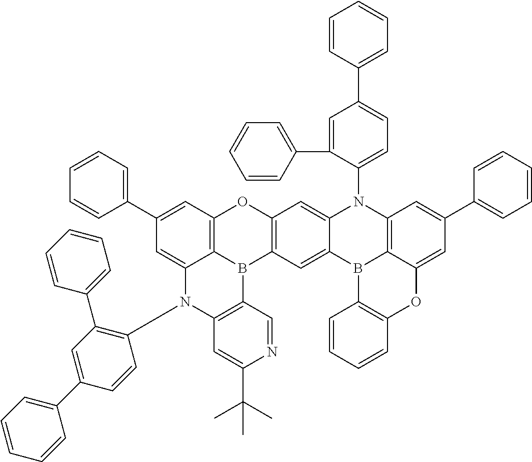 [SMILES: CC(C)(C)c1cc2c(cn1)B1c3cc4c(cc3Oc3cc(-c5ccccc5)cc(c31)N2c1ccc(-c2ccccc2)cc1-c1ccccc1)N(c1ccc(-c2ccccc2)cc1-c1ccccc1)c1cc(-c2ccccc2)cc2c1B4c1ccccc1O2] | 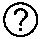 |
| Example 1 | |
| (compound 5) | |
| 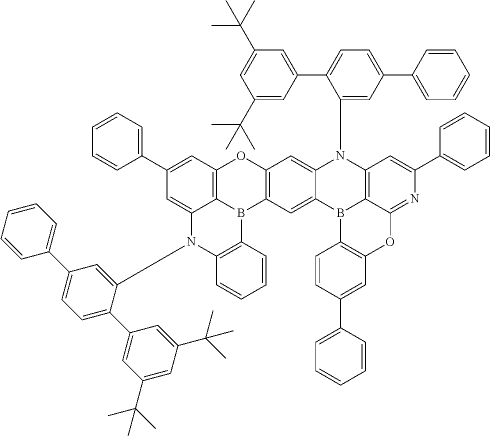 [SMILES: CC(C)(C)c1cc(-c2ccc(-c3ccccc3)cc2N2c3ccccc3B3c4cc5c(cc4Oc4cc(-c6ccccc6)cc2c43)N(c2cc(-c3ccccc3)ccc2-c2cc(C(C)(C)C)cc(C(C)(C)C)c2)c2cc(-c3ccccc3)nc3c2B5c2ccc(-c4ccccc4)cc2O3)cc(C(C)(C)C)c1] | 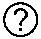 |
| Example 4 | |
| (compound 90) | |
| 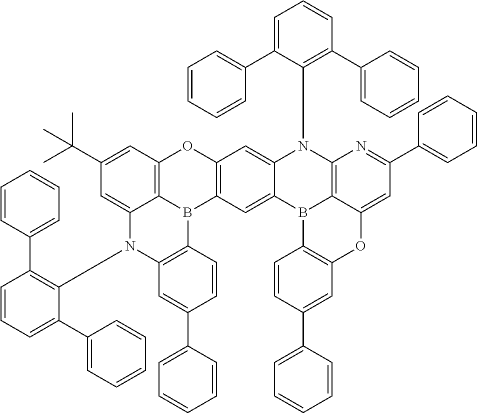 [SMILES: CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1nc(-c2ccccc2)cc2c1B3c1ccc(-c3ccccc3)cc1O2] | 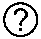 |
| Example 7 | |
| (compound 73) | |
| 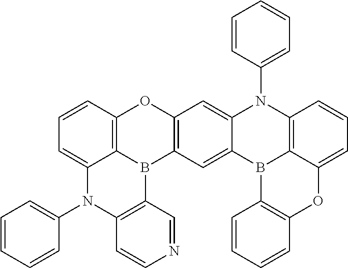 [SMILES: c1ccc(N2c3ccncc3B3c4cc5c(cc4Oc4cccc2c43)N(c2ccccc2)c2cccc3c2B5c2ccccc2O3)cc1] | 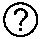 |
| Comparative | |
| Example 1 | |
| (compound C1) | |
| 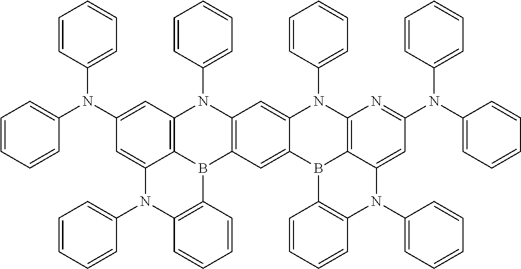 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)nc(c32)N5c2ccccc2)cc1] | 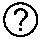 |
| Comparative | |
| Example 2 | |
| (compound C2) | |
| 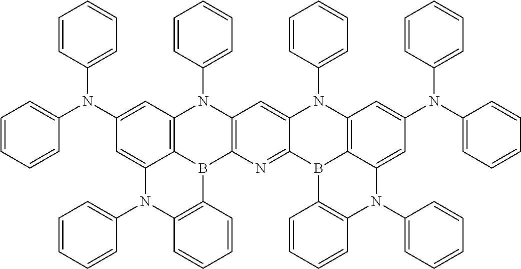 [SMILES: c1ccc(N(c2ccccc2)c2cc3c4c(c2)N(c2ccccc2)c2cc5c(nc2B4c2ccccc2N3c2ccccc2)B2c3ccccc3N(c3ccccc3)c3cc(N(c4ccccc4)c4ccccc4)cc(c32)N5c2ccccc2)cc1] | 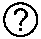 |
| Comparative | |
| Example 3 | |
| (compound C3) | |
| 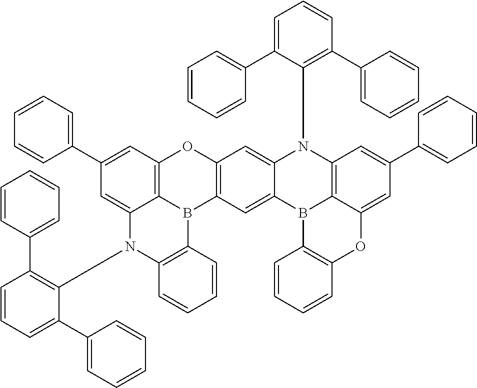 [SMILES: c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc(-c3ccccc3)cc3c2B4c2ccccc2O3)cc1] | 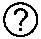 |
| Comparative | |
| Example 4 | |
| (compound C4) | |

vertical direction

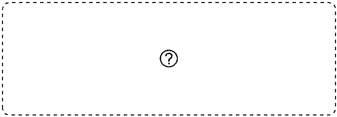

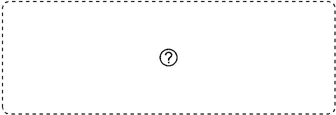

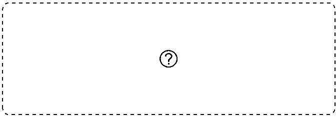

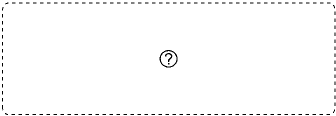

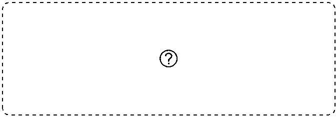

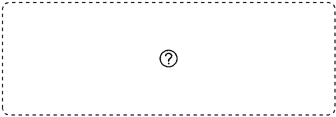

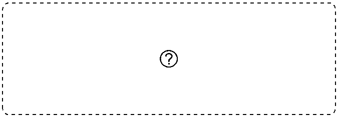

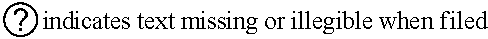

The polycyclic compounds according to the Examples included the electron-deficient nitrogen atom in the luminescent core so that a carrier transport may be enhanced. Additionally, the polycyclic compounds according to the Examples had a substituent other than hydrogen or deuterium at at least one selected from carbon atoms adjacent to the electron-deficient nitrogen atom, so that reactivity of the compounds was lowered, thereby improving oxidation stability.

Further, in Examples, Ar₁ and Ar₂ in Chemical Formula 1 may be selected from bulky groups, so that stacking between the polycyclic compounds can be effectively prevented, suppressed, or reduced.

As shown in the images in a third column of Table 5, the polycyclic compounds according to the Examples had a substituent other than hydrogen or deuterium in dotted line portions, so that oxidation stability was further improved.

In the polycyclic compound of Comparative Example 1, planarity of the molecule was high to easily cause stacking between the compounds. Further, the carbon atom adjacent to the electron-deficient nitrogen atom did not have a substituent to have low oxidation stability. Additionally, a substituent was not present in the dotted line portion to further reduce oxidation stability.

In the polycyclic compounds of Comparative Examples 2 and 3, planarity of the molecules was high to easily cause stacking between the compounds. Additionally, a substituent was not present in the dotted line portion to further reduce oxidation stability.

The polycyclic compound of Comparative Example 4 did not have the electron-deficient nitrogen atom in the luminescent core, and carrier transport properties were lowered. Additionally, a substituent was not present in the dotted line portion to further reduce oxidation stability.

### Evaluation Example 4. Performance Evaluation of Light-Emitting Device

Properties of the light-emitting devices fabricated as described above were measured at a current density of 10 mA/cm² using V7000 OLED IVL Test System, (Polaronix). Specifically, a driving voltage (V), a luminous efficiency (cd/A) and an emission wavelength at a luminance of 1000 cd/m² were measured using Keithley MU 236 and a luminance meter PR650.

The light-emitting device was continuously driven at a current density of 10 mA/cm², and a time until a luminance dropped to 95% of an initial value was measured. A relative value with respect to the time measured in the light-emitting device using the compound of Comparative Example 1 was expressed as a life-span (T95) of each light-emitting device.

The results are shown in Table 6 below.

TABLE 6

| | | | | driving | | emission | life- |
|---|---|---|---|---|---|---|---|
| | host | | dopant | voltage | efficiency | wavelength | span |
| | (HT:ET) | sensitizer | (3%) | (V) | (cd/A/y) | (nm) | (T95) |
| Example 1 | PH-13:ET-16 | PD1-13 | compound 5 | 4.1 | 505 | 457 | 3.0 |
| Example 2 | PH-13:ET-16 | PD1-13 | compound 1 | 4.1 | 510 | 457 | 3.5 |
| Example 3 | PH-13:ET-16 | PD1-13 | compound 68 | 4.1 | 545 | 458 | 4.0 |
| Example 4 | PH-13:ET-16 | PD1-13 | compound 90 | 4.0 | 540 | 458 | 4.3 |
| Example 5 | PH-13:ET-16 | PD1-13 | compound 20 | 4.0 | 530 | 459 | 4.7 |
| Example 6 | PH-13:ET-16 | PD1-13 | compound 36 | 4.1 | 520 | 463 | 5.1 |
| Example 7 | PH-13:ET-16 | PD1-13 | compound 73 | 4.0 | 540 | 460 | 5.3 |
| Example 8 | PH-13:ET-16 | PD1-13 | compound 94 | 4.1 | 541 | 459 | 5.1 |
| Example 9 | PH-13:ET-16 | PD1-13 | compound 114 | 4.1 | 545 | 459 | 4.8 |
| Comparative | PH-13:ET-16 | PD1-13 | compound C1 | 4.2 | 380 | 453 | 1 |
| Example 1 | | | | | | | |
| Comparative | PH-13:ET-16 | PD1-13 | compound C2 | 4.1 | 440 | 454 | 0.8 |
| Example 2 | | | | | | | |
| Comparative | PH-13:ET-16 | PD1-13 | compound C3 | 4.1 | 290 | 505 | 2.2 |
| Example 3 | | | | | | | |
| Comparative | PH-13:ET-16 | PD1-13 | compound C4 | 4.5 | 490 | 456 | 2.8 |
| Example 4 | | | | | | | |
| Comparative | PH-13:ET-16 | PD1-13 | compound C5 | 4.6 | 375 | 450 | 0.4 |
| Example 5 | | | | | | | |

Referring to Table 6, the light-emitting devices using the polycyclic compounds according to Examples had low driving voltages, and enhanced luminescence efficiency and life-span, and a short-wavelength effect was induced so that the emission wavelength was in a range of 450 nm to 470 nm.

The life-span properties were deteriorated in the light-emitting device using the compounds of the Comparative Examples. In the light-emitting device using the compound of Comparative Example 5, an amine group was bonded to a carbon atom adjacent to an sp2 hybridized nitrogen atom. Accordingly, reactivity was excessively increased to result in decrease in the life-span property.

The light-emitting devices using the compounds of Comparative Examples 1 to 3 and 5 had low luminescence efficiency. In the light-emitting device using the compound of Comparative Example 3, the emission wavelength exceeded 490 nm (green emission region).

The driving voltage was excessively increased in the light-emitting devices using the compounds of Comparative Examples 4 and 5.

What is claimed is:

1. A polycyclic compound represented by Chemical Formula 1: 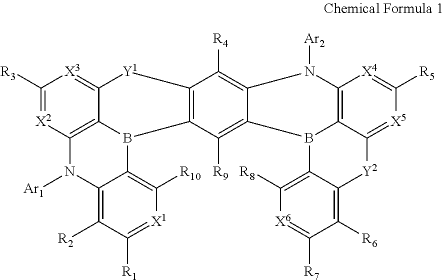
wherein, in Chemical Formula 1, Y¹ and Y² are each independently S, O or Se,
X¹ to X⁶ are each independently CR₁₁ or N, and at least one selected from X¹ to X⁶ is N,
when two or more of X¹ to X⁶ are CR₁₁, two or more CR₁₁ are the same or different from each other,
R₁ to R₁₁ are each independently hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group, and two or more adjacent groups selected from among R₁ to R₁₁ are optionally combined with each other to form a saturated or unsaturated ring, and
when nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ are each independently a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

2. The polycyclic compound of claim 1, wherein when nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ may each independently be a substituted or unsubstituted C₁-C₆₀ alkyl group, a substituted or unsubstituted C₃-C₆₀ cycloalkyl group, a substituted or unsubstituted C₃-C₆₀ heterocycloalkyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

3. The polycyclic compound of claim 2, wherein, when at least one selected from the carbons to which R₁, R₃, R₅, R₇, R₈ and R₁₀ are directly bonded is adjacent to nitrogen, at least one selected from the corresponding R₁, R₃, R₅, R₇, R₈ and R₁₀ are each independently be selected from a group represented by —CH₃, —CD₃, —CD₂H, —CDH₂, and any one selected from Chemical Formulae 3-1 to 3-12: 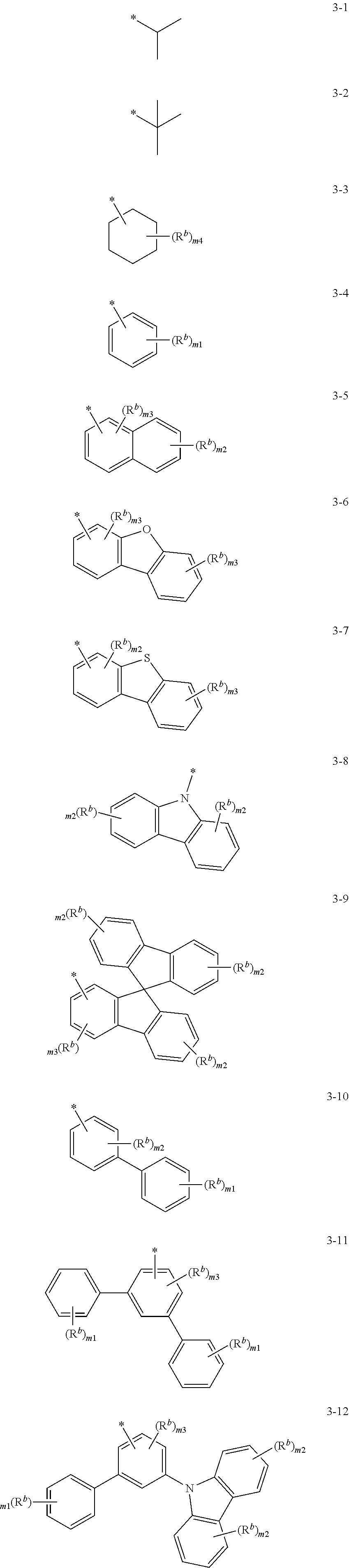
wherein, in Chemical Formulae 3-1 to 3-12, R^{b} each independently represents hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₃₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group,
when R^{b} is plural, two or more adjacent R^{b} are optionally combined with each other to form a saturated or unsaturated ring,
m1s are the same or different, and are an integer from 0 to 5,
m2s are the same or different, and are an integer from 0 to 4,
m3s are the same or different, and are an integer from 0 to 3,
m4 is an integer from 0 to 11, and
*- represents a bonding position.

4. The polycyclic compound of claim 1, wherein any one or two selected from X¹ to X⁶ is N, and the remainder are CR₁₁.

5. The polycyclic compound of claim 4, wherein at least one selected from X² and X⁴ among X¹ to X⁶ is N, and the remainder are CR₁₁.

6. The polycyclic compound of claim 1, wherein Ar₁ and Ar₂ in Chemical Formula 1 are each independently selected from groups represented by Chemical Formulae 2-1 to 2-12: 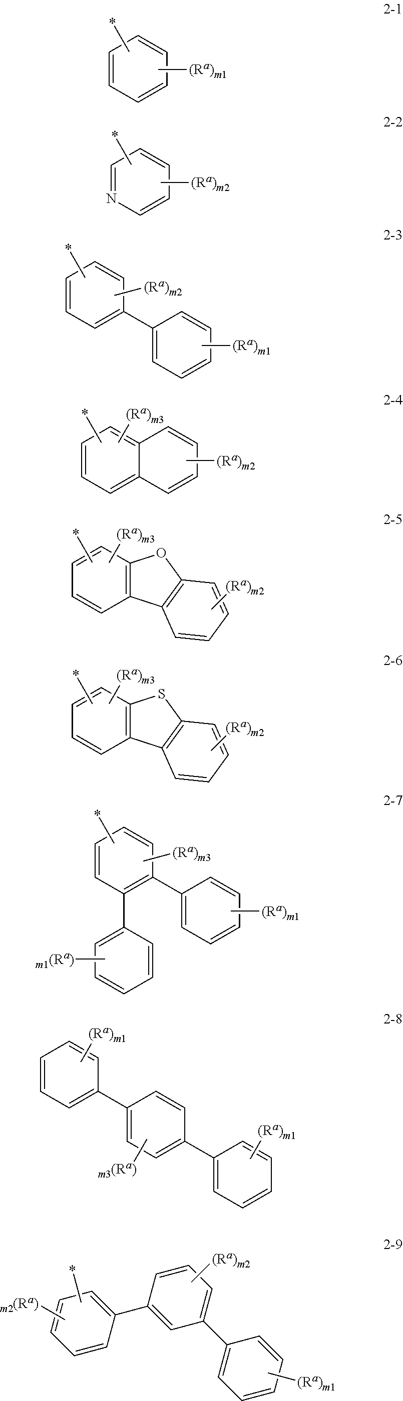 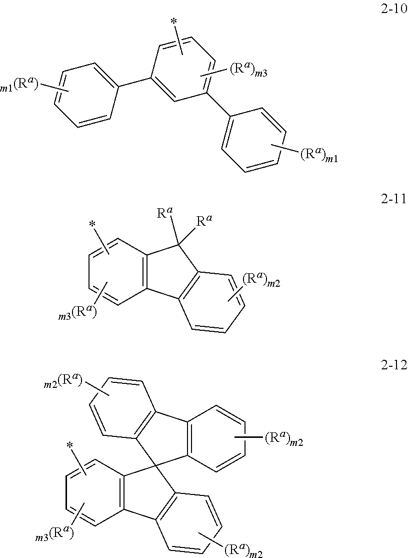
wherein, in Chemical Formulae 2-1 to 2-12, R^{a} each independently represents hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₃₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group,
when R^{a} is plural, two or more adjacent R^{a} are optionally combined with each other to form a saturated or unsaturated ring,
m1s are the same or different, and are an integer from 0 to 5,
m2s are the same or different, and are an integer from 0 to 4,
m3s are the same or different, and are an integer from 0 to 3, and
*- represents a bonding position.

7. The polycyclic compound of claim 6, wherein Ar₁ and Ar₂ in Chemical Formula 1 are each independently selected from groups represented by Chemical Formulae 2-3, and 2-7 to 2-10.

8. The polycyclic compound of claim 7, wherein Ar₁ and Ar₂ in Chemical Formula 1 are each independently selected from groups represented by Chemical Formulae 2-13, 2-14, and 2-15: 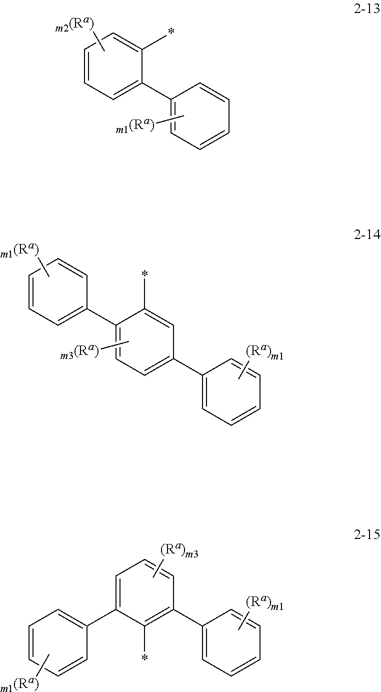
wherein, R^{a} and m1 to m3 are the same as those defined with respect to Chemical Formulae 2-1 to 2-12.

9. The polycyclic compound of claim 1, wherein the polycyclic compound is represented by any one selected from Chemical Formulae 1-1 to 1-6: 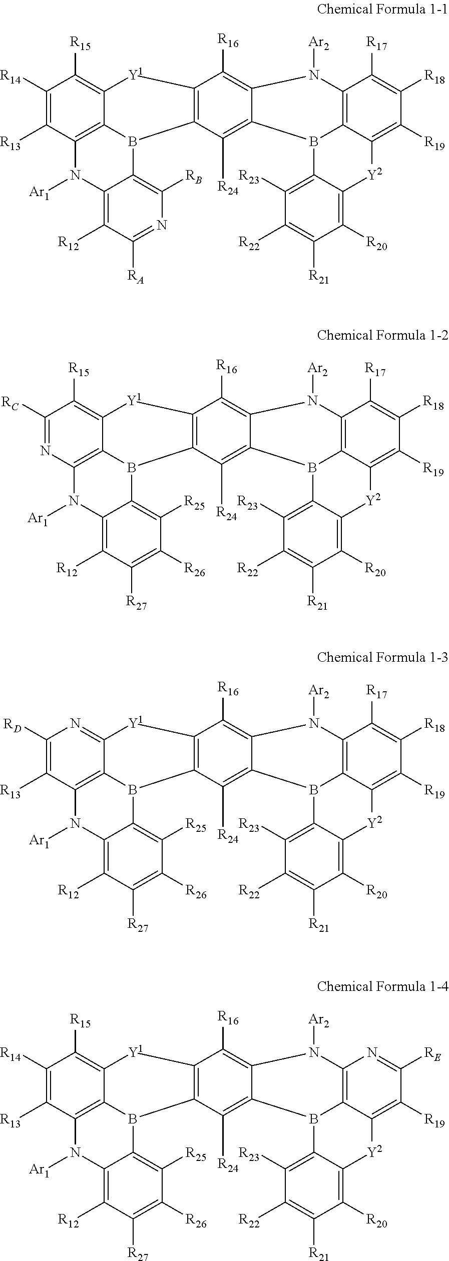 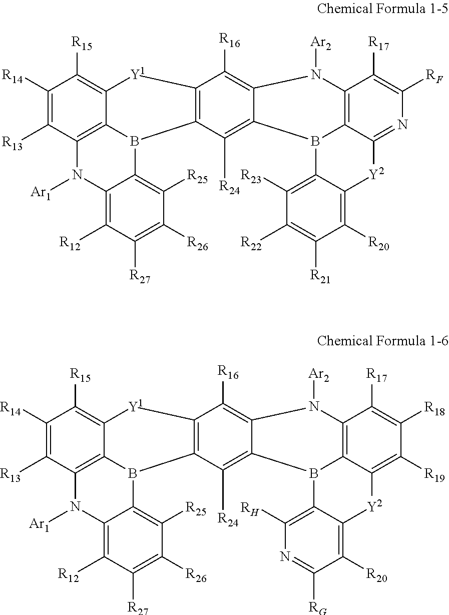
wherein, in Chemical Formulae 1-1 to 1-6, Y¹ and Y² are each independently S, O or Se,
R₁₂ to R₂₇ and R_{A} to R_{H} are each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
two or more adjacent groups selected from among R₁₂ to R₂₇ are optionally combined with each other to form a saturated or unsaturated ring, and
at least one selected from R_{A} and R_{B}; R_{C} to R_{F}; and at least one selected from R_{G} and R_{H} are each independently a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

10. The polycyclic compound of claim 9, wherein Y₁ and Y₂ are the same.

11. The polycyclic compound of claim 10, wherein Y₁ and Y₂ are oxygen.

12. The polycyclic compound of claim 9, wherein at least one selected from R₂₀ to R₂₃ in Chemical Formula 1-1; at least one selected from R₁₂, R₂₀ to R₂₃, and R₂₅ to R₂₇ in Chemical Formula 1-2 to 1-5; and at least one selected from R₁₂, and R₂₅ to R₂₇ in Chemical Formula 1-6 are each independently a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

13. The polycyclic compound of claim 9, wherein at least one selected from R_{A} and R_{B}; R_{C} to R_{F}; and at least one selected from R_{G} and R_{H} are each independently selected from —CH₃, —CD₃, —CD₂H, —CDH₂, and any one selected from groups represented by Chemical Formulae 3-1 to 3-12: 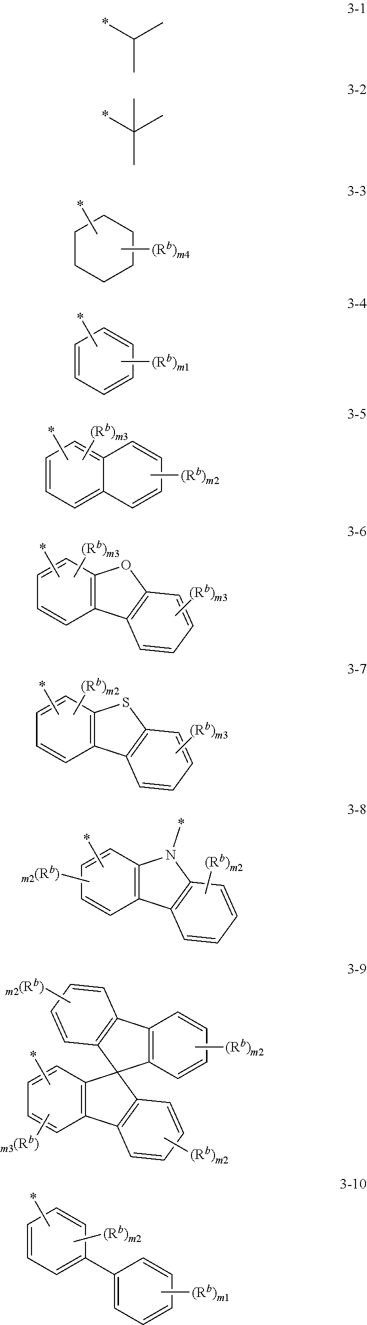 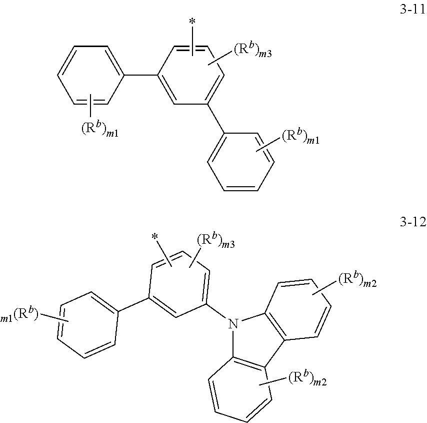
wherein, in Chemical Formulae 3-1 to 3-12, R^{b} each independently represents hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₃₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group,
when R^{b} is plural, two or more adjacent R^{b} are optionally combined with each other to form a saturated or unsaturated ring,
m1s are the same or different, and are an integer from 0 to 5,
m2s are the same or different, and are an integer from 0 to 4,
m3s are the same or different, and are an integer from 0 to 3,
m4 is an integer from 0 to 11, and
*- represents a bonding position.

14. A light-emitting device, comprising:
a first electrode;
a second electrode; and
an emission layer between the first electrode and the second electrode, the emission layer comprising a polycyclic compound represented by Chemical Formula 1: 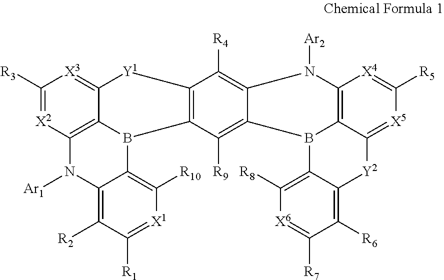
wherein, in Chemical Formula 1, Y¹ and Y² are each independently be S, O or Se,
X¹ to X⁶ are each independently CR₁₁ or N, at least one selected from X¹ to X⁶ is N,
when two or more of X¹ to X⁶ are CR₁₁, two or more CR₁₁ are the same or different from each other,
R₁ to R₁₁ are each independently be hydrogen, deuterium, —OH, —CN, —F, —Cl, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group, and two or more adjacent groups selected from among R₁ to R₁₁ are optionally combined with each other to form a saturated or unsaturated ring, and
when nitrogen is adjacent to at least one selected from carbons to which R₁, R₃, R₅, R₇, R₈ and R₁₀ are directly bonded, at least one selected from the corresponding R₁, R₃, R₅, R₇, R₈ and R₁₀ are each independently a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, or a substituted or unsubstituted C₈-C₆₀ condensed polycyclic group.

15. The light-emitting device of claim 14, further comprising a charge generation layer between the first electrode and the second electrode,
wherein the emission layer comprises a plurality of emission layers, and the charge generation layer is between adjacent emission layers,
wherein at least one selected from the plurality of emission layers comprises the polycyclic compound of Chemical Formula 1.

16. The light-emitting device of claim 14, wherein the polycyclic compound is included as a thermally activated delayed fluorescence (TADF) dopant.

17. The light-emitting device of claim 14, wherein each of the plurality of emission layers comprises the polycyclic compound, and the polycyclic compound is included as a thermally activated delayed fluorescence (TADF) dopant.

18. The light-emitting device of claim 14, wherein the emission layer emits a blue light having a maximum emission wavelength from 440 nm to 480 nm.

19. An electronic device comprising the light-emitting device of claim 14.

20. The electronic device of claim 19, wherein the electronic device is one selected from a flat panel display, a curved display, a computer monitor, a medical monitor, a television, a billboard, a light for indoor or outdoor lighting, a signal lighting, a head-up display, a full or partial transparent display, a flexible display, a rollable display, a foldable display, a stretchable display, a laser printer, a phone, a mobile phone, a tablet, a phablet, a personal information terminal (PDA), a wearable device, a laptop computer, a digital camera, a camcorder, a viewfinder, a micro display, a 3D display, a virtual reality or augmented reality display, a vehicle, a video wall including a plurality of displays tiled together, a theater or stadium screen, a phototherapy device, and a signage.
